(19) United States
(12) Patent Application Publication
(10) Pub. No.: US 2019/0012948 A1
(43) Pub. Date: Jan. 10, 2019

(54) PIXEL CIRCUIT, AND DISPLAY DEVICE AND DRIVING METHOD THEREFOR

(71) Applicant: Sharp Kabushiki Kaisha, Sakai City, Osaka (JP)

(72) Inventors: Masanori OHARA, Sakai City (JP); Hideki UCHIDA, Sakai City (JP); Katsuhiro KIKUCHI, Sakai City (JP); Yuto TSUKAMOTO, Sakai City (JP); Eiji KOIKE, Sakai City (JP); Kazuo TAKIZAWA, Sakai City (JP); Noboru NOGUCHI, Sakai City (JP); Noritaka KISHI, Sakai City (JP); Asae ITO, Sakai City (JP); Yoshiyuki ISOMURA, Sakai City (JP)

(21) Appl. No.: 16/066,813

(22) PCT Filed: Dec. 22, 2016
(86) PCT No.: PCT/JP2016/088333

§ 371 Date: Jun. 28, 2018

(30) Foreign Application Priority Data
Dec. 29, 2015 (JP) 2015-257664

(51) Int. Cl. G09G 3/20; H01L 27/32; G09G 3/3258; G09G 3/3233

(52) U.S. Cl. CPC G09G 3/2003; H01L 27/3276; G09G 2310/0264; G09G 3/3233; G09G 3/3258

(57) ABSTRACT

In each of pixel circuits in an organic EL display device configured to display color images in a field sequential method, a drive transistor is connected to first to third organic EL elements configured to emit red light, green light, and blue light through first to third light emission control transistors. A connection point between the drive transistor and the light emission control transistors is connected to a data line through a monitor control transistors. A data-side driving circuit is provided with a data voltage output unit circuit and a current measurement unit circuit for each of data lines. The data-side driving circuit is configured to be able to switch between the unit circuits to connect either one of the unit circuits to the data line.

### TECHNICAL FIELD

The present disclosure relates to an active matrix display device and, more specifically, relates to an active matrix display device including a current-driven self-luminescent display elements, such as an organic EL display device, and a driving method therefor, and a pixel circuit in such a display device.

### BACKGROUND ART

As display elements included in display devices, there have been known electrooptical elements in each of which luminescence is controlled using voltage applied to the electrooptical element and electrooptical elements in each of which luminescence is controlled using current passing through the electrooptical element. A representative example of the electrooptical element in which luminance is controlled using voltage applied to the electrooptical element is a liquid crystal display element. Meanwhile, a representative example of the electrooptical element in which luminance is controlled using current passing through the electrooptical element is an organic electroluminescence (EL) element. An organic EL element is also referred to as an organic light-emitting diode (OLED). Organic EL display devices using organic EL elements, which are self-luminescent electrooptical elements, can easily be reduced in thickness, reduced in power consumption, achieve high luminescence, and the like compared with liquid crystal display devices, which requires back light, color filters, and the like. Hence, the development of organic EL display devices has been actively pursued in recent years.

As a driving method for an organic EL display device, a passive matrix method (also referred to as a “simple matrix method”) and an active matrix method are known. Organic EL display devices adopting the passive matrix method have simple configurations while having difficulties in being increased in size and achieving higher resolution. In contrast, organic EL display devices adopting the active matrix method (referred to as “active-matrix organic EL display devices” below) can easily be increased in size and achieve higher resolution compared with the organic EL display devices adopting the passive matrix method.

In a general active matrix display device configured to display color images, a plurality of pixel circuits arranged in a matrix are provided. Each pixel of a display image is constituted by three sub pixels, i.e., an R sub pixel displaying red, a G sub pixel displaying green, and a B sub pixel displaying blue, and each of the sub pixels is formed by a single pixel circuit. In such an active-matrix organic EL display device, each of the pixel circuits includes: an organic EL element emitting any one of red, green, and blue lights; a capacitor holding a voltage as sub pixel data that determines the light emission intensity of the organic EL element; an input transistor as a switching element for controlling writing of sub pixel data to the capacitor; and a drive transistor controlling current supply to the organic EL element.

Some organic EL display devices are configured, for the purpose of reducing luminance variations in a display image due to variations in characteristics of the drive transistors, such that a current to be supplied to the organic EL element by each of the drive transistors (referred to as a “drive current” below) is taken out to an external unit of the corresponding pixel circuit to measure the drive current and that sub pixel data to be written into each of the pixel circuits is corrected on the basis of a result of the measurement to compensate the variations in characteristics. A method of compensating variations in characteristics of drive transistors by using such a configuration is referred to as an “external compensation method” below.

PTL 1 (WO 2014/021201) discloses an organic EL display device adopting such an external compensation method. In this organic EL display device, a data driver transmits, to a controller 10, first and second measurement data respectively corresponding to first and second measurement data voltages, and the controller updates threshold voltage correction data and gain correction data on the basis of the first and second measurement data Im while correcting image data on the basis of the threshold voltage correction data and the gain correction data. With this configuration, both threshold voltage compensation and gain compensation for a drive transistor are performed for each pixel circuit while performing display.

In relation to the present disclosure, PTL 2 (JP 2005-148749 A) discloses a pixel circuit having a configuration in which the number of transistors and the number of capacitors necessary for a single pixel are reduced compared with known configurations. This pixel circuit is constituted by a driver, a sequential controller, and three organic EL elements OLED (R), OLED (G), and OLED (B). The driver is constituted by a drive transistor, an input transistor, and a capacitor. The sequential controller is constituted by a transistor T13(R) controlling light emission of the organic EL element OLED(R) for red, a transistor T13(G) controlling light emission of the organic EL element OLED(G) for green, and a transistor T13(B) controlling light emission of the organic EL element OLED(B) for blue and is provided with emission lines EM1, EM2, and EM3 as wiring lines for sequentially turning on the transistors T13(R), T13(G), and T13(B) for light emission control.

### CITATION LIST

### Patent Literature

PTL 1: WO 2014/021201 pamphlet

PTL 2: JP 2005-148749 A

### SUMMARY

### Technical Problem

In an organic EL display device adopting the external compensation method, each pixel circuit includes a transistor as a switching element for measurement of a drive current (referred to as a “monitor control transistor” below) in addition to the capacitor, the input transistor, and the drive transistor that are described above. In other words, each pixel circuit includes at least three transistors and one capacitor. Hence, each circuit forming each pixel constituted by three sub pixels includes at least nine transistors and three capacitors. For this reason, it is difficult to achieve higher resolution of a display image by such an organic EL display device. Moreover, such an organic EL display device needs to include a function for the measurement of a drive current and correction of sub pixel data, based on a result of the measurement (referred to as an “external compensation function” below) for each data signal line for transferring a voltage signal as sub pixel data from an external unit (driving circuit) to each pixel circuit, and thus the cost of an integrated circuit (IC) as a driving circuit increases.

In view of the above, an object of the present disclosure is to provide: a display device that is an active matrix display device using an external compensation method, the active matrix display device including a current-driven self-luminescent display element and that can display a high-resolution color image while suppressing an increase in cost; and a pixel circuit for the display device.

### Solution to Problem

A first aspect of the disclosure is a pixel circuit provided in a display device including a plurality of data lines and a plurality of writing control lines intersecting with the plurality of data lines, the pixel circuit corresponding to any one of the plurality of data lines and to any one of the plurality of writing control lines, the pixel circuit including:

a prescribed number of display elements configured to emit light of a prescribed number of primary colors by being driven by currents, the prescribed number being three or more;

a prescribed number of light emission control transistors configured to serve as switching elements connected to the prescribed number of display elements in series and controlling lighting/lighting-out of the prescribed number of display elements;

a data holding capacity configured to hold data voltages for controlling drive currents of the prescribed number of display elements;

an input transistor configured to serve as a switching element including a control terminal connected to a corresponding one of the plurality of writing control lines and controlling voltage supply from corresponding data line of the plurality of data lines to the data holding capacity;

a drive transistor configured to supply a drive current corresponding to the data voltage to a display element connected to each of the light emission control transistors that is in an ON state among the prescribed number of display elements; and

a monitor control transistor configured to serve as a switching element disposed between a prescribed position in the pixel circuit and the corresponding data line to be able to transmit a current or a voltage in the pixel circuit to the corresponding data line.

A second aspect of the disclosure is a display device including:

a plurality of data lines;

a plurality of writing control lines intersecting with the plurality of data lines;

a plurality of pixel circuits according to the first aspect of the disclosure each corresponding to any one of the plurality of data lines and to any one of the plurality of writing control lines and disposed in a matrix along the plurality of data lines and the plurality of writing control lines;

a plurality of light emission control lines, a prescribed number of the plurality of light emission control lines being disposed for each of the plurality of writing control lines, the prescribed number being equal to the prescribed number of the light emission control transistors;

a plurality of monitor control lines corresponding to the plurality of writing control lines and disposed along the plurality of writing control lines, and each connected to a control terminal of the monitor control transistor in a corresponding one of the plurality of pixel circuits;

a data line driving circuit configured to apply a plurality of data signals to the plurality of data lines, the plurality of data signals representing a color image to be displayed;

a writing control line driving circuit configured to selectively drive the plurality of writing control lines;

a monitor control line driving circuit configured to drive the plurality of monitor control lines;

a light emission control line driving circuit configured to drive the plurality of light emission control lines and cause the prescribed number of light emission control transistors in each of the pixel circuits to sequentially turn into an ON state in each of frame periods;

a measurement circuit configured to measure a current or a voltage in each of the plurality of pixel circuits via the monitor control transistor in the pixel circuit and the data line corresponding to the pixel circuit; and

a drive control circuit configured to control the data line driving circuit, the writing control line driving circuit, the monitor control line driving circuit, and the light emission control line driving circuit.

A third aspect of the disclosure is that, in the second aspect of the disclosure,

in a case where the color image is displayed by the plurality of pixel circuits, the drive control circuit

divides each of the frame periods into a prescribed number of subframe periods corresponding to the prescribed number of primary colors,

controls the writing control line driving circuit and causes the plurality of writing control lines to sequentially turn into an active state in each of the subframe periods,

controls the data line driving circuit to apply, in each of the subframe periods, signals representing an image of a primary color corresponding to the subframe period among images of the prescribed number of primary colors constituting the color image, as the plurality of data signals, to the plurality of data lines,

controls the monitor control line driving circuit to maintain monitor control transistors in the plurality of pixel circuits in an OFF state, and

controls the light emission control line driving circuit to cause, in each of the subframe periods, only a light emission control transistor connected in series to the display element to emit a light in the primary color corresponding to the subframe period among the prescribed number of light emission control transistors in each of the plurality of pixel circuits, to change to an ON state while causing the prescribed number of light emission control transistors in each of the plurality of pixel circuits to sequentially turn into an ON state for prescribed time periods in each of the frame periods.

A fourth aspect of the disclosure, in the third aspect of the disclosure, further includes a selection signal generation circuit configured to generate a prescribed number of selection signals becoming active in the prescribed number of subframe periods in each of the frame periods,

wherein the light emission control line driving circuit includes

a plurality of demultiplexers corresponding to the plurality of writing control lines and each connected to the prescribed number of light emission control lines corresponding to corresponding one of the writing control lines,

a light emission control line activation circuit configured to output a plurality of light emission enable signals to the plurality of demultiplexers,

a plurality of pull-down transistors each functioning as a switching element provided for each of the plurality of light emission control lines and including a first conduction terminal and a second conduction terminal, the first conduction terminal being connected to corresponding light emission control line, the second conduction terminal being supplied with a prescribed voltage indicating an inactive state, and

a light emission control line deactivation circuit configured to control on/off of the plurality of pull-down transistors,

each of the plurality of demultiplexers includes a prescribed number of activation control transistors being a prescribed number of activation control transistors corresponding to the prescribed number of respective light emission control lines connected to the demultiplexer and each functioning as a switching element including a first conduction terminal and a second conduction terminal, the first conduction terminal being supplied with a light emission enable signal output from the light emission control line activation circuit to the demultiplexer, the second conduction terminal being connected to the corresponding one of the plurality of light emission control lines,

the selection signal generation circuit supplies the prescribed number of selection signals to respective control terminals of the prescribed number of activation control transistors in each of the plurality of demultiplexers, and

in a case where the color image is displayed by the plurality of pixel circuits, the drive control circuit

controls the light emission control line activation circuit and the selection signal generation circuit and causes the plurality of light emission control lines to sequentially turn into an active state to cause the light emission control transistors connected to the display elements of one of light emission colors in the plurality of pixel circuits to sequentially turn into an ON state in each subframe period corresponding to the light emission color, and

controls the light emission control line deactivation circuit and causes the plurality of light emission control lines caused to sequentially turn into the active state by the light emission control line activation circuit, to sequentially turn into an inactive state to thereby cause the prescribed number of light emission control transistors in each of the pixel circuits to sequentially turn into an ON state in the respective prescribed periods.

A fifth aspect of the disclosure is that, in the second aspect of the disclosure,

in a case of measuring a current or a voltage in each of the plurality of pixel circuits corresponding to any one writing control line of the plurality of writing control lines,

the drive control circuit controls the monitor control line driving circuit to cause only the monitor control transistor in each of the plurality of pixel circuits corresponding to the one writing control line to be in an ON state, and

the measurement circuit measures a current or a voltage of each of the plurality of pixel circuits corresponding to the one writing control line via the monitor control transistor in the pixel circuit and the data line corresponding to the pixel circuit.

A sixth aspect of the disclosure is that, in the fifth aspect of the disclosure,

in a case of measuring a current or a voltage in each of the plurality of pixel circuits corresponding to any one writing control line of the plurality of writing control lines, the drive control circuit controls the light emission control line driving circuit to cause at least the prescribed number of light emission control transistors of each of the plurality of pixel circuits corresponding to the one writing control line to be an OFF state.

A seventh aspect of the disclosure is that, in any one of the second to sixth aspects of the disclosure,

a transistor configuring each of the plurality of pixel circuits is a thin film transistor in which a channel layer is formed of an oxide semiconductor.

An eighth aspect of the disclosure is a driving method for a display device, the display device including

a plurality of data lines,

a plurality of writing control lines intersecting with the plurality of data lines,

a plurality of pixel circuits each corresponding to any one of the plurality of data lines and to any one of the plurality of writing control lines and disposed in a matrix along the plurality of data lines and the plurality of writing control lines,

a plurality of light emission control lines, a prescribed number of the plurality of light emission control lines being disposed for each of the plurality of writing control lines, the prescribed number being equal to the prescribed number of the light emission control transistors, and

a plurality of monitor control lines corresponding to the plurality of writing control lines and disposed along the plurality of writing control lines,

each of the plurality of pixel circuits including

a prescribed number of display elements configured to emit respective light of a prescribed number of primary colors by being driven by currents, the prescribed number being three or more,

a prescribed number of light emission control transistors configured to serve as switching elements connected to the prescribed number of display elements in series and controlling lighting/lighting-out of the prescribed number of display elements,

a data holding capacity configured to hold data voltages for controlling drive currents of the prescribed number of display elements,

an input transistor configured to serve as a switching element including a control terminal connected to the corresponding one of the plurality of writing control lines and controlling voltage supply from corresponding data line of the plurality of data lines to the data holding capacity,

a drive transistor configured to supply a drive current corresponding to the data voltage to a display element connected to each of the light emission control transistors that is in an ON state among the prescribed number of display elements, and

a monitor control transistor configured to serve as a switching element including a control terminal connected to the monitor control line, disposed along the corresponding writing control line disposed between a prescribed position in the pixel circuit and the corresponding data line to be able to transmit a current or a voltage in the pixel circuit to the corresponding data line, the driving method including:

a data line drive step of applying a plurality of data signals representing a color image to be displayed to the plurality of data lines;

a writing control line drive step of selectively driving the plurality of writing control lines;

a monitor control line drive step of driving the plurality of monitor control lines; and

a light emission control line drive step of driving the plurality of light emission control lines to cause the prescribed number of display elements in each of the plurality of pixel circuits to sequentially turn into a lit state in each of the frame periods.

Other aspects of the disclosure are apparent from descriptions of the above-described first to eighth aspects of the disclosure and embodiments to be described later, descriptions thereof are omitted.

### Advantageous Effects of Disclosure

In a display device including pixel circuits according to the first aspect of the disclosure, the prescribed number of display elements configured to emit lights of the prescribed number of primary colors are included in each of the pixel circuits, the prescribed number being three or more. The display element in a lit state is sequentially switched among the prescribed number of display elements in each pixel circuit in each frame period, and thereby a color image is displayed by sequential additive color mixture. With this configuration, the number of pixel circuits and the area of a display necessary to display a color image at certain resolution (number of pixels) can be significantly reduced in comparison with a known method of forming each pixel of a color image to be displayed by using a certain number of pixel circuits at the same resolution, the certain number being equal to the number of primary colors. Moreover, such a reduction in number of pixel circuits also reduces the number of data lines accordingly, and hence the contents of circuits in a data-side driving circuit is also significantly reduced. Moreover, in a case where the monitor control transistor is included in each pixel circuit to provide a configuration of measuring a current or a voltage in each pixel circuit as in the disclosure, i.e., a case of employing an external compensation method, a circuit (measurement unit circuit) for measurement is provided for each data line in the data-side driving circuit, and hence effects of the reduction in contents of circuits in the data-side driving circuit as a result of the reduction in number of pixel circuits as above are more significant. Hence, it is possible to significantly reduce not only the number of pixel circuits necessary to display a color image at the same resolution as that in a known case but also the contents of circuits in the data-side drive circuit, which makes it possible to display a high-resolution color image while suppressing an increase in cost in an active matrix display device using the external compensation method.

The display device according to the second aspect of the disclosure is an active matrix display device using the external compensation method including pixel circuits according to the first aspect of the disclosure and configured to display a color image in a field sequential method, and exerts similar effects to those according to the first aspect of the disclosure.

According to a third aspect of the disclosure, in a case where a color image is displayed on the basis of input signals from an external unit without measuring a current or a voltage in each pixel circuit (in a case of acting in a normal display mode), each frame period is divided into a prescribed number of subframe periods corresponding to the prescribed number of primary colors, the plurality of writing control lines are sequentially turned into an active state in each subframe period while signals representing an image of the primary color corresponding to the subframe period are applied to the plurality of data lines as a plurality of data signals, and each pixel data indicating the image of the primary color is written into the corresponding pixel circuit and held as a data voltage. Moreover, the prescribed number of light emission control transistors in each pixel circuit are sequentially turned into an ON state at respective prescribed intervals in each frame period. Consequently, the prescribed number of display elements in each pixel circuit are sequentially turned into a lit state for respective prescribed periods (one subframe periods, normally) to emit light at the intensity corresponding to the written pixel data. In this way, the color image represented by the input signals is displayed by sequential additive color mixture. The display device according to the third aspect of the disclosure for displaying a color image in a field sequential method is also an active matrix display device using the external compensation method including pixel circuits according to the first aspect of the disclosure, and exerts similar effects to those according to the first or second aspect of the disclosure.

In the fourth aspect of the disclosure, the light emission control line driving circuit is configured by one demultiplexer provided so as to correspond to each writing control line, the light emission control line activation circuit configured to output a light emission enable signal to each demultiplexer, one pull-down transistor provided for each light emission control line, and the light emission control line deactivation circuit configured to control on/off of each pull-down transistor. Each light emission enable signal output from the light emission control line activation circuit is supplied to the prescribed number of light emission control lines in a time division manner by the prescribed number of activation control transistors included in the demultiplexer, on the basis of selection signals from the selection signal generation circuit. With this configuration, the plurality of light emission control lines are sequentially turned into an active state, and thereby the light emission control transistors connected to the display elements of a certain light emission color in the pixel circuits are sequentially turned into an ON state in each subframe period corresponding to the light emission color. Light emission control lines sequentially turned into an active state are sequentially turned into an inactive state by the pull-down transistors connected to the light emission control lines being turned on by the light emission control line deactivation circuit. Consequently, the prescribed number of light emission control transistors in each pixel circuit are sequentially turned into an ON state at respective prescribed intervals. According to the fourth aspect of the disclosure, similar effects to those of the third aspect of the disclosure can be obtained, and also a color image can be displayed in a similar field sequential method to that of the third aspect of the disclosure while the light emission line control driving circuit is implemented by relatively small contents of circuits.

According to the fifth aspect of the disclosure, in a case of measuring a current or a voltage in each pixel circuit corresponding to any one writing control line, only the monitor control transistor in each pixel circuit corresponding to the one writing control line is turned into an ON state, and the measurement circuit measures a current or a voltage in each pixel circuit corresponding to the one writing control line via the monitor control transistor in the pixel circuit and the data line corresponding to the pixel circuit. The display device according to the fifth aspect of the disclosure for thus measuring a current or a voltage in the pixel circuit is also an active matrix display device using the external compensation method including pixel circuits according to the first aspect of the disclosure, and exerts similar effects to those according to the first or second aspect of the disclosure.

According to the sixth aspect of the disclosure, in a case of measuring a current or a voltage in each pixel circuit corresponding to any one writing control line, at least the light emission control transistors in each pixel circuit corresponding to the one writing control line are all turned into an OFF state. Consequently, the drive transistor in the pixel circuit are electrically separated from any display element, and hence a current or a voltage associated with the drive transistor can be measured more reliably and accurately.

According to the seventh aspect of the disclosure, the transistor configuring each pixel circuit is a thin film transistor in which a channel layer is formed of an oxide semiconductor, and hence power consumption can be reduced in comparison with a case of using thin film transistors of other kinds while similar effects to those in any of the second to sixth aspects of the disclosure can be obtained. Moreover, leak current in the monitor control transistor in each pixel circuit can be extremely small, and hence a current or a voltage in each pixel circuit can be measured at high accuracy.

The eighth aspect of the disclosure exerts similar effects to those of the first or second aspect of the disclosure.

Since effects of other aspects of the disclosure are apparent from descriptions of the effects of the first to eighth aspects of the disclosure and embodiments to be described later, descriptions thereof are omitted.

### BRIEF DESCRIPTION OF DRAWINGS

FIG. 1 is a block diagram illustrating an overall configuration of an organic EL display device according to a first embodiment of the present invention.

FIG. 2 is a block diagram for describing a configuration of a display in the first embodiment.

FIG. 3 is a circuit diagram for describing a configuration of a pixel circuit of an organic EL display device using a known external compensation method.

FIG. 4 is a circuit diagram for describing a configuration of a pixel circuit in the first embodiment.

FIG. 5 is a circuit diagram illustrating a configuration of a data-side unit circuit in a data-side driving circuit in the first embodiment.

FIG. 6 is a block diagram illustrating a configuration of a drive controller in a display control circuit in the first embodiment.

FIG. 7 is a block diagram illustrating a configuration of a writing line counter in the first embodiment.

FIG. 8 is a signal waveform diagram of a clock signal CLK1 and a clock signal CLK2 in a normal process period in the first embodiment.

FIG. 9 is a circuit diagram illustrating a configuration of a matching circuit in the first embodiment.

FIG. 10 is a block diagram illustrating a configuration of a correction data calculator/storage in the display control circuit in the first embodiment.

FIG. 11 is a block diagram illustrating a configuration of a writing control line driving circuit in the first embodiment.

FIG. 12 is a circuit diagram illustrating a configuration of a unit circuit of a shift register configuring the writing control line driving circuit (configuration corresponding to one stage of the shift register) in the first embodiment.

FIG. 13 is a timing chart for describing basic actions of the unit circuit of the shift register configuring the writing control line driving circuit in the first embodiment.

FIG. 14 is a block diagram illustrating a configuration of a monitor control line driving circuit in the first embodiment.

FIG. 15 is a signal waveform diagram of a clock signal CLK3 and a clock signal CLK4 in a normal process period in the first embodiment.

FIG. 16 is a circuit diagram illustrating a configuration of a unit circuit of a shift register configuring the monitor control line driving circuit in the first embodiment.

FIG. 17 is a diagram for describing how a monitor enable signal is supplied to a transistor T49 in the unit circuit of the shift register configuring the monitor control line driving circuit in the first embodiment.

FIG. 18 is a diagram for describing a configuration of a light emission control line driving circuit in the first embodiment.

FIG. 19 is a block diagram illustrating a configuration of a light emission control line activation circuit in the light emission control line driving circuit in the first embodiment.

FIG. 20 is a circuit diagram illustrating a configuration of a unit circuit of a shift register configuring the light emission control line activation circuit in the light emission control line driving circuit in the first embodiment.

FIG. 21 is a timing chart for describing basic actions of the unit circuit of the shift register configuring the light emission control line activation circuit in the first embodiment.

FIG. 22 is a block diagram illustrating a configuration of a light emission control line deactivation circuit in the light emission control line driving circuit in the first embodiment.

FIG. 23 is a circuit diagram illustrating a configuration of a unit circuit of a shift register configuring the light emission control line deactivation circuit in the first embodiment.

FIG. 24 is a timing chart for describing actions of the unit circuit of the shift register configuring the light emission control line deactivation circuit in the first embodiment.

FIG. 25 is a timing chart for describing actions in a normal display mode of the organic EL display device according to the first embodiment.

FIG. 26 is a timing chart for describing actions of the writing control line driving circuit in the first embodiment.

FIG. 27 is a timing chart for describing actions of the monitor control line driving circuit in the first embodiment.

FIG. 28A is a diagram for describing actions in one frame period in the normal display mode, and FIG. 28B is a diagram for describing actions in one frame period in a current measurement mode, in the first embodiment.

FIG. 29 is a timing chart illustrating states of writing control lines and monitor control lines in the current measurement mode in the first embodiment.

FIG. 30 is a circuit diagram for describing actions for measuring a current in the pixel circuit in the first embodiment.

FIG. 31 is a circuit diagram illustrating a configuration of the data-side unit circuit in the data-side driving circuit in the current measurement period in the first embodiment.

FIG. 32 is a flowchart illustrating a control procedure for a characteristics detection process (a series of operations for detecting characteristics of a drive transistor) in the first embodiment.

FIG. 33 is a flowchart illustrating a procedure for a compensation process in a case of focusing on one pixel (pixel at i-th row, j-th column) (a series of operations for compensating variations in characteristics of the drive transistors) in the first embodiment.

FIG. 34 is a diagram illustrating gray scale-current characteristics in the first embodiment.

FIGS. 35A and 35B illustrate diagrams for describing effects in the first embodiment from a viewpoint of an area of a thin film transistor.

FIGS. 36A and 36B illustrate diagrams for describing effects in the first embodiment from a viewpoint of the area of a capacitor as a data holding capacity.

FIGS. 37A and 37B are timing charts for describing actions in a second embodiment of the present invention.

FIG. 38 is a flowchart illustrating a control procedure for a characteristics detection process in the second embodiment.

FIG. 39 is a block diagram for describing a configuration for determining a timing for starting actions in a current measurement mode in the second embodiment.

FIG. 40 is a block diagram for describing a configuration for determining a timing for starting actions in a current measurement mode in a third embodiment of the present invention.

FIGS. 41A and 41B are timing charts for describing actions in the third embodiment.

FIG. 42 is a timing chart for describing a first modified example of each of embodiments of the present invention.

FIG. 43 is a circuit diagram for describing a configuration of a light emission control line driving circuit in the first modified example.

FIG. 44 is a circuit diagram for describing a second modified example of each of the embodiments of the present invention.

FIG. 45 is a circuit diagram illustrating a configuration of a voltage measurement unit circuit in the second modified example.

### DESCRIPTION OF EMBODIMENTS

Embodiments of the present invention will be described below with reference to the accompanying drawings. Note that in each of transistors to be mentioned below, a gate terminal corresponds to a control terminal, and one of a drain terminal and a source terminal corresponds to a first conduction terminal while the other corresponds to a second conduction terminal.

### 1. First Embodiment

### 1.1 Overall Configuration and Action Overview

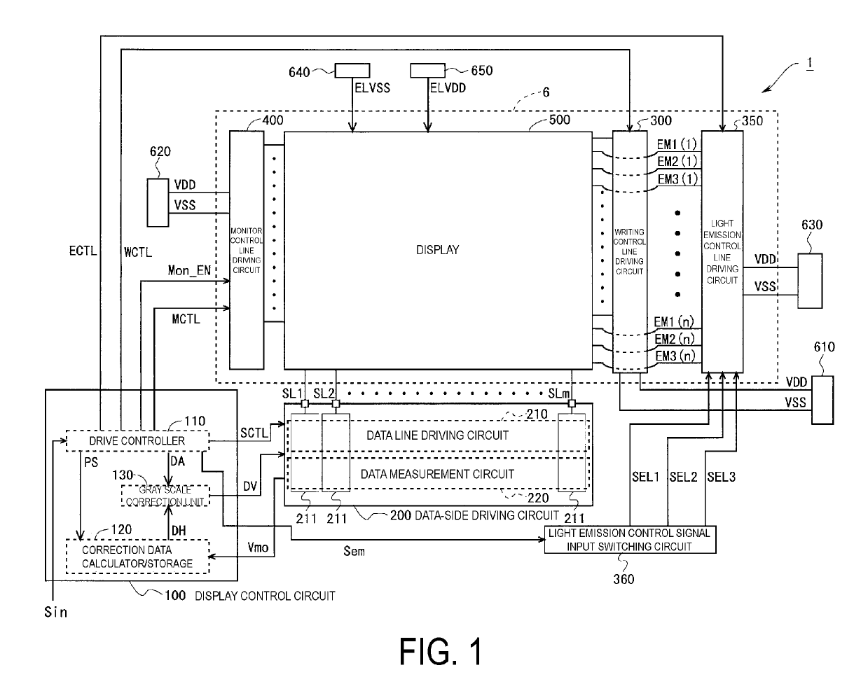

FIG. 1 is a block diagram illustrating an overall configuration of an active-matrix organic EL display device 1 according to a first embodiment of the present invention. The organic EL display device 1 is a display device configured to display color images in a field sequential method and includes a display control circuit 100, a data-side driving circuit 200, a writing control line driving circuit 300, a monitor control line driving circuit 400, a light emission control line driving circuit 350, a light emission control signal input switching circuit 360, and a display 500. The data-side driving circuit 200 functionally includes a data line driving circuit 210 and a current measurement circuit 220. Note that, the writing control line driving circuit 300, the monitor control line driving circuit 400, and the light emission control line driving circuit 350 are formed integrally with the display device 500 in an organic EL panel 6 in the present embodiment, but the present invention is not limited to such a configuration. In addition, logic power sources 610, 620, and 630, an organic EL high level power source 650, and an organic EL low level power source 640 are provided to this organic EL display device 1 as constituent elements for supplying various supply voltages to the organic EL panel 6.

The organic EL panel 6 is supplied with a high level supply voltage VDD and a low level supply voltage VSS necessary for actions of the writing control line driving circuit 300 from the logic power source 610, supplied with a high level supply voltage VDD and a low level supply voltage VSS necessary for actions of the monitor control line driving circuit 400 from the logic power source 620, and supplied with a high level supply voltage VDD and a low level supply voltage VSS necessary for actions of the light emission control line driving circuit 350 from the logic power source 630. Moreover, the organic EL panel 6 is supplied with a high level supply voltage ELVDD from the organic EL high level power source 650 and supplied with a low level supply voltage ELVSS from the organic EL low level power source 640. Note that the high level supply voltage VDD, the low level supply voltage VSS, the organic EL high level supply voltage ELVDD, and the organic EL low level supply voltage ELVSS are all constant voltages (direct-current voltages). In the following, power source lines for supplying the high level supply voltage VDD, the low level supply voltage VSS, the high level supply voltage ELVDD, and the low level supply voltage ELVSS are also denoted respectively by the reference signs “VDD”, “VSS”, “ELVDD”, and “ELVSS”.

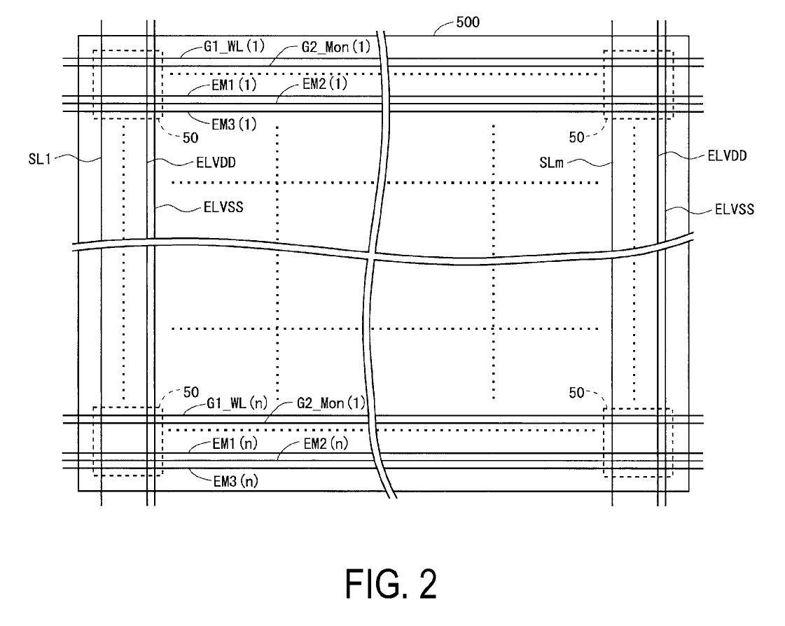

FIG. 2 is a diagram for describing a configuration of the display 500 in the present embodiment. In the display 500, m data lines SL1 to SLm and n writing control lines G1_WL(1) to G1_WL(n) are disposed so as to intersect each other as illustrated in FIG. 2. Pixel circuits 50 are provided at respective intersect points of the data lines SL1 to SLm and the writing control lines G1_WL(1) to G1_WL(n). Specifically, in the display 500, n*m pixel circuits 50 are arranged in a matrix so as to configure a plurality of rows (n rows) along the writing control lines G1_WL(1) to G1_WL(n) and a plurality of columns (m columns) along the data lines SL1 to SLm. Each pixel circuit 50 corresponds to any one of the writing control lines G1_WL(1) to G1_WL(n) and corresponds to any one of the data lines SL1 to SLm. Moreover, in the display 500, n monitor control lines G2_Mon(1) to G2_Mon(n) are disposed so as to correspond one-to-one with the n writing control lines G1_WL(1) to G1_WL(n). Moreover, in the display 500, n first light emission control lines EM1(1) to EM1(n), n second light emission control lines EM2(1) to EM2(n), and n third light emission control lines EM3(1) to EM3(n) are disposed so as to correspond with the n writing control lines G1_WL(1) to G1_WL(n). In addition, in the display 500, high level power source lines ELVDD and low level power source lines ELVSS are disposed. A detailed configuration of the pixel circuits 50 will be described later.

Note that, in the following, in a case where the m data lines SL1 to SLm do not need to be distinguished from each other, the data lines are simply denoted by a reference sign “SL”. Similarly, the writing control lines, the monitor control lines, the first light emission control lines, the second light emission control lines, and the third light emission control lines are simply denoted respectively by reference signs “G1_WL”, “G2_Mon”, “EM1”, “EM2”, and “EM3” in some cases. The first to third light emission control lines EM1 to EM3 are also referred to simply as a “light emission control line” collectively. The light emission control lines are denoted by a reference sign “EM”. In addition, in the following, it is assumed that each transistor (the input transistor T1 in each pixel circuit 50) with a gate terminal connected to the corresponding writing control line G1_WL is in an ON state in a case where the writing control line G1_WL is in an active state (a state in which a high level voltage is supplied in the present embodiment) while being in an OFF state in a case where the writing control line G1_WL is in an inactive state (a state in which a low level voltage is supplied, in the present embodiment). Similarly, it is assumed that a transistor (the monitor control transistor Tm in each pixel circuit 50) with a gate terminal connected to the corresponding monitor control line G2_Mon is in an ON state in a case where the monitor control line G2_Mon is in an active state while being in an OFF state in a case where the monitor control line G2_Mon is in an inactive state. In addition, it is assumed that a transistor (each of the light emission control transistors T3 to T5 in each pixel circuit 50) with a gate terminal connected to the corresponding light emission control line EM is in an ON state in a case where the light emission control line EM is in an active state (a state in which a high level voltage is supplied in the present embodiment) while being in an OFF state in a case where the light emission control line EM is in an inactive state (a state in which a low level voltage is supplied, in the present embodiment).

The display control circuit 100 is typically implemented as an integrated circuit (IC). As illustrated in FIG. 1, the display control circuit 100 includes a drive controller 110, a compensation data calculator/storage 120, and a gray scale correction unit 130 and receives, from an external unit of the display device 1, an input signal Sin including an RGB video data signal Din as image information and an external clock signal CLKin as timing control information.

On the basis of this input signal Sin, the drive controller 110 outputs a writing control signal WCTL for controlling actions of the writing control line driving circuit 300, a monitor control signal MCTL and a monitor enable signal Mon_EN for controlling actions of the monitor control line driving circuit 400, a light emission control signal ECTL for controlling actions of a light emission control line driving circuit 350, a source control signal SCTL for controlling actions of the data-side driving circuit 200, and a light emission switching indication signal Sem for controlling actions of the light emission control signal input switching circuit 360, and also outputs, in the display control circuit 100, a display data signal DA based on the RGB video data signal Din and a gray scale position indication signal PS to be described later. The writing control signal WCTL includes a start pulse signal GSP, a clock signal CLK1, and a clock signal CLK2, to be described later. The monitor control signal MCTL includes a start pulse signal MSP, a clock signal CLK3, and a clock signal CLK4, to be described later. The light emission control signal ECTL includes an activation start pulse signal ESPa, first to third deactivation start pulse signals ESPd1 to ESPd3, the clock signal CLK1, the clock signal CLK2, and a subframe reset signal SUBF_RST, to be described later. The source control signal SCTL includes a start pulse signal SSP, a clock signal SCK, a latch strobe signal LS, and an input/output control signal DWT, to be described later. Note that the monitor enable signal Mon_EN is a signal for controlling whether to enable measurement of a drive current.

The correction data calculator/storage 120 holds correction data to be used for correction of the display data signal DA. The correction data is constituted by an offset value and a gain value. The correction data calculator/storage 120 receives the gray scale position indication signal PS and a monitor voltage Vmo, which is a result of current measurement in the data-side driving circuit 200, and updates the correction data.

The gray scale correction unit 130 performs correction on the display data signal DA output from the drive controller 110 by using correction data DH held in the correction data calculator/storage 120 and outputs the data obtained through the correction as a digital video signal DV. A more detailed description of the constituent elements in the display control circuit 100 will be given later.

The data-side driving circuit 200 selectively performs actions for driving the data lines SL1 to SLm, i.e., actions as the data line driving circuit 210, and actions for measuring a drive current output from each pixel circuit 50 to the corresponding one of the data lines SL1 to SLm, i.e., actions as the current measurement circuit 220. Note that, as described above, the correction data calculator/storage 120 holds an offset value and a gain value as correction data. To update the correction data, measurement of a drive current is performed in the data-side driving circuit 200 on the basis of two kinds of gray scales (a first gray scale P1 and a second gray scale P2: P2>P1).

In the present embodiment, action modes include a normal display mode, in which an image is displayed on the display 500 on the basis of the input signal Sin, and a current measurement mode, in which a current passing through a drive transistor to be described later in each of the pixel circuits 50 connected to either one of the writing control line G1_WL(i) and the monitor control line G2_Mon(i) in one frame period is measured as a drive current. Switching of the action mode between the normal display mode and the current measurement mode may be enabled by including a mode control signal Cm indicating a certain action mode in the input signal Sin or may be enabled by providing a switch for manually switching the action mode in the organic EL display device and thereby generating a mode control signal Cm in accordance with an operation performed on the switch.

In the normal display mode, each of frame periods is divided into the number of subframe periods, the number being equal to the number of primary colors for color image display, i.e., three subframe periods, and pixel data is written into each pixel circuit 50 by sequentially causing the writing control lines G1_WL(1) to G1_WL(n) to turn into an active state in the subframe periods. In the current measurement mode, pixel data is written into each pixel circuit 50 by sequentially causing the writing control lines G1_WL(1) to G1_WL(n) to turn into an active state in the frame periods without dividing each frame period into a plurality of subframe periods, and a current passing through the drive transistor to be described later in each pixel circuit 50 connected to either one of the writing control line G1_WL(i) and the monitor control line G2_Mon(i) in one frame period is measured as a drive current. Note that in the following, a period in which actions for writing pixel data into the pixel circuit 50 in any of the current measurement mode and the normal display mode are performed is referred to as a “normal action period”, and the period in which actions for detecting characteristics of the drive transistor by measuring a drive current in the current measurement mode are performed is referred to as a “characteristics detection process period”. The data-side driving circuit 200 acts as a data line driving circuit 210 in the normal action period while acting as a current measurement circuit 220 in a period of measuring a current passing through each drive transistor (referred to as a “current measurement period” below) in the characteristics detection process period. In the normal display mode, each subframe period is constituted only by the normal action period; meanwhile, in the current measurement mode, each frame period is constituted by the normal action period and the characteristics detection process period including the current measurement period (to be described later in detail).

The writing control line driving circuit 300 drives the writing control lines G1_WL(1) to G1_WL(n) on the basis of the writing control signal WCTL from the display control circuit 100. The monitor control line driving circuit 400 drives the monitor control lines G2_Mon(1) to G2_Mon(n) on the basis of the monitor control signal MCTL and the monitor enable signal Mon_EN from the display control circuit 100 (to be described later in detail). Note that the monitor control line driving circuit 400 sets the monitor enable signal Mon_EN at inactive (low level) in the normal action period to cause all the monitor control lines G2_Mon(1) to G2_Mon(n) to change to an inactive state, i.e., a low level.

The light emission control line driving circuit 350 outputs light emission enable signals to be supplied to the light emission control lines EM1(1) to EM1(n), EM2(1) to EM2(n), and EM3(1) to EM3(n), on the basis of the light emission control signal ECTL from the display control circuit 100 and selection signals SEL1 to SEL3 to be described later output from the light emission control signal input switching circuit 360. The light emission control line driving circuit 350 will be described later in detail.

The light emission control signal input switching circuit 360 outputs the first to third selection signals SEL1, SEL2, and SEL3 on the basis of the light emission switching indication signal Sem from the display control circuit 100, and functions as a selection signal generation circuit. In the present embodiment, as has been already described above, each frame period is divided into the number of subframe periods that is equal to the number of primary colors for color image display, i.e., three subframe periods including first to third subframe periods. The first to third selection signals SEL1, SEL2, and SEL3 are sequentially changed to active (high level) in respective subframe periods. Hence, the first selection signal SEL1 is in a high level in the first subframe period, the second selection signal SEL2 is in a high level in the second subframe period, and the third selection signal SEL3 is in a high level in the third subframe period.

As will be described later, one pixel circuit row is a unit of measurement target (this measurement target pixel circuit row is also referred to as a “compensation target row” below) in the current measurement period. Here, the pixel circuit row is a pixel circuit group constituted by m pixel circuits 50 aligned along a direction in which the writing control line G1_WL(i) extends (horizontal direction) in the display 500 and is also referred to simply as a “row” below. In the current measurement mode, to perform measurement more reliably and accurately, at least first to third light emission control lines EM1(It), EM2(It), and EM3(It) corresponding to the compensation target row are preferably in an inactive state (a state where a low level voltage is supplied). In the present embodiment, all the light emission control lines EM1(1) to EM1(n), EM2(1) to EM2(n), and EM3(1) to EM3(n) are in an inactive state in the current measurement mode. Consequently, in each of all the pixel circuits 50, the drive transistor is electrically separated from the organic EL elements, and all the organic EL elements are in a lit-out state. Moreover, in the current measurement mode, the monitor control line driving circuit 400 supplies an active signal (a high level voltage in the present embodiment) to the monitor control line G2_Mon(It) corresponding to the compensation target row, to cause the monitor control line G2_Mon(It) to be in an active state.

The constituent elements act as described above to drive the data lines SL1 to SLm, the writing control lines G1_WL(1) to G1_WL(n), the monitor control lines G2_Mon(1) to G2_Mon(n), and the light emission control lines EM1(1) to EM1(n), EM2(1) to EM2(n), and EM3(1) to EM3(n), whereby an image is displayed on the display 500 in the normal display mode, and a drive current in the measurement target pixel circuit 50 is measured in the current measurement period in the current measurement mode. In the present embodiment, correction is made to the display data signal DA on the basis of a result of measurement of drive currents, which compensates variations in characteristics of the drive transistors.

### 1.2 Pixel Circuit and Data-Side Driving Circuit

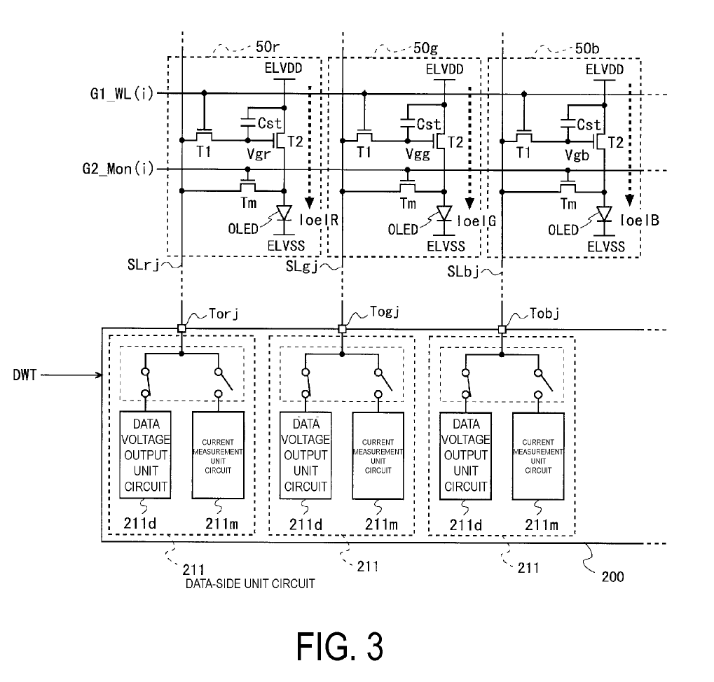

FIG. 3 is a circuit diagram illustrating a configuration of a pixel circuit of a known organic EL display device using the external compensation method. In this known organic EL display device, each of pixels of an image to be displayed is constituted by an R sub pixel, a G sub pixel, and a B sub pixel, and an R pixel circuit 50r, a G pixel circuit 50g, a B pixel circuit 50b for respectively forming the R sub pixel, the G sub pixel, and the B sub pixel are disposed adjacent to each other in the horizontal direction (the direction in which the writing control line G1_WL(i) extends) in the display 500. In the display 500, an R data line SLrj connected to n R pixel circuits 50r aligned in the vertical direction, a G data line SLgj connected to n G pixel circuits 50g aligned in the vertical direction, and a B data line SLbj connected to n B pixel circuits 50b aligned in the vertical direction (j=1 to m) are arranged in the above pixel configuration.

The R pixel circuit 50r includes an organic EL element OLED as one light emitting type display element emitting red light, three N channel type transistors (each referred to briefly as an “Nch transistor” below) T1, T2, and Tm, and one capacitor Cst. The transistor T1 functions as an input transistor with a gate terminal connected to the writing control line G1_WL(i) to select the pixel, the transistor T2 functions as a drive transistor controlling supply of a current to the organic EL element OLED according to the voltage held by the capacitor Cst, and the transistor Tm functions as a monitor control transistor with a gate terminal connected to the monitor control line G2_Mon(i) to control whether to perform current measurement for detection of characteristics of the drive transistor. The capacitor Cst functions as a data holding capacity for holding a data voltage indicating the value of the R sub pixel (luminance value) (this capacitor is also referred to as a “data holding capacity” below). The G pixel circuit 50g includes an organic EL element (OLED) emitting green light, instead of the OLED configured to emit red light, but otherwise has a similar configuration to that of the R pixel circuit 50r. The B pixel circuit 50b includes an organic EL element (OLED) emitting blue light, instead of the OLED configured to emit red light, but otherwise has a similar configuration to that of the R pixel circuit 50r.

The data-side driving circuit 200 in this known organic EL display device includes output terminals Torj, Togj, and Tobj to which the data lines SLrj, SLgj, and SLbj are connected respectively (j=1 to m) as illustrated in FIG. 3. The data-side driving circuit 200 includes data-side unit circuits 211 connected to the respective output terminals Torj, Togj, and Tobj. Each data-side unit circuit 211 includes a data voltage output unit circuit 211d, a current measurement unit circuit 211m, and a switching switch SW and has a configuration that the switching switch SW is controlled in accordance with an input/output control signal DWT included in the source control signal SCTL from the display control circuit 100 to thereby switch the unit circuit connected to a corresponding one of the data lines SLxj (x=r, g, b) between the data voltage output unit circuit 211d and the current measurement unit circuit 211m. With this configuration, each data line SLxj is connected to the data voltage output unit circuit 211d when the data-side driving circuit 200 functions as the data line driving circuit 210 while being connected to the current measurement unit circuit 211m when the data-side driving circuit 200 functions as the current measurement circuit 220.

In the known organic EL display device as that described above, display of an image configured by n*m pixels requires 3*n*m pixel circuits 50x and 3m data-side unit circuits 211, and each one of the pixel circuits 50x (x=r, g, b) is constituted by three transistors T1, T2, Tm, one capacitor Cst, and one organic EL element OLED.

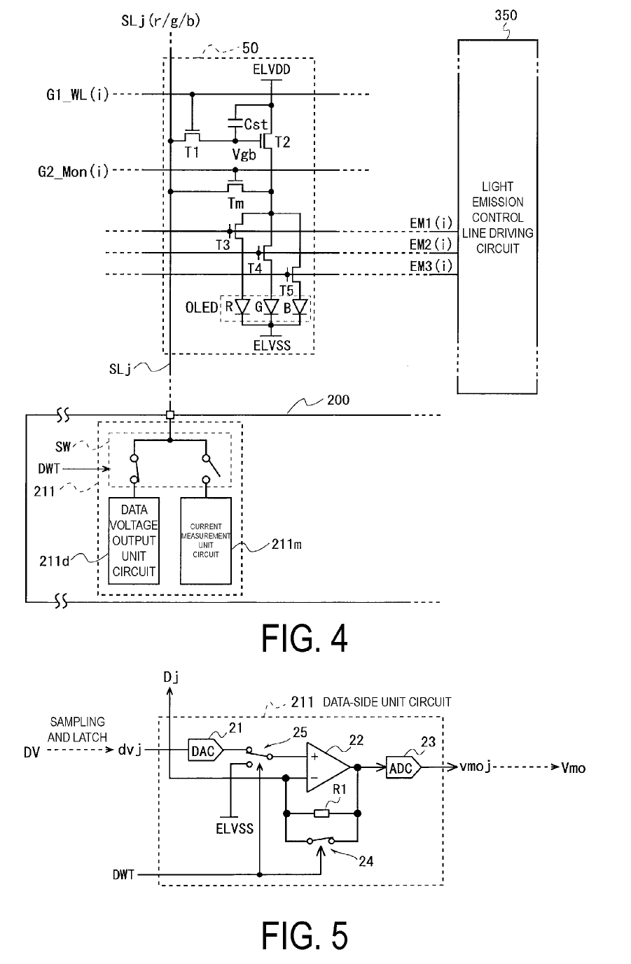

FIG. 4 is a circuit diagram for describing a configuration of the pixel circuits in the present embodiment. As illustrated in FIG. 4, in the present embodiment, the pixel circuit 50 for forming each of pixels of an image to be displayed, is provided in the display 500. Each pixel circuit 50 corresponds to any one of the n writing control lines G1_WL(1) to G1_WL(n), any one of n monitor control lines G2_Mon(1) to G2_Mon(n), any one of the n first light emission control lines EM1(1) to EM1(n), any one of the n second light emission control lines EM2(1) to EM2(n), and any one of the n third light emission control lines EM3(1) to EM3(n).

Each pixel circuit 50 includes one display element group constituted by first to third organic EL elements OLED configured to emit red light, green light, and blue light respectively (indicated by respective reference signs “OLED(R)”, “OLED(G)”, and “OLED(B)” below when distinguishing the organic EL elements from each other), six Nch transistors T1 to T5 and Tm, and one capacitor Cst. The transistor T1 functions as an input transistor configured to select a pixel, the transistor T2 functions as a drive transistor configured to control current supply to the organic EL element selected by the light emission control transistors T3 to T5 to be described later among the three organic EL elements OLED(R), OLED(G), and OLED(B), the transistor Tm functions as a monitor control transistor configured to control whether to perform current measurement for detection of characteristics of the drive transistor, and the transistors T3 to T5 function as light emission control transistors. The capacitor Cst functions as a data holding capacity for holding a data voltage indicating pixel data (a voltage indicating the value (luminance) of a red pixel, a green pixel, or a blue pixel). Note that all the transistors other than the transistor T2 among the transistors T1 to T5 and Tm in each pixel circuit 50 act as switching elements.

The input transistor T1 is disposed between the data line SLj and the gate terminal of the transistor T2. The gate terminal and a source terminal of the input transistor T1 are connected respectively to the writing control line G1_WL(i) and the data line SLj. The drive transistor T2 includes a drain terminal connected to the high level power source line ELVDD, and the data holding capacity Cst is connected between the drain terminal and the gate terminal of the drive transistor T2. A source terminal of the drive transistor T2 is connected to the data line SLj via the monitor control transistor Tm, and the monitor control line G2_Mon(i) is connected to the gate terminal of the monitor control transistor Tm.

The drive transistor T2 is connected to each of the first to third organic EL elements OLED(R), OLED(G), and OLED(B) in series and is also connected to the first to third light emission control transistors T3 to T5 in series. Specifically, the first light emission control transistor T3 is connected to the first organic EL element OLED(R) in series to control supply/block of a drive current to the first organic EL element OLED(R), the second light emission control transistor T4 is connected to the second organic EL element OLED(G) in series to control supply/block of a drive current to the second organic EL element OLED(G), and the third light emission control transistor T5 is connected to the third organic EL element OLED(B) in series to control supply/block a drive current to the third organic EL element OLED(B). In the example illustrated in FIG. 4, the source terminal of the drive transistor T2 is connected to drain terminals of the first to third light emission control transistors T3 to T5. The source terminal of the first light emission control transistor T3 is connected to the anode of the first organic EL element OLED(R), the source terminal of the second light emission control transistor T4 is connected to the anode of the second organic EL element OLED(G), and the source terminal of the third light emission control transistor T5 is connected to the anode of the third organic EL element OLED(B). The cathodes of the first to third organic EL elements OLED(R), OLED(G), and OLED(B) are connected to the low level power source line ELVSS.

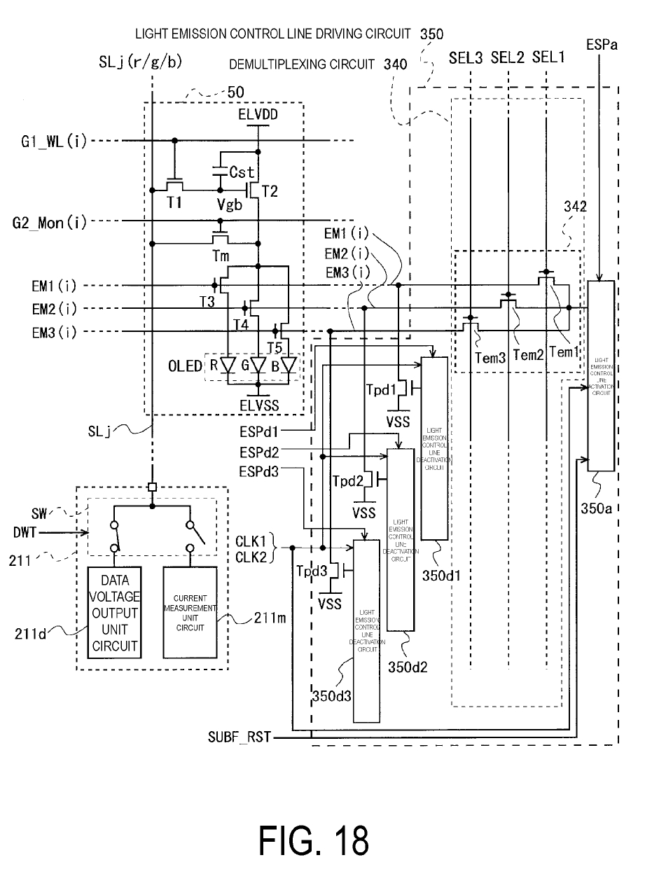

The first to third light emission control lines EM1(i), EM2(i), and EM3(i) are connected to the respective gate terminals of the first to third light emission control transistors T3 to T5. As has already been described, a light emission enable signal GGem(i) generated by the light emission control line driving circuit 350 is supplied to the first to third light emission control lines EM1(i), EM2(i), and EM3(i) in a time division manner by a demultiplexer 342 in the light emission control line driving circuit 350 (refer to FIG. 18 to be described later).

In the present embodiment, the transistors T1 to T5 and Tm in the pixel circuit 50 are all N-channel type but may adopt a configuration using a P-channel type TFT. A thin film transistor (abbreviated as “TFT” below) in which a channel layer is formed of an oxide semiconductor, is adopted as each of the transistors T1 to T5 and Tm. The same applies to the transistors in the writing control line driving circuit 300, the monitor control line driving circuit 400, and the light emission control line driving circuit 350. The present invention is also applicable to a configuration using transistors each of which includes a channel layer made of amorphous silicon, polysilicon, microcrystalline silicon, continuous grain silicon (continuous grain silicon), or the like.

An oxide semiconductor layer included in each TFT used in the present embodiment is, for example, an In—Ga—Zn—O based semiconductor layer. The oxide semiconductor layer includes an In—Ga—Zn—O based semiconductor, for example. The In—Ga—Zn—O based semiconductor is ternary oxide of indium (In), gallium (Ga), and zinc (Zn). The ratio (composition ratio) of In, Ga, and Zn is not particularly limited. For example, the ratio may be In:Ga:Zn=2:2:1, In:Ga:Zn=1:1:1, In:Ga:Zn=1:1:2, or the like. A TFT including the In—Ga—Zn—O based semiconductor layer has high mobility (20 times greater mobility than that of an amorphous silicon TFT) and small leak current (leak current smaller than 1/100 of that of an amorphous silicon TFT) and is hence preferably used as each of the transistors T1 to T5 and Tm in the pixel circuit 50. In the present embodiment, not only the pixel circuit 50 corresponding to one monitor control line G2_Mon that is in an active state in the current measurement mode but also the pixel circuits 50 corresponding to n−1 monitor control lines G2_Mon in an inactive state are connected to each of the data lines SLj. Hence, using, as the monitor control transistor Tm, a TFT having a minimal leak current as described above is particularly effective to increase the accuracy in current measurement for detection of the characteristics of the drive transistor T2 in each pixel circuit 50.

The data-side driving circuit 200 in the present embodiment includes one data-side unit circuit 211 for each of the data lines SL1 to SLm as illustrated in FIG. 1. As illustrated in FIG. 4, this data-side unit circuit 211, similar to the data-side unit circuit 211 (FIG. 3) in the known organic EL device using the external compensation method, includes the data voltage output unit circuit 211d, the current measurement unit circuit 211m, and the switching switch SW and has a configuration that the switching switch SW is controlled in accordance with the input/output control signal DWT included in the source control signal SCTL from the display control circuit 100 to thereby switch the unit circuit connected to the data line SLj between the data voltage output unit circuit 211d and the current measurement unit circuit 211m. With this configuration, each data line SLj is connected to the data voltage output unit circuit 211d when the data-side driving circuit 200 functions as the data line driving circuit 210 while being connected to the current measurement unit circuit 211m when the data-side driving circuit 200 functions as the current measurement circuit 220.

As is apparent from comparison between FIG. 3 and FIG. 4, according to the present embodiment described above, although the light emission control line driving circuit 350 is necessary, the R pixel circuit 50r, the G pixel circuit 50g, and the B pixel circuit 50b for forming one pixel in the known organic EL display device using the external compensation method are implemented by one pixel circuit 50, and accordingly, each of the number of data lines SL and the number of data-side unit circuits 211 is reduced to one-third of that of the known organic EL display device using the external compensation method. In other words, in the present embodiment, to display an image constituted of n*m pixels, n*m pixel circuits 50, m data-side unit circuits 211, n demultiplexers 342, and the light emission control line driving circuit 350 are needed. Here, one pixel circuit 50 is constituted by six transistors T1 to T5 and Tm, one capacitor Cst, and three organic EL elements OLED(R), OLED(G), and OLED(B).

FIG. 5 is a circuit diagram illustrating a configuration example of the data-side unit circuit 211 in the data-side driving circuit 200. The data-side unit circuit 211 illustrated in FIG. 5 includes a DA converter 21, an operational amplifier 22, a resistance element R1, a first switch 24, a second switch 25, and an AD converter 23. A digital video signal DV (more precisely, a digital signal dvj obtained from sampling and latch) is supplied to an input terminal of the DA converter 21, and the input/output control signal DWT included in the source control signal SCTL is supplied to each of the first switch 24 and the second switch 25 as a control signal. This input/output control signal DWT is in a low level in a current measurement period while being in a high level in periods other than the current measurement period. The second switch 25 is a switching switch including two input terminals, to one of which the output terminal of the DA converter 21 is connected and to the other of which a low level power source line ELVSS is connected, and an output terminal connected to a noninverting input terminal of the operational amplifier 22. With this second switch 25, the noninverting input terminal of the operational amplifier 22 is supplied with an analog signal corresponding to the digital video signal DV (more precisely, the digital signal dvj) when the input/output control signal DWT is in a high level while being supplied with the low level supply voltage ELVSS when the input/output control signal DWT is in a low level. The DA converter 21 converts this digital video signal DV into an analog data voltage. The noninverting input terminal of the operational amplifier 22 is connected to the data line SLj. The first switch 24 is provided between the noninverting input terminal and the output terminal of the operational amplifier 22. The resistance element R1 is provided between the noninverting input terminal and the output terminal of the operational amplifier 22 in parallel to the first switch 24. The output terminal of the operational amplifier 22 is connected to the input terminal of the AD converter 23.

With the above-described configuration, the first and second switches 24 and 25 correspond to the switching switch SW in the data-side unit circuit 211 illustrated in FIG. 4, and when the input/output control signal DWT is in a high level, the first switch 24 is in an ON state and the second switch 25 outputs, as a data voltage, an analog signal corresponding to the digital video signal DV. Through this, a short-circuit is established between the noninverting input terminal and the output terminal of the operational amplifier 22 to supply a data voltage corresponding to the digital video signal DV to the noninverting input terminal of the operational amplifier 22. Consequently, the operational amplifier 22 functions as a buffer amplifier to apply, as an analog video signal (referred to as a “drive data signal” or simply as a “data signal” below) Dj, the data voltage supplied to the noninverting input terminal of the operational amplifier 22, to the data line SLj corresponding to this data-side unit circuit 211.

In contrast, when the input/output control signal DWT is in a low level, the first switch 24 is in an off state while the second switch 25 outputs the low level supply voltage ELVSS. Through this operation, the noninverting input terminal and the output terminal of operational amplifier 22 are connected via the resistance element R1 to supply the low level supply voltage ELVSS to the noninverting input terminal of the operational amplifier 22. Consequently, the operational amplifier 22 outputs a voltage corresponding to a drive current output to the data line SLj from the pixel circuit 50 connected to the monitor control line G2_Mon(i) supplied with a high level voltage among the pixel circuits 50 connected to the data line SLj. The output voltage from the operational amplifier 22 is converted into a digital value by the AD converter 23 and is then output as a monitor voltage vmoj. The monitor voltage vmoj output from each of the data-side unit circuit 211 is transmitted to the correction data calculator/storage 120 in the display control circuit 100 as a current measurement result Vmo obtained in the current measurement circuit 220.

As descried above, the data-side unit circuit 211 functions as the current measurement unit circuit 211m in the current measurement period due to the input/output control signal DWT turned into a low level, while functioning as the data voltage output unit circuit 211d in each period other than the current measurement period due to the input/output control signal DWT turned into a high level. Hence, the data-side driving circuit 200 functions as the current measurement circuit 220 in the current measurement period while functioning as the data line driving circuit 210 in each period other than the current measurement period.

### 1.3 Display Control Circuit

Next, a detailed configuration and actions of the display control circuit 100 in the present embodiment will be described.

### 1.3.1 Drive Controller

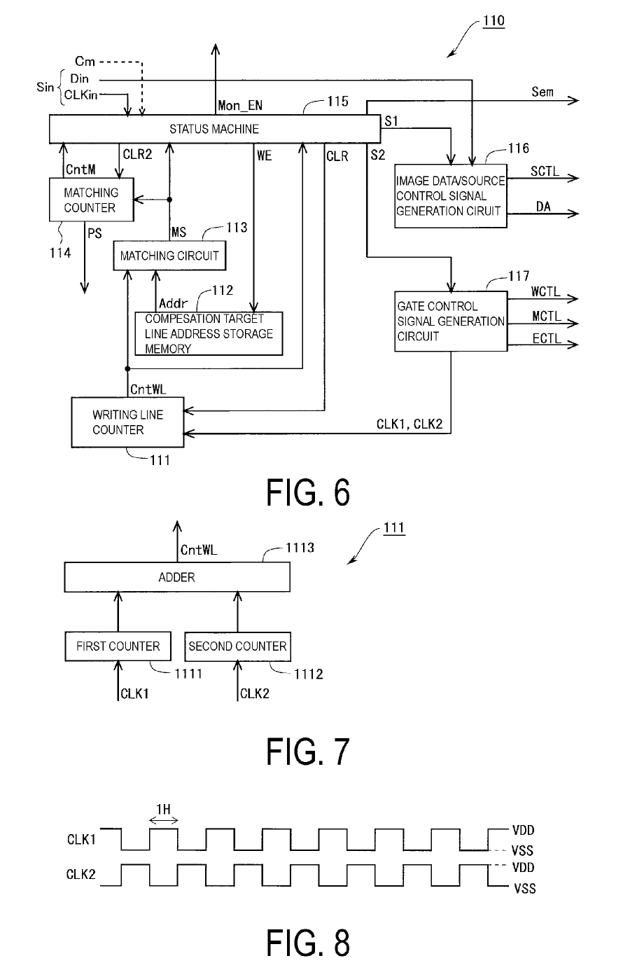

FIG. 6 is a block diagram illustrating a detailed configuration of the drive controller 110 in the display control circuit 100. As illustrated in FIG. 6, the drive controller 110 includes a writing line counter 111, a compensation target line address storage memory 112, a matching circuit 113, a matching counter 114, a status machine 115, an image data/source control signal generation circuit 116, and a gate control signal generation circuit 117. Among the input signal Sin from an external unit, an external clock signal CLKin is supplied to the status machine 115, and an RGB video data signal Din is supplied to the image data/source control signal generation circuit 116.

The status machine 115 is a sequential circuit for which an output signal and the next interior state are determined on the basis of an input signal and the current interior state, and performs concrete actions as follows. Specifically, the status machine 115 outputs a control signal 51, a control signal S2, a monitor enable signal Mon_EN, and a light emission switching indication signal Sem on the basis of the external clock signal CLKin and a matching signal MS. Moreover, the status machine 115 outputs a clear signal CLR for initializing the writing line counter 111 and a clear signal CLR2 for initializing the matching counter 114. Further, the status machine 115 outputs a rewrite signal WE for updating a compensation target line address Addr stored in the compensation target line address storage memory 112.

FIG. 7 is a block diagram illustrating a configuration of the writing line counter 111. As illustrated in FIG. 7, the writing line counter 111 is constituted by: a first counter 1111 configured to count the number of clock pulses in the clock signal CLK1 output from the gate control signal generation circuit 117; a second counter 1112 configured to count the number of clock pulses in the clock signal CLK2 output from the gate control signal generation circuit 117; and an adder 1113 configured to output, as a writing count value CntWL, a value indicating the sum of an output value of the first counter 1111 and an output value of the second counter 1112. Here, the clock signals CLK1 and CLK2 are the same as the clock signals CLK1 and CLK2 included in the writing control signal WCTL. The clock signals CLK1 and CLK2 change as illustrated in FIG. 8 in the normal action period and have phases shifted by 180 degrees from each other. The writing line counter 111 is configured so that, after the occurrence of a pulse of a start pulse signal GSP, the writing count value CntWL is set at 1 at the time when the clock signal CLK1 rises for the first time. After the rising of the first clock signal CLK1, the writing count value CntWL increments by 1 every time either the clock signal CLK1 or the clock signal CLK2 rises. Note that the writing count value CntWL output from the writing line counter 111 is initialized to zero by the clear signal CLR from the status machine 115.

In the compensation target line address storage memory 112 in the drive controller 110 illustrated in FIG. 6, an address (referred to as a “compensation target line address” below) Addr indicating the row for which measurement of a drive current is to be performed next (compensation target row) is stored. The compensation target line address Addr stored in the compensation target line address storage memory 112 is rewritten by the rewrite signal WE output from the status machine 115. Note that, herein, a description will be given by assuming that a value representing the compensation target row is defined in the compensation target line address Addr. For example, when the compensation target row is the fifth row, the compensation target line address indicates “5”.

The matching circuit 113 determines whether the writing count value CntWL output from the writing line counter 111 and the compensation target line address Addr stored in the compensation target line address storage memory 112 match, and outputs the matching signal MS indicating a result of the determination. Note that the writing count value CntWL and the compensation target line address Addr are represented by the same number of bits. In the present embodiment, when the writing count value CntWL and the compensation target line address Addr match, the matching signal MS is set at a high level; when the writing count value CntWL and the compensation target line address Addr do not match, the matching signal MS is set at a low level. The matching signal MS output from the matching circuit 113 is supplied to the status machine 115 and the matching counter 114.

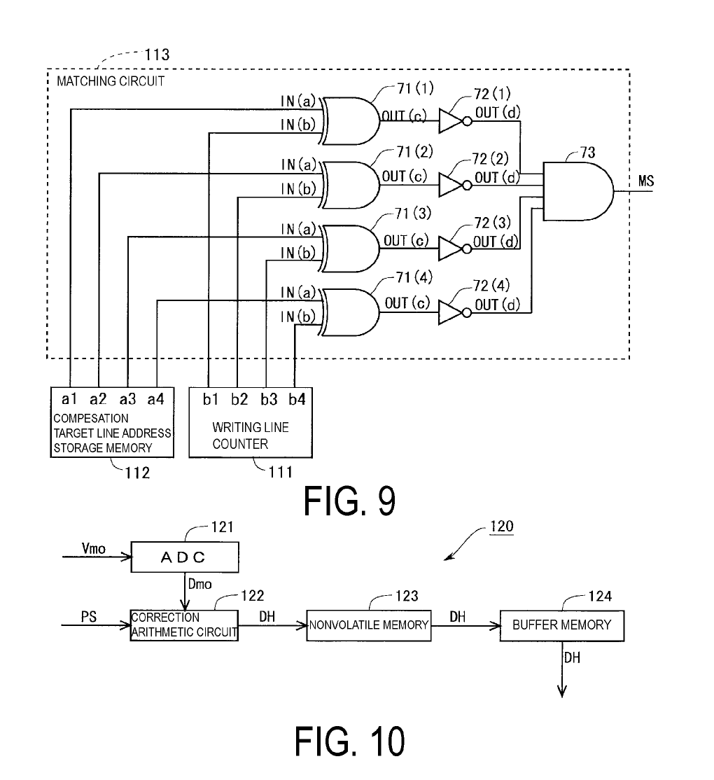

FIG. 9 is a logical circuit diagram illustrating a configuration of the matching circuit 113 in the present embodiment. This matching circuit 113 is constituted by four exclusive OR circuits (EXOR circuits) 71(1) to 71(4), four inverters (logical NOT circuits) 72(1) to 72(4), and one AND circuit 73 (logical AND circuit). The EXOR circuits 71(1) to 71(4) and the inverters 72(1) to 72(4) have one-to-one correspondence. One of input terminals of each of the EXOR circuits 71 is supplied with 1-bit data of 4-bit data indicating the compensation target line address Addr stored in the compensation target line address storage memory 112, as first input data IN(a). The other input terminal of each of the EXOR circuits 71 is supplied with 1-bit data of 4-bit data (writing count value CntWL) output from the writing line counter 111, as second input data IN(b). Each of the EXOR circuits 71 outputs, as first output data OUT(c), a value indicating the exclusive OR of a logical value of the first input data IN(a) and a logical value of the second input data IN(b). The input terminal of each of the inverters 72 is provided with first output data OUT(c) output from the corresponding EXOR circuit 71. Each of the inverters 72 outputs, as second output data OUT(d), the value obtained by inverting the logical value of the first output data OUT(c) (i.e., the value indicating the logical NOT of the logical value of the first output data OUT(c)). The AND circuit 73 outputs, as the matching signal MS, a value indicating the logical AND of four second output data OUT(d) output from the inverters 72(1) to 72(4). Note that, although an example of comparing 4-bit data is described here, 10 EXOR circuits 71 and 10 inverters 72 are provided to compare 10-bit data in an actual case, for example. In other words, the larger the number of writing control lines G1_WL becomes, the larger the numbers of EXOR circuits 71 and inverters 72 may be set. Note that the matching circuit 113 is not limited to the configuration illustrated in FIG. 9 and may, for example, have a configuration using a NOR circuit (negative OR circuit) instead of the inverters 72(1) to 72(4) and the AND circuit 73 in the present embodiment.

In the present embodiment, the writing control lines G1_WL sequentially turn into an active state on the basis of the clock signals CLK1 and CLK2 after the occurrence of a pulse of the start pulse signal GSP. Moreover, the writing count value CntWL output from the writing line counter 111 is incremented by 1 on the basis of the clock signals CLK1 and CLK2. Accordingly, the writing count value CntWL represents the value of the row of the writing control line G1_WL to be turned into an active state. For example, assume that the clock signal CLK1 rises at a certain time point tx and the writing count value CntWL changes to “50”. Then, the 50-th writing control line G1_WL(50) is in an active state for one horizontal interval from the time point tx. Moreover, the compensation target line address Addr indicating the compensation target row is stored in the compensation target line address storage memory 112, and hence the time point at which the writing count value CntWL and the compensation target line address Addr match is the start time point of the characteristics detection process period.

In the drive controller 110 illustrated in FIG. 6, the matching counter 114 outputs a matching count value CntM. This matching count value CntM is initialized (set at “0”) and then incremented by 1 every time the matching signal MS changes from a low level to a high level. Moreover, the matching counter 114 outputs a gray scale position indication signal PS for identifying whether measurement of a drive current is performed on the basis of the first gray scale P1 or measurement of a drive current is performed on the basis of the second gray scale P2. Note that the matching counter 114 is initialized by a clear signal CLR2 output from the status machine.

The image data/source control signal generation circuit 116 outputs the source control signal SCTL and the display data signal DA on the basis of the RGB video data signal Din included in the input signal Sin from an external unit and a control signal 51 supplied from the status machine 115. Note that the control signal 51 includes a signal indicating, for each frame period, whether to start a compensation process (a series of operations for compensating variations in characteristics of the drive transistors) or to start normal actions. The gate control signal generation circuit 117 outputs the writing control signal WCTL, the monitor control signal MCTL, and the light emission control signal ECTL on the basis of the control signal S2 provided from the status machine 115. Note that the control signal S2 includes a signal based on the external clock signal CLKin included in the input signal Sin, for example, a signal controlling clock actions of the clock signals CLK1 to CLK4, and a signal indicating output of each pulse of a start pulse signal GSP and MSP, an activation start pulse signal ESPa, and first to third deactivation start pulse signals ESPd1 to ESPd3.

### 1.3.2 Gray Scale Correction Unit

The gray scale correction unit 130 included in the display control circuit 100 in the configuration illustrated in FIG. 1 reads correction data DH (an offset value and a gain value) held in the correction data calculator/storage 120 and correction on the display data signal DA output from the drive controller 110. The gray scale correction unit 130 then outputs, as the digital video signal DV, a gray scale voltage obtained as a result of the correction. This digital video signal DV is transmitted to the data-side driving circuit 200.

### 1.3.3 Correction Data Calculator/Storage

FIG. 10 is a block diagram illustrating a configuration of the correction data calculator/storage 120 in the display control circuit 100. As illustrated in FIG. 10, the correction data calculator/storage 120 includes an AD converter 121, a correction arithmetic circuit 122, a nonvolatile memory 123, and a buffer memory 124. The AD converter 121 converts the monitor voltage Vmo (analog voltage) output from the data-side driving circuit 200, into the digital signal Dmo. The correction arithmetic circuit 122 obtains correction data (an offset value and a gain value) to be used for correction at the gray scale correction unit 130, on the basis of the digital signal Dmo. In this operation, the gray scale position indication signal PS output from the matching counter 114 is referred to, to determine whether the digital signal Dmo output from the AD converter 121 is data based on the first gray scale P1 or data based on the second gray scale P2. The correction data DH obtained at the correction arithmetic circuit 122 is held by the nonvolatile memory 123. Specifically, the offset value and the gain value for each pixel circuit 50 are held by the nonvolatile memory 123. When the gray scale correction unit 130 performs correction on the display data signal DA, the correction data DH temporarily read from the nonvolatile memory 123 to the buffer memory 124 is used.

### 1.4 Configuration of Writing Control Line Driving Circuit

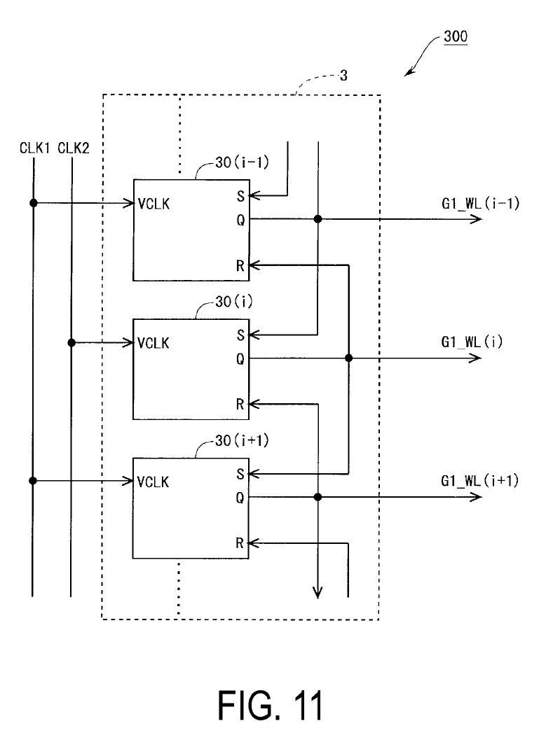

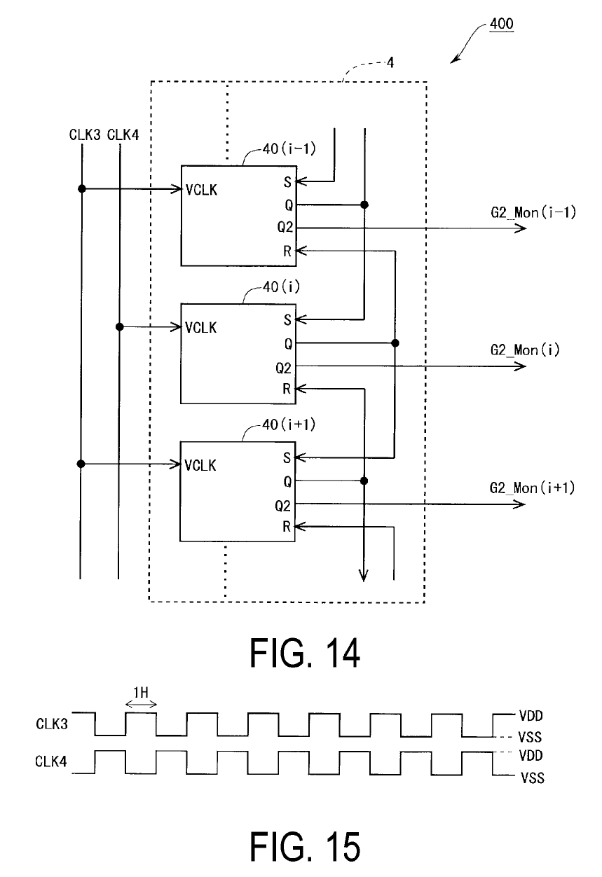

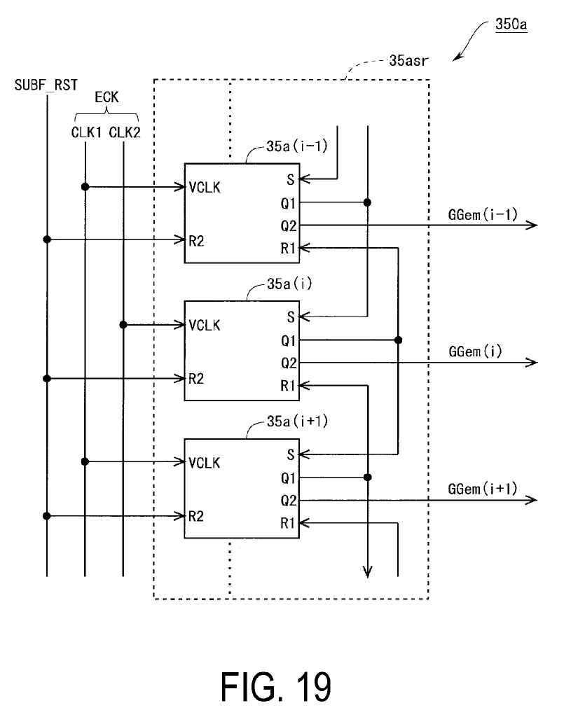

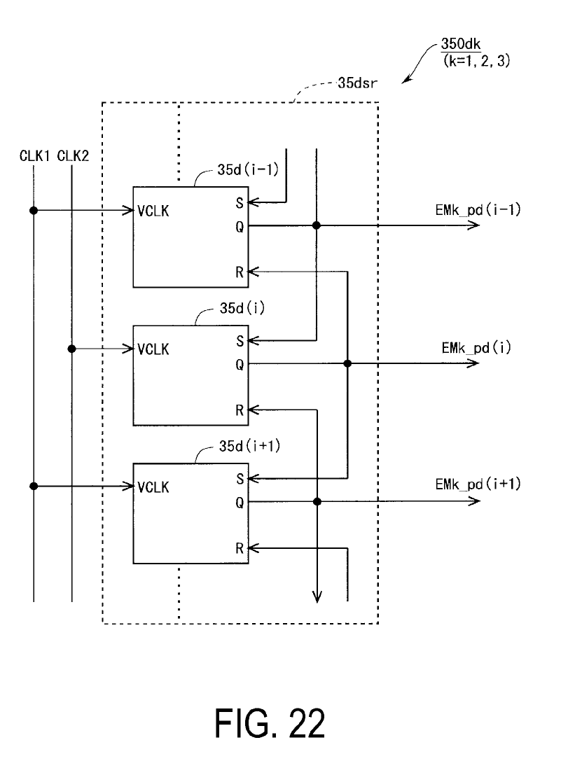

FIG. 11 is a block diagram illustrating a configuration of the writing control line driving circuit 300 in the present embodiment. The writing control line driving circuit 300 is implemented by using the shift register 3. Stages of the shift register 3 are provided having a one-to-one correspondence with the writing control lines G1_WL in the display 500. In other words, in the present embodiment, the shift register 3 of n stages is included in the writing control line driving circuit 300. Note that FIG. 11 illustrates only unit circuits 30(i−1) to 30(i+1) forming (i−1)-th to (i+1)-th stages of the n stages. For the convenience of description, i is assumed to be an even number (the same applies to FIG. 14, FIG. 19, and FIG. 22). Each stage (each unit circuit) of the shift register 3 is provided with an input terminal configured to receive a clock signal VCLK, an input terminal configured to receive a set signal S, an input terminal configured to receive a reset signal R, and an output terminal configured to output a state signal Q indicating an interior state of the corresponding stage.

As illustrated in FIG. 11, signals supplied to the input terminals of each stage (each unit circuit) of the shift register 3 are as follows. At each odd-numbered stage, the clock signal CLK1 is supplied as the clock signal VCLK, while at each even-numbered stage, the clock signal CLK2 is supplied as the clock signal VCLK. Moreover, at a certain stage, the state signal Q output from the previous stage is supplied as the set signal S, and the state signal Q output from the next stage is supplied as the reset signal R. However, for the first stage (not illustrated in FIG. 11), the start pulse signal GSP is supplied as the set signal S. Note that the low level supply voltage VSS (not illustrated in FIG. 11) is supplied to all the unit circuits 30 in common. Each stage of the shift register 3 outputs the state signal Q. The state signal Q output from each stage is output to the corresponding writing control line G1_WL and also supplied to the previous stage as the reset signal R while being supplied to the next stage as the set signal S.

FIG. 12 is a circuit diagram illustrating a configuration of each of the unit circuits 30 of the shift register 3 configuring the writing control line driving circuit 300 (configuration corresponding to one stage of the shift register 3). As illustrated in FIG. 12, the unit circuit 30 includes four transistors T31 to T34. Moreover, the unit circuit 30 includes three input terminals 31 to 33 and one output terminal 38 in addition to a low level supply voltage VSS input terminal. Here, the input terminal configured to receive the set signal S is denoted by a reference sign “31”, the input terminal configured to receive the reset signal R is denoted by a reference sign “32”, and the input terminal configured to receive the clock signal VCLK is denoted by a reference sign “33”. Moreover, the output terminal configured to output the state signal Q is denoted by a reference sign “38”. A parasitic capacitance Cgd is formed between the gate terminal and the drain terminal of the transistor T32, and a parasitic capacitance Cgs is formed between the gate terminal and the source terminal of the transistor T32. The source terminal of the transistor T31, the gate terminal of the transistor T32, and the drain terminal of the transistor T34 are connected to each other. Note that each region (wiring line) where the terminals are connected to each other is referred to as a “first node” below. The first node is denoted by a reference sign “N1”.

The transistor T31 is connected, at the gate terminal and the drain terminal thereof, to the input terminal 31 (i.e., a diode connection is established) and is connected, at the source terminal thereof, to the first node N1. The transistor T32 is connected, at the gate terminal thereof, to the first node N1, is connected, at the drain terminal thereof, to the input terminal 33, and is connected, at the source terminal thereof, to the output terminal 38. The transistor T33 is connected, at the gate terminal thereof, to the input terminal 32, is connected, at the drain terminal thereof, to the output terminal 38, and is connected, at the source terminal thereof, the low level supply voltage VSS input terminal. The transistor T34 is connected, at the gate terminal thereof, to the input terminal 32, is connected, at the drain terminal thereof, to the first node N1, and is connected, at the source terminal thereof, to the low level supply voltage VSS input terminal.

Next, a function of the unit circuit 30 will be described. When the set signal S is changed to a high level, the transistor T31 changes the electric potential of the first node N1 toward a high level. When the electric potential of the first node N1 is at or near the high level, the transistor T32 supplies the electric potential of the clock signal VCLK to the output terminal 38. When the reset signal R is changed to a high level, the transistor T33 changes the electric potential of the output terminal 38 toward the electric potential of the low level supply voltage VSS. When the reset signal R is changed to a high level, the transistor T34 changes the electric potential of the first node N1 toward the electric potential of the low level supply voltage VSS.

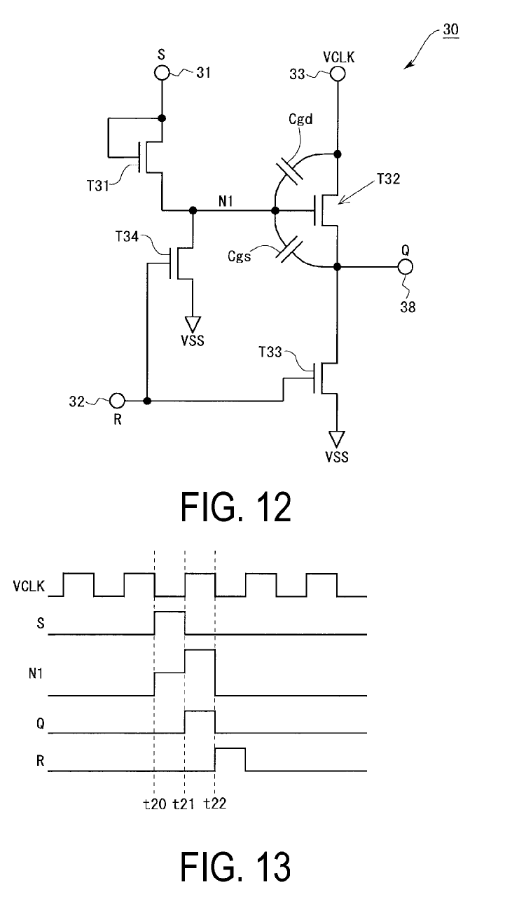

Basic actions of the unit circuit 30 will be described with reference to FIG. 12 and FIG. 13. The waveforms of clock signals CLK1 and CLK2 supplied to the unit circuit 30 as the clock signal VCLK are as illustrated in FIG. 8 (except for the characteristics detection process period). As illustrated in FIG. 13, the period before a time point t20, the electric potential of the first node N1 and the electric potential of the state signal Q (electric potential of the output terminal 38) is in a low level. Moreover, the input terminal 33 is supplied with the clock signal VCLK that is changed to a high level at prescribed intervals. Note that, regarding FIG. 13, ideal waveforms are illustrated here although actual waveforms include some delays.

At the time point t20, a pulse of the set signal S is supplied to the input terminal 31. The transistor T31 has a diode connection as illustrated in FIG. 12, and thus the transistor T31 turns into an ON state in response to the pulse of the set signal S. Consequently, the electric potential of the first node N1 increases.

At a time point t21, the clock signal VCLK changes from a low level to a high level. At the time of the change, the reset signal R is in a low level, and hence the transistor T34 is in an OFF state. Hence, the first node N1 turns into a floating state. As described above, the parasitic capacitance Cgd is formed between the gate terminal and the drain terminal of the transistor T32, and the parasitic capacitance Cgs is formed between the gate terminal and the source terminal of the transistor T32. With this configuration, the electric potential of the first node N1 increases significantly due to a bootstrap effect. As a result of the increase, a high voltage is applied to the gate terminal of the transistor T32. Consequently, the electric potential of the state signal Q (electric potential of the output terminal 38) increases to the high level electric potential of the clock signal VCLK. Note that, in the period from the time point t21 to a time point t22, the reset signal R is in a low level. Accordingly, the transistor T33 is maintained in an OFF state, so that the electric potential of the state signal Q does not decrease during this period.

At the time point t22, the clock signal VCLK changes from a high level to a low level. Consequently, the electric potential of the state signal Q decreases together with a decrease in the electric potential of the input terminal 33, and the electric potential of the first node N1 also decreases via the parasitic capacitances Cgd and Cgs. In addition, at the time point t22, a pulse of the reset signal R is supplied to the input terminal 32. In response to this, the transistor T33 and the transistor T34 turn into an ON state. The change of the transistor T33 into an ON state causes the electric potential of the state signal Q to decrease to a low level, and the change of the transistor T34 into an ON state causes the electric potential of the first node N1 to decrease to a low level.

By taking account of the above-described actions of the unit circuit 30 and the configuration of the shift register 3 illustrated in FIG. 11, it can be understood that the following actions are performed in the normal action period. When a pulse of the start pulse signal GSP as the set signal S is supplied to the first stage of the shift register 3, the shift pulse included in the state signal Q output from each stage is sequentially transferred from the first stage to subsequent stages on the basis of the clock signals CLK1 and CLK2. Moreover, the state signal Q output from each stage is output to the corresponding writing control line G1_WL. Consequently, according to the transfer of the shift pulse, the writing control lines G1_WL sequentially turn into an active state one by one. Thus, the writing control lines G1_WL sequentially turn into an active state in the normal action period one by one.

Note that the configuration of the unit circuit 30 is not limited to the configuration illustrated in FIG. 12 (configuration including the four transistors T31 to T34). For the purpose of improving drive performance and improving reliability, the number of transistors included in the unit circuit 30 is generally greater than four. The present invention is applicable even to such a case.

### 1.5 Configuration of Monitor Control Line Driving Circuit

FIG. 14 is a block diagram illustrating a configuration of the monitor control line driving circuit 400 in the present embodiment. The monitor control line driving circuit 400 is implemented by using a shift register 4. Stages of the shift register 4 are provided having a one-to-one correspondence with the monitor control lines G2_Mon in the display 500. In other words, in the present embodiment, the shift register 4 of n stages is included in the monitor control line driving circuit 400. Note that FIG. 14 illustrates only unit circuits 40(i−1) to 40(i+1) forming (i−1)-th to (i+1)-th stages of the n stages. Each stage (each unit circuit) of the shift register 4 is provided with an input terminal configured to receive the clock signal VCLK, an input terminal configured to receive the set signal S, an input terminal configured to receive the reset signal R, an output terminal configured to output the state signal Q, and an output terminal configured to output an output signal Q2.

As illustrated in FIG. 14, signals supplied to the input terminals of each stage (each unit circuit) of the shift register 4 are as follows. At each odd-numbered stage, a clock signal CLK3 is supplied as the clock signal VCLK, while at each even-numbered stage, a clock signal CLK4 is supplied as the clock signal VCLK. Moreover, at a certain stage, the state signal Q output from the previous stage is provided as the set signal S, and the state signal Q output from the next stage is supplied as the reset signal R. However, for the first stage (not illustrated in FIG. 14), the start pulse signal MSP is supplied as the set signal S. Note that the low level supply voltage VSS (not illustrated in FIG. 14) is supplied to all the unit circuits 40 in common. Moreover, the monitor enable signal Mon_EN (not illustrated in FIG. 14) is supplied to all the unit circuits 40 in common. Each stage of the shift register 4 outputs the state signal Q and the output signal Q2. The state signal Q output from each stage is supplied to the previous stage as the reset signal R and is also supplied to the next stage as the set signal S. The output signal Q2 output from each stage is output to the corresponding monitor control line G2_Mon. Note that the clock signal CLK3 and the clock signal CLK4 change as illustrated in FIG. 15 in the normal action period.

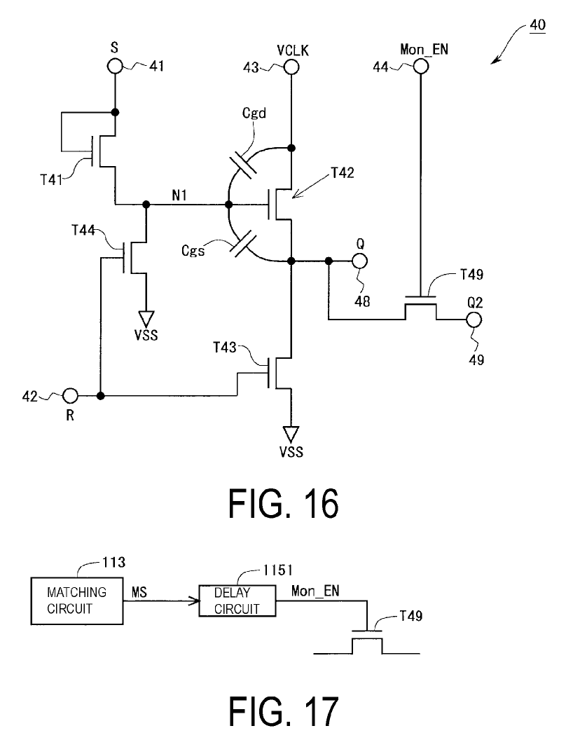

FIG. 16 is a circuit diagram illustrating a configuration of each of the unit circuits 40 of the shift register 4 configuring the monitor control line driving circuit 400 (configuration corresponding to one stage of the shift register 4). As illustrated in FIG. 16, the unit circuit 40 includes five transistors T41 to T44 and T49. Moreover, the unit circuit 40 includes four input terminals 41 to 44 and two output terminals 48 and 49 in addition to a low level supply voltage VSS input terminal. The transistors T41 to T44, the input terminals 41 to 43, and the output terminal 48 in FIG. 16 correspond respectively to the transistors T31 to T34, the input terminals 31 to 33, and the output terminal 38 in FIG. 12. In other words, the unit circuit 40 has a similar configuration to that of the unit circuit 30 except for the following respects. The output terminal 49, different from the output terminal 48, is provided to the unit circuit 40. Moreover, the transistor T49 is provided to the unit circuit 40, the transistor T49 having a configuration that the transistor T49 is connected, at the drain terminal thereof, to the output terminal 48 while being connected, at the source terminal thereof, to the output terminal 49, and that the monitor enable signal Mon_EN is provided to the gate terminal. Note that the configuration of the unit circuit 40 is not limited to the configuration illustrated in FIG. 16 as in the case of the unit circuit 30 of the shift register 3 constituting the writing control line driving circuit 300.

As described above, the unit circuit 40 has a similar configuration as that of the unit circuit 30 except for the respect that the output terminal 49 and the transistor T49 are provided. Moreover, the clock signals CLK3 and CLK4 having the waveforms illustrated in FIG. 15 are supplied to the shift register 4. With this configuration, the state signals Q output from the respective stages of the shift register 4 are sequentially changed to a high level on the basis of the clock signals CLK3 and CLK4. Here, in a case of focusing on a certain one of the unit circuits 40, the transistor T49 is in an OFF state when the monitor enable signal Mon_EN is in a low level. In this case, even when the state signal Q is in a high level, the output signal Q2 can be maintained in a low level. Hence, the monitor control line G2_Mon corresponding to this unit circuit 40 does not turn into an active state. In contrast to this, the transistor T49 is in an ON state when the monitor enable signal Mon_EN is in a high level. In this case, when the state signal Q is in a high level, the output signal Q2 is also in a high level. With this configuration, the monitor control line G2_Mon corresponding to this unit circuit 40 is in an active state.

Here, a description will be given of how the monitor enable signal Mon_EN is supplied to the transistor T49 in the unit circuit 40, with reference to FIG. 17. As illustrated in FIG. 17, the monitor enable signal Mon_EN supplied to the transistor T49 is output from a delay circuit 1151. This delay circuit 1151 is provided in the status machine 115 in the drive controller 110 in the display control circuit 100. When the writing count value CntWL output from the writing line counter 111 and the compensation target line address Addr stored in the compensation target line address storage memory 112 match, the matching signal MS changes from a low level to a high level. The delay circuit 1151 delays the waveform of the matching signal MS for one horizontal interval. A signal thus obtained is output from the delay circuit 1151 as the monitor enable signal Mon_EN. In this way, the monitor enable signal Mon_EN supplied to the transistor T49 is changed to a high level one horizontal interval after the time point at which the matching signal MS changes from a low level to a high level.

### 1.6 Configuration of Light Emission Control Line Driving Circuit

FIG. 18 is a diagram for describing a configuration of the light emission control line driving circuit 350 in the present embodiment. This light emission control line driving circuit 350 is constituted by a light emission control line activation circuit 350a, first to third light emission control line deactivation circuits 350d1 to 350d3, a demultiplexing circuit 340, and first to third pull-down transistors Tpd1 to Tpd3, which are provided for the respective pixel circuit rows. The light emission control signal ECTL output from the drive controller 110 in the display control circuit 100 includes, as has already been described, the activation start pulse signal ESPa, first to third deactivation start pulse signals ESPd1 to ESPd3, and the clock signals CLK1 and CLK2. The activation start pulse signal ESPa is input to the light emission control line activation circuit 350a, the first to third deactivation start pulse signals ESPd1 to ESPd3 are input to the respective first to third light emission control line deactivation circuits 350d1 to 350d3, and the clock signals CLK1 and CLK2 are input to the light emission control line activation circuit 350a and the first to third light emission control line deactivation circuits 350d1 to 350d3. The k-th light emission control line deactivation circuit 350dk generates n deactivation signals EMk_pd(1) to EMk_pd(n) corresponding to the n pixel circuit rows and supplies each deactivation signal EMk_pd(i) to the gate terminal of the k-th pull-down transistor Tpdk of the corresponding row (k=1, 2, 3). The first to third light emission control lines EM1(i) to EM3(i) passing through the corresponding pixel circuit row are connected to the low level power supply line VSS via the respective first to third pull-down transistors Tpd1 to Tpd3.

Note that the value or symbol in parentheses attached immediately after each of reference signs indicating constituent components and signals of a unit circuit in a shift register constituting the light emission control line activation circuit 350a, the first to third light emission control line deactivation circuits 350d1 to 350d3, and the like is assumed to indicate the position of the unit circuit in the shift register. Specifically, a reference sign to which “(i)” is attached immediately after indicates a constituent element or a signal in the i-th unit circuit in the shift register.

### 1.6.1 Configuration of Light Emission Control Line Activation Circuit

FIG. 19 is a block diagram illustrating a configuration example of the light emission control line activation circuit 350a in the present embodiment. The light emission control line activation circuit 350a is configured by a shift register 35asr of n stages configured by n unit circuits 35a. Note that FIG. 19 illustrates unit circuits 35a(i−1) to 35a(i+1) in the (i−1)-th stage to the (i+1)-th stage. Here, i is an even number that is two or greater and (n−1) or smaller. Each unit circuit 35a is provided with an input terminal configured to receive the clock signal VCLK, an input terminal configured to receive the set signal S, an input terminal configured to receive a first reset signal R1, an input terminal configured to receive a second reset signal R2, an output terminal configured to output a first output signal Q1, and an output terminal configured to output a second output signal Q2. Note that, each unit circuit 35a further includes an input terminal configured to receive the high level supply voltage VDD and an input terminal configured to receive the low level supply voltage VSS, but illustration of these input terminals is omitted in FIG. 19.

The shift register 35asr configuring the light emission control line activation circuit 350a is supplied with two-phase clock signals CLK1 and CLK2 as a light emission control clock signal ECK. Here, the clock signals CLK1 and CLK2 are the same as the clock signals CLK1 and CLK2 included in the writing control signal WCTL (refer to FIG. 8).

Signals supplied to the input terminals of each stage (each unit circuit) of the shift register 35asr are as follows. At each odd-numbered stage, the first clock signal CLK1 is supplied as the clock signal VCLK. At each odd-numbered stage, the second clock signal CLK2 is supplied as the clock signal VCLK. Moreover, at a certain stage, the first output signal Q1 output from the previous stage is supplied as the set signal S, and the first output signal Q1 output from the subsequent stage is supplied as the first reset signal R1. However, for the first stage, the activation start pulse signal ESPa is provided as the set signal S. Moreover, a subframe reset signal SUBF_RST is provided to all the stages in common as the second reset signal R2.

In the configuration as described above, when a pulse of the activation start pulse signal ESPa as the set signal S is supplied to the first stage of the shift register 35asr, the shift pulse included in the first output signal Q1 output from each stage is sequentially transferred from the first stage to the n-th stage on the basis of the first clock signal CLK1 and the second clock signal CLK2. In response to the transfer of the shift pulse, the first output signals Q1 output from the respective stages sequentially change to a high level, and the second output signals Q2 output from the respective stages sequentially change to high level. Note that the second output signal Q2 output from each stage is supplied to the corresponding light emission control line EM as the light emission enable signal GGem via the demultiplexing circuit 340.

### 1.6.2 Configuration of Unit Circuit in Light Emission Control Line Activation Circuit

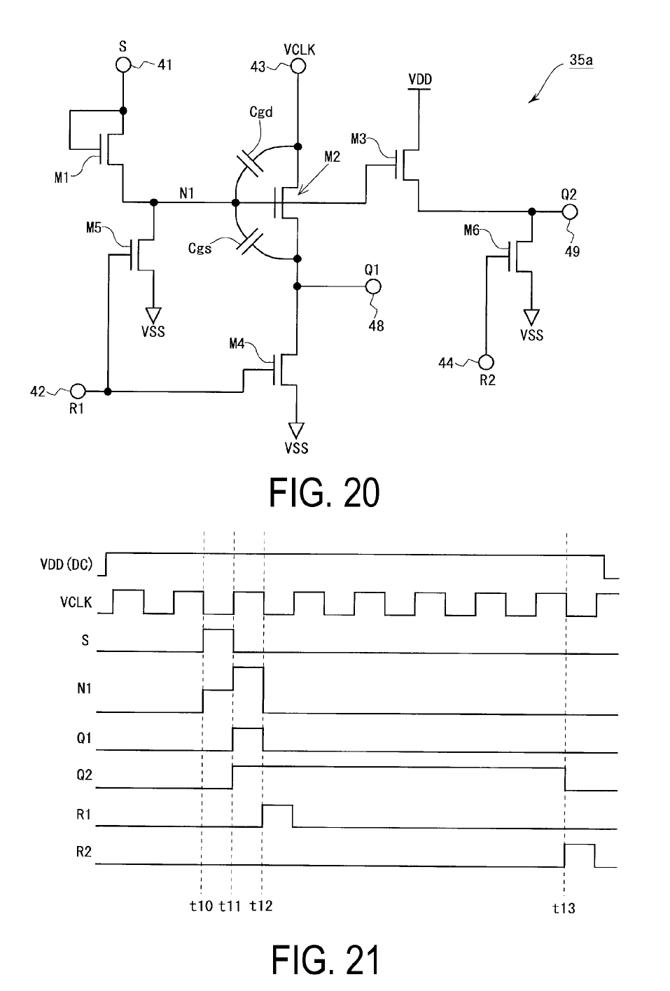

FIG. 20 is a circuit diagram illustrating a configuration of each of the unit circuits 35a in the shift register 35asr configuring the light emission control line activation circuit 350a (configuration corresponding to one stage of the shift register 35asr). As illustrated in FIG. 20, the unit circuit 35a includes six transistors M1 to M6. Moreover, the unit circuit 35a includes four input terminals 41 to 44 and two output terminals 48 and 49 in addition to a high level supply voltage VDD input terminal and a low level supply voltage VSS input terminal. Here, the input terminal configured to receive the set signal S is denoted by a reference sign “41”, the input terminal configured to receive the first reset signal R1 is denoted by a reference sign “42”, the input terminal configured to receive the clock signal VCLK is denoted by a reference sign “43”, and the input terminal configured to receive the second reset signal R2 is denoted by a reference sign “44”. Moreover, the output terminal configured to output the first output signal Q1 is denoted by a reference sign “48”, and the output terminal configured to output the second output signal Q2 is denoted by a reference sign “49”. The parasitic capacitance Cgd is formed between the gate terminal and the drain terminal of the transistor M2, and the parasitic capacitance Cgs is formed between the gate terminal and the source terminal of the transistor M2. The source terminal of the transistor M1, the gate terminal of the transistor M2, the gate terminal of the transistor M3, and the drain terminal of the transistor M5 are connected to each other. Note that each region (wiring line) where the terminals are connected to each other is referred to as a “first node” below. The first node is denoted by a reference sign “N1”.

The transistor M1 is connected, at the gate terminal and the drain terminal thereof, to the input terminal 41 (i.e., a diode connection is established) and is connected, at the source terminal thereof, to the first node N1. The transistor M2 is connected, at the gate terminal thereof, to the first node N1, is connected, at the drain terminal thereof, to the input terminal 43, and is connected, at the source terminal thereof, to the output terminal 48. The transistor M3 is connected, at the gate terminal thereof, to the first node N1, is connected, at the drain terminal thereof, to the high level supply voltage VDD input terminal, and is connected, at the source terminal thereof, to the output terminal 49. The transistor M4 is connected, at the gate terminal thereof, to the input terminal 42, is connected, at the drain terminal thereof, to the output terminal 48, and is connected, at the source terminal thereof, to the low level supply voltage VSS input terminal. The transistor M5 is connected, at the gate terminal thereof, to the input terminal 42, is connected, at the drain terminal thereof, to the first node N1, and is connected, at the source terminal thereof, to the low level supply voltage VSS input terminal. The transistor M6 is connected, at the gate terminal thereof, to the input terminal 44, is connected, at the drain terminal thereof, to the output terminal 49, and is connected, at the source terminal thereof, to the low level supply voltage VSS input terminal.

Next, a function of each of constituent elements in this unit circuit 35a will be described. When the set signal S changes to a high level, the transistor M1 changes the electric potential of the first node N1 toward a high level. When the electric potential of the first node N1 at or near the high level, the transistor M2 supplies the electric potential of the clock signal VCLK to the output terminal 48. When the electric potential of the first node N1 at or near the high level, the transistor M3 supplies the electric potential of the high level supply voltage VDD to the output terminal 49. When the first reset signal R1 changes to a high level, the transistor M4 changes the electric potential of the output terminal 48 toward the electric potential of the low level supply voltage VSS. When the first reset signal R1 changes to a high level, the transistor M5 changes the electric potential of the first node N1 toward the electric potential of the low level supply voltage VSS. When the second reset signal R2 changes to a high level, the transistor M6 changes the electric potential of the output terminal 49 toward the electric potential of the low level supply voltage VSS.

### 1.6.3 Actions of Unit Circuit in Light Emission Control Line Activation Circuit

Next, a description will be given of actions of the unit circuit 35a in the present embodiment with reference to FIG. 20 and FIG. 21. As illustrated in FIG. 21, the period before a time point t10, the electric potential of the first node N1, the electric potential of the first output signal Q1 (electric potential of the output terminal 48), and the electric potential of the second output signal Q2 (electric potential of the output terminal 49) are in a low level. Moreover, the input terminal 43 is supplied with the clock signal VCLK that changes to a high level at prescribed intervals. Note that, regarding FIG. 21, ideal waveforms are illustrated here although actual waveforms include some delays.

At the time point t10, a pulse of the set signal S is supplied to the input terminal 41. The transistor M1 has a diode connection as illustrated in FIG. 20, and thus the transistor M1 turns into an ON state in response to the pulse of the set signal S. Consequently, the electric potential of the first node N1 increases.

At a time point t11, the clock signal VCLK changes from a low level to a high level. At the time of the change, the first reset signal R1 is in a low level, and hence the transistor M5 is in an OFF state. Hence, the first node N1 turns into a floating state. As described above, the parasitic capacitance Cgd is formed between the gate terminal and the drain terminal of the transistor M2, and the parasitic capacitance Cgs is formed between the gate terminal and the source terminal of the transistor M2. With this configuration, the electric potential of the first node N1 increases significantly due to a bootstrap effect. As a result of the increase, a high voltage is applied to the transistor M2 and the transistor M3. Consequently, the electric potential of the first output signal Q1 (electric potential of the output terminal 48) increases to the high level electric potential of the clock signal VCLK, and the electric potential of the second output signal Q2 (electric potential of the output terminal 49) increases to the electric potential of the high level supply voltage VDD. Note that, in the period from the time point t11 to the time point t12, the first reset signal R1 is in a low level. Accordingly, the transistor M4 is maintained in an OFF state, so that the electric potential of the first output signal Q1 does not decrease during this period. Note that, in the period from the time point t11 to the time point t12, the second reset signal R2 is in a low level. Accordingly, the transistor M6 is maintained in an OFF state, so that the electric potential of the second output signal Q2 does not decrease during this period.

At the time point t12, the clock signal VCLK changes from a high level to a low level. Consequently, the electric potential of the first output signal Q1 decreases together with a decrease in the electric potential of the input terminal 43, and the electric potential of the first node N1 also decreases via the parasitic capacitances Cgd and Cgs. In addition, at the time point t12, a pulse of the first reset signal R1 is supplied to the input terminal 42. In response to this, the transistor M4 and the transistor MS turn into an ON state. The change of the transistor M4 into an ON state causes the electric potential of the first output signal Q1 to decrease to a low level, and the change of the transistor MS into an ON state causes the electric potential of the first node N1 to decrease to a low level. Note that, the decrease of the electric potential of the first node N1 to a low level causes the transistor M3 to turn into an OFF state, but the second reset signal R2 is maintained in a low level until a time point t13. Thus, the output terminal 49 is maintained in a floating state, and the electric potential of the second output signal Q2 is maintained at the electric potential of the high level supply voltage VDD, in the period from the time point t12 to the time point t13.

At the time point t13, a pulse of the second reset signal R2 is supplied to the input terminal 44. In response to this, the transistor M6 turns into an ON state. As a result, the electric potential of the second output signal Q2 decreases to a low level. Note that a pulse of the subframe reset signal SUBF_RST as the second reset signal R2 is supplied to each unit circuit 35a at the termination of each subframe period. In other words, the time point t13 in FIG. 21 corresponds to the termination of each subframe period.

Note that the configuration of the unit circuits 35a is not limited to the configuration illustrated in FIG. 20 (configuration including the six transistors M1 to M6). For the purpose of improving drive performance and improving reliability, the number of transistors included in each unit circuit 35a is generally greater than six. The present invention is applicable even to such a case.

### 1.6.4 Demultiplexing Circuit

The demultiplexing circuit 340 includes a first demultiplexer 342 to an n-th demultiplexer 342 corresponding to respective light emission enable signals GGem(1) to GGem(n) output from the light emission control line driving circuit 350, and the n pixel circuit rows in the display 500 corresponds to the respective n demultiplexers 342. As has already been described, the pixel circuit row is a pixel circuit group configured by m pixel circuits 50 aligned along a direction in which the writing control line G1_WL(i) extends (horizontal direction) in the display 500 (also referred to simply as a “row”). With the following configuration, each demultiplexer 342 supplies the corresponding light emission enable signal GGem(i) to the three light emission control lines EM1(i), EM2(i), and EM3(i) passing through the corresponding pixel circuit row in a time division manner (i=1 to n).

Specifically, as illustrated in FIG. 18, each demultiplexer 342 includes three activation control transistors Tem1 to Tem3 as switching elements, and the input terminal of the demultiplexer 342 configured to receive the light emission enable signal GGem(i) from the light emission control line driving circuit 350 is connected to the first light emission control line EM1(i) via the activation control transistor Tem1, is connected to the second light emission control line EM2(i) via the activation control transistor Tem2, and is connected to the third light emission control line EM3(i) via the activation control transistor Tem3. The gate terminals (control terminals) of these activation control transistors Tem1 to Tem3 are supplied with respective first to third selection signals SEL1 to SEL3 output from the light emission control signal input switching circuit 360. Hence, each demultiplexer 342 supplies each light enable signal GGem(i) to the first light emission control line EM1(i) when the first selection signal SEL1 is active (high level in the present embodiment), to the second light emission control line EM2(i) when the second selection signal SEL2 is active, and to the third light emission control line EM3(i) when the third selection signal SEL3 is active. As has been described above, the first to third selection signals SEL1, SEL2, and SEL3 sequentially change into a high level each one subframe period in each frame period, and hence the light emission enable signals GGem(i) output from the light emission control line driving circuit 350 is sequentially supplied to the first to third light emission control lines EM1(i), EM2(i), and EM3(i) in every one subframe period in each frame period.

### 1.6.5 Configuration of Light Emission Control Line Deactivation Circuit

Next, a description will be given of first to third light emission control line deactivation circuits 350d1 to 350d3 included in the light emission control line driving circuit 350 in the present embodiment. Different start pulse signals ESPd1 to ESPd3 are input to the respective first to third light emission control line deactivation circuits 350d1 to 350d3, but the first to third light emission control line deactivation circuits 350d1 to 350d3 have the same configuration and act in accordance with the same clock signals CLK1 and CLK2. In the following, a description will be given of the configurations of the first to third light emission control line deactivation circuits 350d1 to 350d3 all together as a configuration of a k-th light emission control line deactivation circuit 350dk (k=1, 2, 3)

FIG. 22 is a block diagram illustrating a configuration example of the light emission control line deactivation circuit 350dk included in the light emission control line driving circuit 350 in the present embodiment. This light emission control line deactivation circuit 350dk is configured by a shift register 35dsr of n stages configured by n unit circuits 35d. Note that FIG. 22 illustrates unit circuits 35d(i−1) to 35d(i+1) in the (i−1)-th stage to the (i+1)-th stage. Here, i is an even number that is two or greater and (n−1) or smaller. Each unit circuit 35d is provided with an input terminal configured to receive the clock signal VCLK, an input terminal configured to receive the set signal S, an input terminal configured to receive the reset signal R, and an output terminal configured to output the state signal Q. Note that, each unit circuit 35d further includes an input terminal configured to receive the low level supply voltage VSS, but illustration of the input terminal is omitted in FIG. 22.

The shift register 35dsr configuring the light emission control line deactivation circuit 350dk is supplied with two-phase clock signals CLK1 and CLK2 as a light emission control clock signal ECK. Here, the clock signals CLK1 and CLK2 are the same as the clock signals CLK1 and CLK2 included in the writing control signal WCTL (refer to FIG. 8).

Signals supplied to the input terminals of each stage (each unit circuit) of the shift register 35dsr are as follows. At each odd-numbered stage, the clock signal CLK1 is supplied as the clock signal VCLK, while at each even-numbered stage, the clock signal CLK2 is supplied as the clock signal VCLK. Moreover, at a certain stage, the state signal Q output from the previous stage is supplied as the set signal S, and the state signal Q output from the next stage is supplied as the reset signal R. However, for the first stage (not illustrated in FIG. 22), the deactivation start pulse signal ESPdk is supplied as the set signal S. Note that the low level supply voltage VSS (not illustrated in FIG. 22) is applied to all the unit circuits 35d in common. Each stage of the shift register 35dsr outputs the state signal Q. The state signal Q output from each stage is supplied to the gate terminal of the corresponding pull-down transistor Tpdk as the deactivation signal EMk_pd(i) and is also supplied to the previous stage as the reset signal R while being supplied to the next stage as the set signal S.

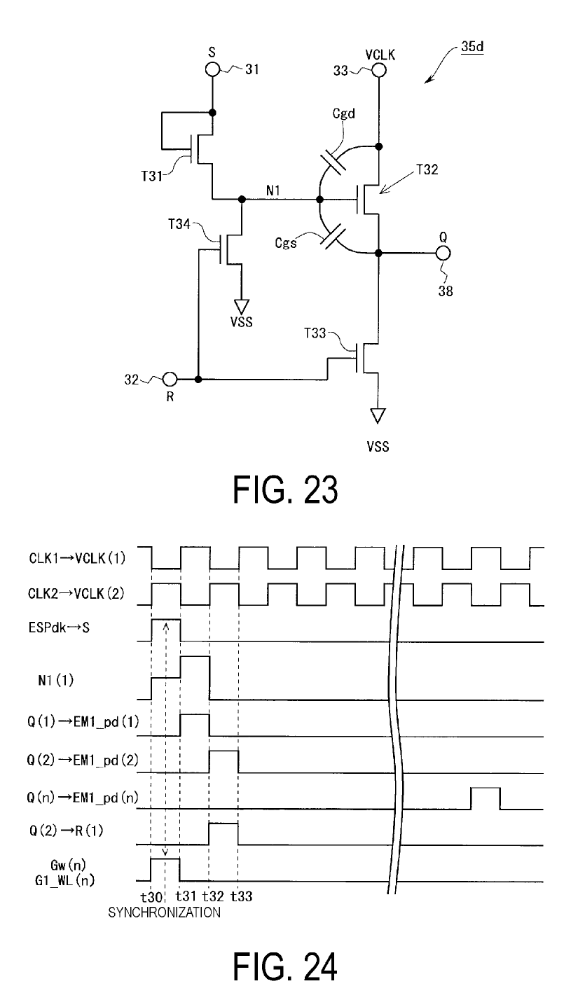

FIG. 23 is a circuit diagram illustrating a configuration of the unit circuits 35d in the shift register 35dsr configuring the light emission control line deactivation circuit 350dk (configuration corresponding to one stage of the shift register 35dsr). As illustrated in FIG. 23, the unit circuit 35d in the light emission control line deactivation circuit 350dk has a similar configuration to that of the unit circuit 30 (FIG. 12) in the writing control line driving circuit 300. Each part of the configuration of the unit circuit 35d in the light emission control line deactivation circuit 350dk that is the same as a part of the unit circuit 30 in the writing control line driving circuit 300 is denoted by the same reference sign, and a detailed description thereof is omitted.

As illustrated in FIG. 23, the unit circuit 35d includes four transistors T31 to T34 and also includes three input terminals 31 to 33 and one output terminal 38 in addition to a low level supply voltage VSS input terminal. When the set signal S input from the input terminal 31 changes to a high level, the transistor T31 changes the electric potential of the first node N1 toward a high level. When the electric potential of the first node N1 at or near the high level, the transistor T32 supplies the electric potential of the clock signal VCLK input from the input terminal 33, to the output terminal 38. When the reset signal R input from the input terminal 32 changes to a high level, the transistor T33 changes the electric potential of the output terminal 38 toward the electric potential of the low level supply voltage VSS. When the reset signal R changes to a high level, the transistor T34 changes the electric potential of the first node N1 toward the electric potential of the low level supply voltage VSS.

Next, basic actions of the unit circuit 35d will be described with reference to FIG. 23 and FIG. 24. The waveforms of clock signals CLK1 and CLK2 provided to the unit circuit 30 as the clock signal VCLK are as illustrated in FIG. 8 (except for the characteristics detection process period). As illustrated in FIG. 24, in the period before a time point t30, the electric potential of the first node N1 and the electric potential of the state signal Q (electric potential of the output terminal 38) is in a low level. Moreover, the input terminal 33 is supplied with the clock signal VCLK that changes to a high level at prescribed intervals. Note that, regarding FIG. 24, ideal waveforms are illustrated here although actual waveforms include some delays.

At the time point t30, a pulse of the set signal S is supplied to the input terminal 31. For example, the input terminal 31 of the unit circuit 35d(1) in the first stage is supplied with the deactivation start pulse signal ESPdk as the set signal S. Since the transistor T31 has a diode connection as illustrated in FIG. 23, the transistor T31 turns into an ON state in response to the pulse of the set signal S. Consequently, the electric potential of the first node N1 increases.

In consideration of a case where the clock signal CLK1 is supplied as the clock signal VCLK, the clock signal VCLK changes from a low level to a high level at the time point t31. As illustrated in FIG. 22, the state signal Q of the next stage is supplied as the reset signal R. At the time of the change, this reset signal R is in a low level, and hence the transistor T34 is in an OFF state. Hence, the first node N1 turns into a floating state. The parasitic capacitance Cgd is formed between the gate terminal and the drain terminal of the transistor T32, and the parasitic capacitance Cgs is formed between the gate terminal and the source terminal of the transistor T32. With this configuration, the electric potential of the first node N1 increases significantly due to a bootstrap effect. As a result of the increase, a large voltage is applied to the gate terminal of the transistor T32. Consequently, the electric potential of the state signal Q (electric potential of the output terminal 38) increases to the high level electric potential of the clock signal VCLK. Note that, in the period from the time point t31 to a time point t32, the reset signal R is in a low level. Accordingly, the transistor T33 is maintained in an OFF state, so that the electric potential of the state signal Q does not decrease during this period.

At the time point t32, the clock signal VCLK changes from a high level to a low level. Consequently, the electric potential of the state signal Q decreases together with a decrease in the electric potential of the input terminal 33, and the electric potential of the first node N1 also decreases via the parasitic capacitances Cgd and Cgs. In addition, at the time point t32, a pulse of the reset signal R is supplied to the input terminal 32. In response to this, the transistor T33 and the transistor T34 turn into ON states. The change of the transistor T33 into an ON state causes the electric potential of the state signal Q to decrease to a low level, and the change of the transistor T34 into an ON state causes the electric potential of the first node N1 to decrease to a low level.

By taking account of the above-described actions of the unit circuits 35d and the configuration of the shift register 35dsr illustrated in FIG. 22, it can be understood that the following actions are performed in the normal action period. The unit circuit 35d(1) at the first stage in the shift register 35dsr is supplied with a pulse of the deactivation start pulse signal ESPdk as the set signal S. This deactivation start pulse signal ESPdk is generated as a signal having a pulse synchronized with a pulse of the writing control signal Gw(n) applied to the n-th (last) writing control line G1_WL(n) in the subframe period immediately before the k-th subframe period as illustrated in FIG. 24. When a pulse of such a deactivation start pulse signal ESPdk is supplied to the unit circuit 35d(1) at the first stage as the set signal S, the shift pulse included in the state signal Q output from each stage is sequentially transferred from the first stage to subsequent stages on the basis of the clock signals CLK1 and CLK2. Moreover, the state signal Q output from each stage is output to the gate terminal of the corresponding pull-down transistor Tpdk as the deactivation signal EMk_pd(i) (i=1 to n; k=1, 2, 3). Hence, the k-th light emission control line EMk(1) to EMk(n) are sequentially changed to a low level (inactive state) one by one according to transfer of the shift pulse in the k-th subframe period in each frame period (k=1, 2, 3). When the first to third light emission control lines EMk(i) corresponding to the i-th pixel circuit row turn into an inactive state, each of the light emission control transistors T3, T4, and T5 in each of the pixel circuits 50 in the i-th pixel circuit row turns into an OFF state, and consequently each of the organic EL elements OLED(R), OLED(G), and OLED(B) is lit out. Detailed actions for deactivation of each of the light emission control lines EM1(i), EM2(i), and EM3(i) thus configured will be described later.

Note that the configuration of the unit circuit 35d is not limited to the configuration illustrated in FIG. 23 (configuration including the four transistors T31 to T34). For the purpose of improving drive performance and improving reliability, the number of transistors included in the unit circuit 35d is generally greater than four. The present invention is applicable even to such a case.

### 1.7 Actions in Normal Display Mode

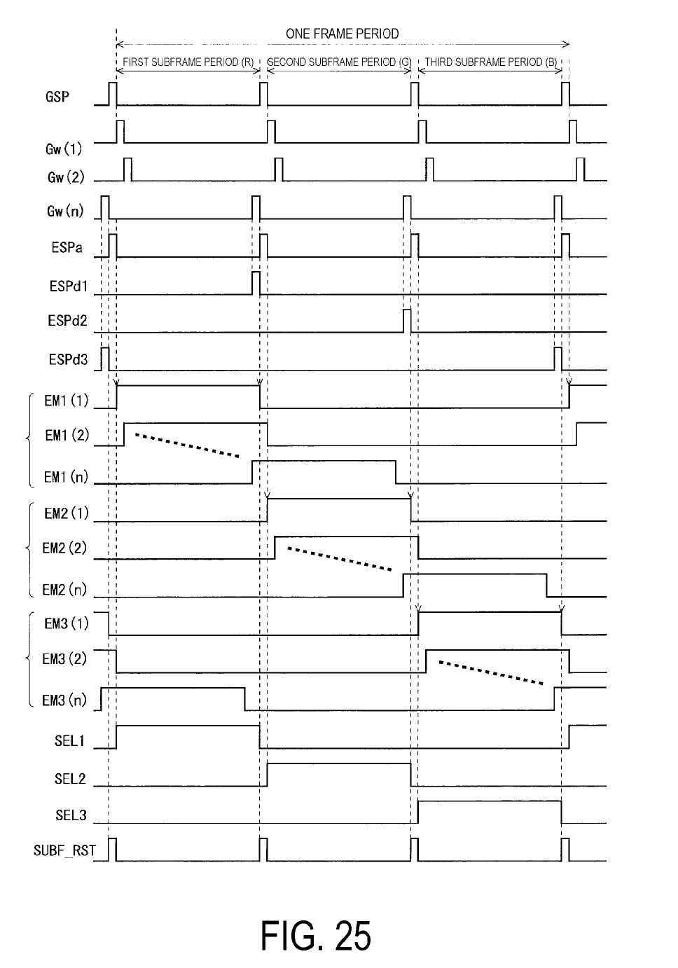

FIG. 25 is a timing chart for describing actions in the normal display mode of the organic EL display device according to the present embodiment, and specifically actions for displaying a color image in the display 500 on the basis of the input signal Sin. As illustrated in FIG. 25, each frame period includes the first to third subframe periods, and the writing control signals Gw(1) to Gw(n) that sequentially turn into an active state in each subframe period is applied to the writing control line G1_WL(1) to G1_WL(n) by the writing control line driving circuit 300. Meanwhile, the drive data signals D1 to Dm are applied to the respective data lines SL1 to SLm by the data line driving circuit 210 (m data voltage output unit circuits 211d) in the data-side driving circuit 200. When the writing control lines G1_WL(1) to G1_WL(n) and the data lines SL1 to SLm are thus driven, a voltage based on the corresponding drive data signal Dj is held by the data holding capacity Cst in each pixel circuit 50 in each subframe period, and consequently, pixel data based on the input signal Sin is written into the corresponding pixel circuit 50. In this operation, data indicating red components of the pixels configuring the image represented by the RGB video data signal Din in the input signal Sin i.e., the color image to be displayed (referred to as “R pixel data” below), is written into n*m pixel circuits 50 in the first subframe period (referred to also as an “R subframe period” below), data indicating green components of the pixels configuring the color image to be displayed (referred to as “G pixel data” below), is written into n*m pixel circuits 50 in the second subframe period (referred to also as a “G subframe period” below), and data indicating blue components of the pixels configuring the color image to be displayed (referred to as “B pixel data” below), is written into n*m pixel circuits 50 in the third subframe period (referred to also as a “B subframe period” below). Note that, in the normal display mode, all the monitor control lines G2_Mon(1) to G2_Mon(n) are maintained in an inactive state (state in which a low level voltage is applied).

To the light emission control line activation circuit 350a, the activation start pulse signal ESPa including a pulse immediately before each subframe period is input from (the drive controller 110 of) the display control circuit 100 (FIG. 1 and FIG. 18). Moreover, to the first light emission control line deactivation circuit 350d1, a first deactivation start pulse signal ESPd1 including a pulse immediately after a period in which the n-th writing control signal Gw(n) is in an active state (high level) in the subframe period immediately before the first subframe period (the third subframe period in an immediately previous frame period) (refer to FIG. 25) is input from the display control circuit 100; to the second light emission control line deactivation circuit 350d2, a second deactivation start pulse signal ESPd2 including a pulse immediately after a period in which the n-th writing control signal Gw(n) is in an active state in the first subframe period is input from the display control circuit 100; and to the third light emission control line deactivation circuit 350d3, a third deactivation start pulse signal ESPd3 including a pulse immediately after a period in which the n-th writing control signal Gw(n) is in an active state in the third subframe period is input from the display control circuit 100 (refer to FIG. 1 and FIG. 18).

As has been already described, the light emission control line activation circuit 350a and the first to third light emission control line deactivation circuit 350d1 to 350d3 are supplied with the same clock signals CLK1 and CLK2 (FIG. 8) as the clock signals supplied to the writing control line driving circuit 300, from the display control circuit 100. Moreover, each light emission enable signal GGem(i) output from the light emission control line activation circuit 350a is applied to the light emission control line EMk(i) (i=1 to n; k=1, 2, 3) selected by the first to third selection signals SEL1 to SEL3 in the demultiplexer 342 corresponding to the light emission enable signal GGem. As illustrated in FIG. 25, the first selection signal SEL1 is active (high level) only in the first subframe period, the second selection signal SEL2 is active (high level) only in the second subframe period, and the third selection signal SEL3 is active (high level) only in the third subframe period.

When signals of different kinds as above are supplied to the light emission control line activation circuit 350a and the light emission control line deactivation circuits 350d1 to 350d3, the light emission control lines EMk(1) to EMk(n) are driven as will be described below (k=1, 2, 3), and the first to third organic EL elements OLED(R), OLED(G), and OLED(B) in each pixel circuit 50 are lit accordingly.

In the first subframe period, the first selection signal SEL1 changes to a high level, so that the activation control transistor Tem1 of each demultiplexer 342 turns into an ON state, and consequently the first light emission control lines EM1(1) to EM1(n) are sequentially changed to a high level as illustrated in FIG. 25 by the light emission control line activation circuit 350a. When the first subframe period ends, the subframe reset signal SUBF_RST input to the light emission control line activation circuit 350a is changed to a high level in a blanking interval immediately after the first subframe period (period in which all the writing control signals Gw(1) to Gw(n) are in a low level), so that all the light emission enable signals GGem(1) to GGem(n) are changed to a low level. However, the first selection signal SEL1 changes to a low level at the time when the first subframe period ends, the activation control transistor Tem1 in each demultiplexer 342 turns into an OFF state, and consequently, all the first light emission control lines EM1(1) to EM1(n) turn into a floating state to be maintained in a high level (active state) on the basis of the respective wiring line capacities. Thereafter, the pull-down transistors Tpd1(1) to Tpd1(n) connected to the respective first light emission control lines EM1(1) to EM1(n) are sequentially turned into an ON state from the time when the first subframe period ends, by the first light emission control line deactivation circuit 350d1 on the basis of the first deactivation start pulse signal ESPd1 including a pulse synchronized with the pulse of the n-th writing control signal Gw(n) in the first subframe period. Consequently, the first light emission control lines EM1(1) to EM1(n) sequentially turn into a low level (inactive state) from the time when the first subframe period ends as illustrated in FIG. 25.

Hence, the voltages of the first light emission control lines EM1(1) to EM1(n) are sequentially changed to a high level at the timings shifted by one horizontal interval in the first subframe period, so that each of the first light emission control lines EM1(1) to EM1(n) is maintained in a high level for a period equal to one subframe period. In the period where the first light emission control line EM1(i) in the i-th row is in a high level, the writing control signal Gw(i) changes to a high level at the beginning of the period to write the data signal Dj (j=1 to m) as R pixel data into each of the pixel circuits 50 in the i-th row (each of the pixel circuits 50 in the i-th pixel circuit row), the first organic EL element OLED(R) in each of the pixel circuits 50 in the i-th row turns into a lit state and emits red light at the intensity corresponding to the R pixel data (i=1 to n).

In the second subframe period, the second selection signal SEL2 changes to a high level, so that the activation control transistor Tem2 of each demultiplexer 342 turns into an ON state, and consequently the second light emission control lines EM2(1) to EM2(n) are sequentially changed to a high level as illustrated in FIG. 25 by the light emission control line activation circuit 350a. When the second subframe period ends, the subframe reset signal SUBF_RST is changed to a high level in a blanking interval immediately after the second subframe period, so that all the light emission enable signals GGem(1) to GGem(n) are changed to a low level. However, the second selection signal SEL2 changes to a low level at the time when the second subframe period ends, the activation control transistor Tem2 in each demultiplexer 342 turns into an OFF state, and consequently, all the second light emission control lines EM2(1) to EM2(n) turn into a floating state to be maintained in a high level (active state) on the basis of the respective wiring line capacities. Thereafter, the pull-down transistors Tpd2(1) to Tpd2(n) connected to the respective second light emission control lines EM2(1) to EM2(n) are sequentially turned into an ON state from the time when the second subframe period ends, by the second light emission control line deactivation circuit 350d2 on the basis of the second deactivation start pulse signal ESPd2 including a pulse synchronized with the pulse of the n-th writing control signal Gw(n) in the second subframe period. Consequently, the second light emission control lines EM2(1) to EM2(n) sequentially turn into a low level (inactive state) from the time when the second subframe period ends as illustrated in FIG. 25.

Hence, the voltages of the second light emission control lines EM2(1) to EM2(n) are changed to a high level at the timings shifted by one horizontal interval in the second subframe period, so that each of the first light emission control lines EM2(1) to EM2(n) is maintained in a high level for a period equal to one subframe period. In the period where the second light emission control line EM2(i) in the i-th row is in a high level, the writing control signal Gw(i) changes to a high level at the beginning of the period to write the data signal Dj (j=1 to m) as G pixel data into each of the pixel circuits 50 in the i-th row, the second organic EL element OLED(G) in each of the pixel circuits 50 in the i-th row turns into a lit state and emits green light at the intensity corresponding to the G pixel data (i=1 to n).

In the third subframe period, the third selection signal SEL3 changes to a high level, so that the activation control transistor Tem3 of each demultiplexer 342 turns into an ON state, and consequently the third light emission control lines EM3(1) to EM3(n) are sequentially changed to a high level as illustrated in FIG. 25 by the light emission control line activation circuit 350a. When the third subframe period ends, the subframe reset signal SUBF_RST is changed to a high level in a blanking interval immediately after the third subframe period, so that all the light emission enable signals GGem(1) to GGem(n) are changed to a low level. However, the third selection signal SEL3 changes to a low level at the time when the third subframe period ends, the activation control transistor Tem3 in each demultiplexer 342 turns into an OFF state, and consequently, all the third light emission control lines EM3(1) to EM3(n) turn into a floating state to be maintained in a high level (active state) on the basis of the respective wiring line capacities. Thereafter, the pull-down transistors Tpd3(1) to Tpd3(n) connected to the respective third light emission control lines EM3(1) to EM3(n) are sequentially turned into an ON state from the time when the third subframe period ends, by the third light emission control line deactivation circuit 350d3 on the basis of the third deactivation start pulse signal ESPd3 including a pulse synchronized with the pulse of the n-th writing control signal Gw(n) in the third subframe period. Consequently, the voltages of the third light emission control lines EM3(1) to EM3(n) sequentially turn into a low level (inactive state) from the time when the third subframe period ends as illustrated in FIG. 25.

Hence, the voltages of the third light emission control lines EM3(1) to EM3(n) are changed to a high level at the timings shifted by one horizontal interval in the third subframe period, so that each of the third light emission control lines EM3(1) to EM3(n) is maintained in a high level for a period equal to one subframe period. In the period where the third light emission control line EM3(i) in the i-th row is in a high level, the writing control signal Gw(i) changes to a high level at the beginning of the period to write the data signal Dj (j=1 to m) as B pixel data into each of the pixel circuits 50 in the i-th row, and the third organic EL element OLED(B) in each of the pixel circuits 50 in the i-th row turns into a lit state and emits blue light at the intensity corresponding to the B pixel data (i=1 to n).

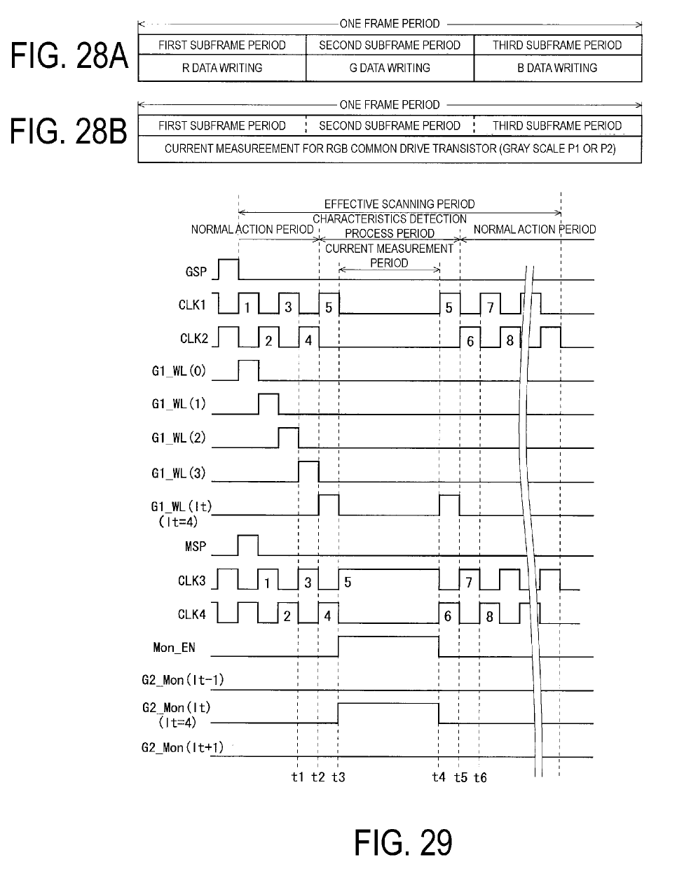

As described above, in the normal display mode, writing of the R pixel data (R data writing) to each of the pixel circuits 50 is performed in the first subframe period, writing of the G pixel data (G data writing) to each of the pixel circuits 50 is performed in the second subframe period, and writing of the B pixel data (B data writing) to each of the pixel circuits 50 is performed in the third subframe period, on the basis of input signals Sin (refer to FIG. 28A to be described later). The pixel circuits 50 sequentially emit red light, green light, and blue light in accordance with the R pixel data, the G pixel data, and the B pixel data sequentially written in the pixel circuits 50, which results in sequential additive color mixture to display the color image in the display 500.

### 1.8 Actions in Current Measurement Mode

A description will be given below of actions of the organic EL display device according to the present embodiment in the current measurement mode.

### 1.8.1 Control Process in Display Control Circuit

First, a description will be given of a control process performed in the display control circuit 100 to cause the writing control line driving circuit 300 and the monitor control line driving circuit 400 to perform desired actions in the current measurement mode. In each frame period, in a state where the monitor enable signal Mon_EN is set to a low level, the compensation target line address Addr indicating the compensation target row is set in the compensation target line address storage memory 112, and the writing line counter 111 is initialized, a pulse of the start pulse signal GSP indicating start of actions of the writing control line driving circuit 300 is output. Moreover, one horizontal period after the pulse of the start pulse signal GSP is output, the pulse of the start pulse signal MSP indicating start of actions of the monitor control line driving circuit 400 is output. After the output of the pulse of the start pulse signal GSP, the writing count value CntWL increases on the basis of the clock signals CLK1 and CLK2.

As described above, the matching circuit 113 determines whether the writing count value CntWL output from the writing line counter 111 and the compensation target line address Addr stored in the compensation target line address storage memory 112 match. When the writing count value CntWL and the compensation target line address Addr match, the matching signal MS supplied to the status machine 115 changes from a low level to a high level. In this operation, the following control is performed by the status machine 115. Note that the time point at which the writing count value CntWL and the compensation target line address Addr match serves as a time point of start of a characteristics detection process period.

### (a) Control on Clock Signals CLK1 and CLK2

One horizontal interval after the time point at which the writing count value CntWL and the compensation target line address Addr match, both the clock signal CLK1 and the clock signal CLK2 are set to a low level. Thereafter, throughout the current measurement period, the clock actions of the clock signals CLK1 and CLK2 are stopped. After the current measurement period ends, the states of the clock signals CLK1 and CLK2 are returned to the states immediately before the start of the current measurement period.

### (b) Control on Clock Signals CLK3 and CLK4

One horizontal interval after the time point at which the writing count value CntWL and the compensation target line address Addr match, both the clock signal CLK3 and the clock signal CLK4 are changed similarly to a normal case. Thereafter, throughout the current measurement period, the clock actions of the clock signals CLK3 and CLK4 are stopped. After the current measurement period ends, the clock actions by the clock signals CLK3 and CLK4 are restarted.

### (c) Control on Monitor Enable Signal Mon_EN

One horizontal interval after the time point at which the writing count value CntWL and the compensation target line address Addr match, the monitor enable signal Mon_EN is set to a high level. Thereafter, throughout the current measurement period, the monitor enable signal Mon_EN is maintained at a high level. After the current measurement period ends, the monitor enable signal Mon_EN is changed to a low level.

In other words, the drive controller 110 in the display control circuit 100 performs the following control process. The drive controller 110 controls the clock signals CLK1 and CLK2 so that only the electric potential of the clock signal supplied to the unit circuit 30 corresponding to the compensation target row among the two clock signals CLK1 and CLK2 is changed at the times of start and end of the current measurement period and so that the clock actions of the clock signals CLK1 and CLK2 are stopped throughout the current measurement period. Moreover, the drive controller 110 controls the clock signals CLK3 and CLK4 so that, after the electric potentials of the clock signals CLK3 and CLK4 are changed at the time of start of the current measurement period, the clock actions of the clock signals CLK3 and CLK4 are stopped throughout the current measurement period. The drive controller 110 also changes the monitor enable signal Mon_EN to be active (high level) only in the current measurement period.

Note that in the current measurement mode, the subframe reset signal SUBF_RST in a high level is supplied to the light emission control line activation circuit 350a, and thereby all the light emission enable signals GGem(1) to GGem(n) are in low level (refer to FIG. 19 to FIG. 20) to maintain the first to third selection signals SEL1 to SEL3 in a high level. Consequently, all the first to third light emission control lines EM1(1) to EM1(n), EM2(1) to EM2(n), and EM3(1) to EM3(n) are maintained in a low level (inactive state), and hence the light emission control transistors T3 to T5 in each pixel circuit 50 are in an OFF state (refer to FIG. 15).

### 1.8.2 Actions of Writing Control Line Driving Circuit

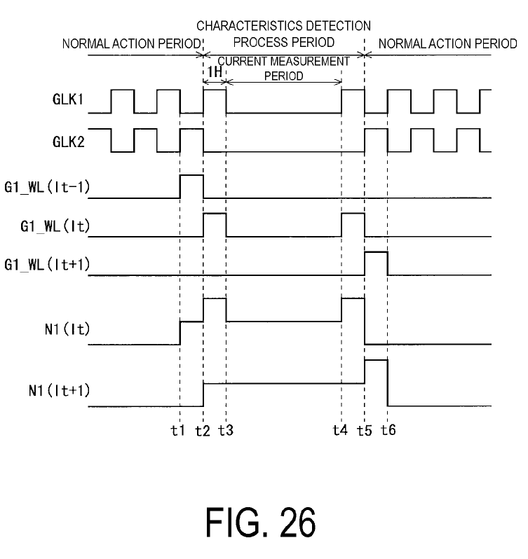

A description will be given of actions of the writing control line driving circuit 300 in or around the characteristics detection process period with reference to the contents in the above-descried control process in the display control circuit 100. FIG. 26 is a timing chart for describing actions of the writing control line driving circuit 300. Note that the It-th row is assumed to be determined as a compensation target row.

At a time point t1, the writing control line G1_WL(It−1) in the (It−1)-th column turns into an active state. Thereby, normal data writing is performed in the (It−1)-th row. Moreover, the change of the writing control line G1_WL(It−1) in the (It−1)-th row into an active state causes the electric potential of the first node N1(It) to increase in the unit circuit 30(It) in the It-th stage in the shift register 3. Note that until the time point immediately before a time point t2, the compensation target line address Addr and the writing count value CntWL do not match.

At the time point t2, the clock signal CLK1 rises. Consequently, the electric potential of the first node N1(It) further increases in the unit circuit 30(It) in the It-th stage. As a result of this, the writing control line G1_WL(It) in the It-th row turns into an active state. In this active state, pre-compensation data is written into each of the pixel circuits 50 in the It-th row. Moreover, at the time point t2, the change of the writing control line G1_WL(It) in the It-th row into an active state causes the electric potential of the first node N1(It+1) to increase in the unit circuit 30(It+1) in the (It+1)-th row in the shift register 3.

At the same time, at the time point t2, due to the rising of the clock signal CLK1, the compensation target line address Addr and the writing count value CntWL match. Consequently, the display control circuit 100 drops the clock signal CLK1 at a time point t3, which is one horizontal interval after the time point t2, and thereafter stops the clock actions of the clock signals CLK1 and CLK2 until the time point of the end of the current measurement period (time point t4). In other words, in the period from the time point t3 to the time point t4, the clock signal CLK1 and the clock signal CLK2 are maintained in a low level.

Note that, at the time point t3, the electric potential of the first node N1(It) decreases in the unit circuit 30(It) in the It-th stage as a result of the drop of the clock signal CLK1. Moreover, the clock signal CLK2 does not rise at the time point t3, and thus the writing control line G1_WL(It+1) in the (It+1)-th row does not turn into an active state. Hence, the reset signal R in a high level is not input to the unit circuit 30(It) in the It-th stage. Consequently, the electric potential of the first node N1(It) in the unit circuit 30(It) in the It-th stage at the time point immediately after the time point t3 is approximately equal to the electric potential at the time point immediately before the time point t2.

In the period from the time point t3 to the time point t4 (current measurement period), measurement of a drive current for detecting the characteristics of the drive transistor T2 is performed. In the current measurement period, the clock actions of the clock signals CLK1 and CLK2 are stopped. Consequently, the electric potential of the first node N1(It) in the unit circuit 30(It) in the It-th stage is maintained in the current measurement period.

At the time point t4, which is the time point of the end of the current measurement period, the display control circuit 100 restarts the clock actions of the clock signals CLK1 and CLK2. At this time, the signal that has been dropped at the time point of the start of the current measurement period (time point t3) of the clock signal CLK1 and the clock signal CLK2 is raised (clock signal CLK1 in the example illustrated in FIG. 26). Since the clock signal CLK1 thus rises at the time point t4, the electric potential of the first node N1(It) increases in the unit circuit 30(It) in the It-th stage. As a result of this, the writing control line G1_WL(It) in the It-th row turns into an active state. In this state, post-compensation data is written into each of the pixel circuits 50 in the It-th row.

At the time point t5, the clock signal CLK1 drops, and the clock signal CLK2 rises. In the period after this time point t5, the writing control lines G1_WL sequentially turn into an active state one row by one row. Thereby, normal data writing is performed in each row.

### 1.8.3 Actions of Monitor Control Line Driving Circuit

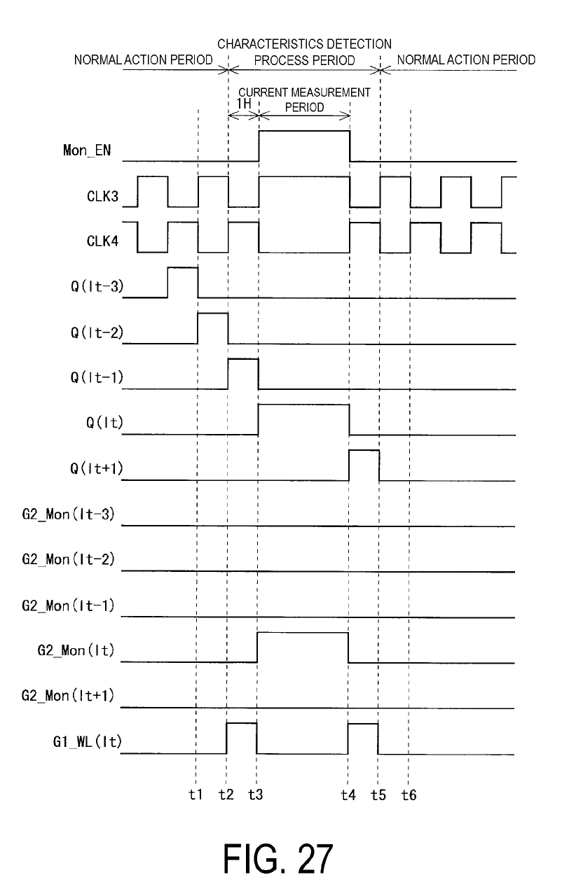

A description will be given of actions of the monitor control line driving circuit 400 in or around the characteristics detection process period with reference to the contents in the above-descried control process in the display control circuit 100. FIG. 27 is a timing chart for describing actions of the monitor control line driving circuit 400. Note that the It-th row is assumed to be determined as a compensation target row also in this case.

In the monitor control line driving circuit 400, the state signals Q output from the respective unit circuits 40 in the shift register 4 are sequentially changed to a high level each one horizontal interval on the basis of the clock signals CLK3 and CLK4. For example, in the period from the time point t1 to the time point t2, the state signal Q(It−2) output from the unit circuit 40(It−2) in the (It−2)-th stage is in a high level, and in the period from the time point t2 to the time point t3, the state signal Q(It−1) output from the unit circuit 40(It−1) in the (It−1)-th stage is in a high level. However, in the period before the time point immediately before the time point t3, the monitor enables signal Mon_EN is in a low level, and hence the monitor control line G2_Mon(It−2) in the (It−2) row and the monitor control line G2_Mon(It−1) in the (It−1)-th row do not turn in an active state.

At the time point t2, the compensation target line address Addr and the writing count value CntWL match. Consequently, the display control circuit 100 changes the monitor enable signal Mon_EN from a low level to a high level at the time point t3, which is one horizontal interval after the time point t2. As a result of this, at the time point t3, the transistors T49 in all the unit circuits 40 turn into an ON state. Moreover, at the time point t3, the state signal Q(It) output from the unit circuit 40(It) in the It-th stage changes to a high level. Through the above, the output signal Q2(It) output from the unit circuit 40(It) in the It-th stage changes to a high level, and consequently, the monitor control line G2_Mon(It) in the It-th row turns into an active state.

Moreover, the display control circuit 100 changes the values of the clock signal CLK3 and the clock signal CLK4 at the time point t3 and thereafter stops the clock actions of the clock signals CLK3 and CLK4 in the current measurement period (period from the time point t3 to the time point t4). In the example illustrated in FIG. 27, the clock signal CLK3 changes from a low level to a high level, and the clock signal CLK4 changes from a high level to a low level, at the time point t3, and thus the clock signal CLK3 is maintained in a high level while the clock signal CLK4 is maintained in a low level, in the current measurement period. The clock actions based on the clock signals CLK3 and CLK4 are thus stopped, and hence the monitor control line G2_Mon(It) in the It-th row is maintained in an active state in the current measurement period.

At the time point t4, which is the time point of the end of the current measurement period, the display control circuit 100 changes the monitor enable signal Mon_EN from a high level to a low level and restarts the clock actions of the clock signals CLK3 and CLK4. In the period from the time point t4 to the time point t5, the state signal Q(It+1) output from the unit circuit 40(It+1) in the (It+1)-th stage is in a high level, but the monitor enable signal Mon_EN is in a low level. Therefore, the monitor control line G2_Mon(It+1) in the (It+1)-th row does not turn into an active state. Similarly, in the period after the time point t5, none of the monitor control lines G2_Mon turns into an active state.

### 1.8.4 Actions for Measuring Drive Current in Pixel Circuit

As has already been described, in the normal display mode, to display a color image by sequential additive color mixture, writing of the R pixel data (R data writing) to each pixel circuit 50 is performed in the first subframe period, writing of the G pixel data (G data writing) to each pixel circuit 50 is performed in the second subframe period, and writing of the B pixel data (B data writing) to each pixel circuit 50 is performed in the third subframe period (refer to FIG. 28A). In contrast to this, in the current measurement mode, pixel data (data indicating the gray scale P1 or P2) is written into each pixel circuit 50 by sequentially causing the writing control lines G1_WL(1) to G1_WL(n) to turn into an active state in the respective frame periods without dividing each frame period into a plurality of subframe periods, and a current (drive current) passing through the drive transistor T2 in each of the pixel circuits 50 connected to either one of the writing control line G1_WL(i) and the monitor control line G2_Mon(i) in each frame period is measured (FIG. 28B).

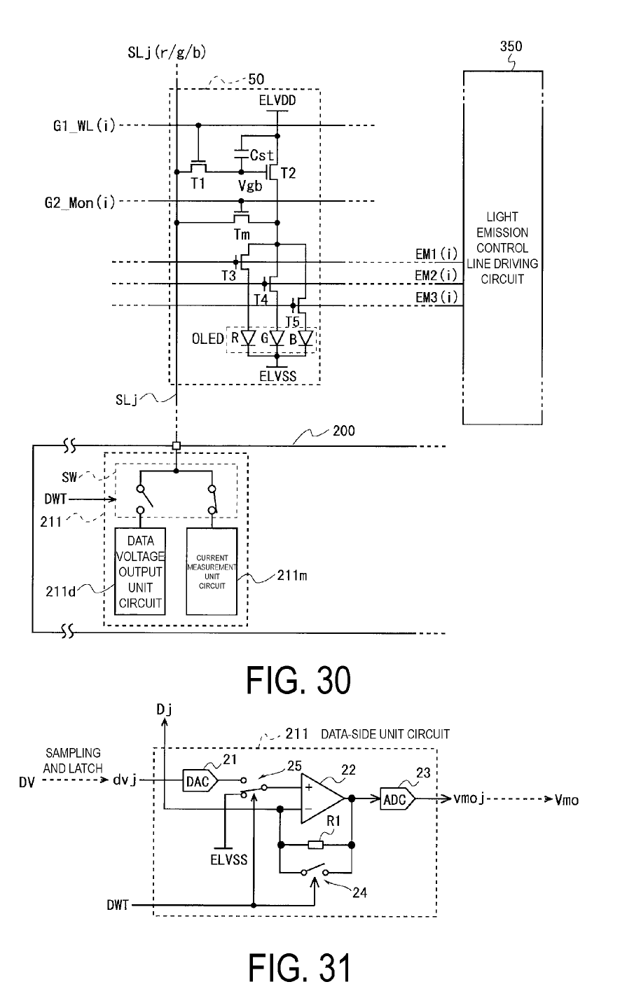

FIG. 29 is a timing chart illustrating changes in states (changes between an active state and inactive state) of the writing control lines G1_WL and the monitor control lines G2_Mon in the current measurement mode. FIG. 30 is a circuit diagram for describing actions for current measurement in the pixel circuit 50 and illustrates a configuration of a part of the display 500 and the data-side driving circuit 200 in the present embodiment corresponding to driving of one data line SLj.

FIG. 30 illustrates a connection configuration in a state where the input/output control signal DWT is changed from a high level to a low level in the circuit illustrated in FIG. 4. The m data-side unit circuits 211 in the data-side driving circuit 200 correspond to the m data lines SL1 to SLm in the display 500 one by one. As illustrated in FIG. 30, in the current measurement mode, the current measurement unit circuit 211m in each data-side circuit 211 is connected to the corresponding one of the data lines SLj in the current measurement period. The data-side unit circuit 211 in the circuit illustrated in FIG. 30 may be assumed to have a configuration illustrated in FIG. 31, for example. FIG. 31 illustrates a connection configuration in a state where the input/output control signal DWT is changed from a high level to a low level in the data-side unit circuit 211 illustrated in FIG. 5. In the data-side unit circuit 211 illustrated in FIG. 31, the first switch 24 is in an OFF state, and hence the inverting input terminal and the output terminal of the operational amplifier 22 are connected to each other via the resistance element R1. Moreover, the low level supply voltage ELVSS is output from the second switch 25 and is supplied to the noninverting input terminal of the operational amplifier 22.

In the action example illustrated in FIG. 29, actions of the writing control line driving circuit 300 and the monitor control line driving circuit 400 described above (FIG. 26 and FIG. 27) cause the writing control lines G1_WL(1) to G1_WL(5) to sequentially turn into an active state in each one horizontal interval, and the compensation target line address Addr and the writing count value CntWL match at the time point t2, so that the period from the time point t3 to the time point t4 serves as a current measurement period. The compensation target row It in FIG. 26 and FIG. 27 is the fifth row (It=5) in the example illustrated in FIG. 29. As has been described above, in this current measurement period t3 to t4, all the writing control lines G1_WL are in an inactive state, and the monitor enable signal Mon_EN is in a high level. Hence, the monitor control line G2_Mon(It) is in an active state.

While the writing control line G1_WL(It) is in an active state (a period t2 to t3) immediately before the current measurement period t3 to t4, the input transistor T1 of each pixel circuit (referred to as a “target pixel circuit” below) 50 in the compensation target row It is in an ON state. In this state, the input/output control signal DWT is in a high level, and hence the drive data signal Dj (pre-compensation data) is written into the target pixel circuit 50 as pixel data by the data voltage output unit circuit 211d in each data-side unit circuit 211. More specifically, the drive data signals Dj each indicating a gray scale voltage, which is pre-compensation data, are sequentially written into the pixel circuits 50 in the compensation target row It as pixel data (refer to FIG. 4).

At the time point t3, the writing control line G1_WL(It) turns into an inactive state, and the current measurement period starts. In the current measurement period t3 to t4, the input transistor T1 of the target pixel circuit 50 is in an OFF state, and the data voltage corresponding to the pre-compensation pixel data is held in the capacitor Cst of the target pixel circuit. Moreover, at the time point t3, the input/output control signal DWT changes to a low level, and the current measurement unit circuit 211m in each data-side unit circuit 211 is connected to the corresponding data line SLj. Furthermore, the monitor enable signal Mon_EN changes to a high level, and thus the monitor control line G2_Mon(It) turns into an active state (high level). Therefore, the monitor control transistor Tm of the target pixel circuit 50 turns into an ON state. Hence, in the current measurement period t3 to t4, the drive current of the target pixel circuit 50 is supplied to the current measurement unit circuit 211m via the monitor control transistor Tm of the pixel circuit 50 and the data line SLj connected to the monitor control transistor Tm (refer to FIG. 30). Each current measurement unit circuit 211m measures the drive current of the target pixel circuit 50 thus supplied and outputs the monitor voltage vmoj indicating a result of the measurement (refer to FIG. 31).

Note that in the current measurement mode, since the light emission control transistors T3 to T5 in each pixel circuit 50 are in an OFF state as has been described, all the organic EL elements OLED in the display 500 are in a lit-out state. Moreover, each data line SLj (j=1 to m) is maintained at the low level supply voltage ELVSS by the current measurement unit circuit 211m having the configuration as illustrated in FIG. 31 (the data-side unit circuit 211 at the time when the input/output control signal DWT is in a low level) in the current measurement period t3 to t4, and thus the source terminal of the drive transistor T2 in the target pixel circuit 50 is also maintained at the low level supply voltage ELVSS (refer to FIG. 30). Hence, even when there are one or more light emission control transistors T3 to T5 that are in an ON state in the target pixel circuit 50 in the current measurement mode, no current flows into any of the organic EL elements OLED in the target pixel circuit 50 in the current measurement period t3 to t4.

The monitor voltage vmoj output from each current measurement unit circuit 211m is transmitted to the correction data calculator/storage 120 in the display control circuit 100 as the current measurement result Vmo obtained in the current measurement circuit 220 (refer to FIG. 1). As has been already described, the correction data calculator/storage 120 holds correction data (offset value and gain value), calculates new correction data (offset value and gain value) at the time when two current measurement results corresponding to two kinds of gray scales (first gray scale P1 and second gray scale P2: P2>P1) are obtained for each target pixel circuit 50, and updates the held correction data by the calculated data.

As illustrated in FIG. 29, when the monitor control line G2_Mon(It) corresponding to the compensation target row It changes to a low level at the time point t4 after the current measurement, the monitor control transistor Tm of each target pixel circuit 50 turns into an OFF state. Moreover, as illustrated in FIG. 29, the clock signal CLK1 rises at the time point t4, and consequently, the writing control line G1_WL(It) is turned into an active state (changed to a high level). In this state, the input/output control signal DWT turns into a high level, the data voltage output unit circuit 211d in each data-side unit circuit 211 is connected to the corresponding data line SLj, and hence the drive data signal Dj (post-compensation data) is written into the target pixel circuit 50 as pixel data by the data voltage output unit circuit 211d. More specifically, the drive data signal Dj indicating a gray scale voltage after the compensation, which is post-compensation data, is written into the corresponding pixel circuit in the compensation target row It as pixel data (j=1 to m) (refer to FIG. 4). Note that a predetermined gray scale voltage value (default gray scale voltage) is written into the pixel circuit 50 for which the current measurement of only one of the first and second gray scales P1 and P2 is completed, as pixel data.

### 1.8.5 Characteristics Detection Process

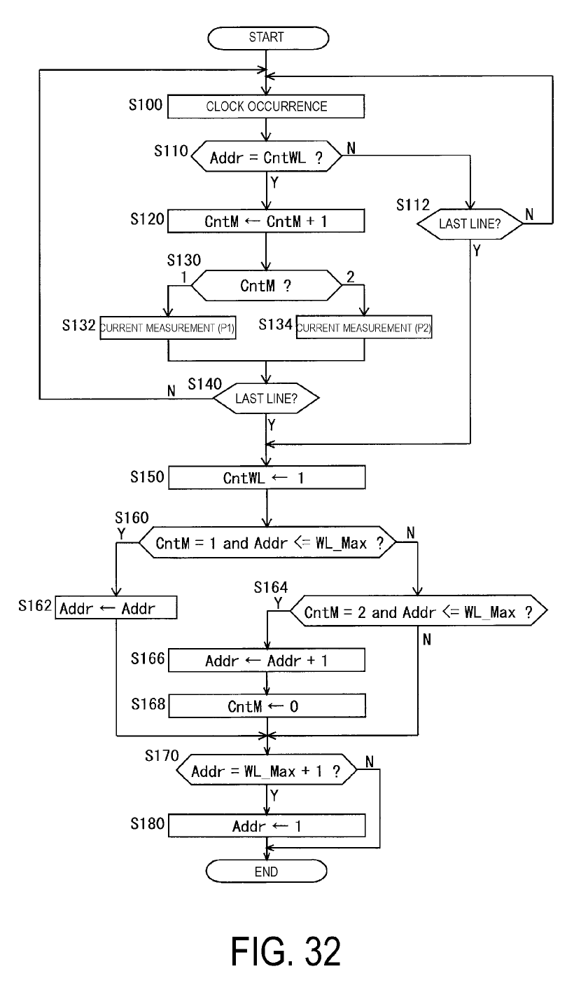

Next, with reference to FIG. 32 together with FIG. 6, a description will be given of a series of operations performed in the present embodiment to detect characteristics of the drive transistor T2 of the pixel circuit 50 on the basis of the current detection (referred to as a “characteristics detection process” below). FIG. 32 is a flowchart illustrating a control procedure for this characteristics detection process. Note that it is assumed that the writing line counter 111 and the matching counter 114 are initialized in advance and that the value of the compensation target line address Addr stored in the compensation target line address storage memory 112 is a value indicating the compensation target row.

After the characteristics detection process is started, one writing control line G1_WL is selected as a scan target every time a clock pulse of the clock signal CLK1 or the clock signal CLK2 is generated (Step S100). Determination on whether the compensation target line address Addr stored in the compensation target line address storage memory 112 and the writing count value CntWL output from the writing line counter 111 match, is performed (Step S110). As a result of this, when the values match, the process advances to Step S120. When the values do not match, on the other hand, the process advances to Step S112. In Step S112, determination on whether the scan target is the writing control line in the last row, is performed. As a result of this, when the scan target is the writing control line in the last row, the process advances to Step S150. When the scan target is not the writing control line in the last row, on the other hand, the process returns to Step S100. Note that in a case where the process advances to Step S112, normal data writing is performed.

In Step S120, the matching count value CntM is incremented by 1. Thereafter, determination on whether the matching count value CntM is 1 or 2 is performed (Step S130). As a result, when the matching count value CntM is 1, the process advances to Step S132. When the matching count value CntM is 2, on the other hand, the process advances to Step S134. In Step S132, measurement of a drive current based on the first gray scale P1 is performed. In Step S134, measurement of a drive current based on the second gray scale P2 is performed.

After the completion of Step S132 or Step S134, determination on whether the scan target is the writing control line in the last row, is performed (Step S140). As a result of this, when the scan target is the writing control line in the last row, the process advances to Step S150. When the scan target is not the writing control line in the last row, on the other hand, the process returns to Step S100.

In Step S150, the writing count value CntWL is initialized. Thereafter, determination on whether the condition that “the matching count value CntM is 1, and the value of the compensation target line address Addr is the value WL_Max indicating the last row or smaller” is satisfied, is determined (Step S160). As a result of this, when the condition is satisfied, the process advances to Step S162. When the condition is not satisfied, on the other hand, the process advances to Step S164.

In Step S162, the same value is substituted into the compensation target line address Addr in the compensation target line address storage memory 112. Note that this Step S162 does not always need to be provided. In Step S164, determination on whether the condition that “the matching count value CntM is 2, and the value of the compensation target line address Addr is the value WL_Max indicating the last row or smaller” is satisfied, is performed. As a result of this, when the condition is satisfied, the process advances to Step S166. When the condition is not satisfied, on the other hand, the process advances to Step S170. In Step S166, the compensation target line address Addr is incremented by 1. In Step S168, the matching count value CntM is initialized.

In Step S170, determination on whether the condition that “the value of the compensation target line address Addr is equal to a value obtained by adding 1 to the value WL_Max indicating the last row” is satisfied, is performed. As a result of this, when the condition is satisfied, the process advances to Step S180. When the condition is not satisfied, on the other hand, it is assumed that the measurement of a drive current in each of the pixel circuits 50 in one compensation target row has ended although the characteristics detection process for the drive transistors of all the pixel circuits 50 in the display 500 is not completed, and the characteristics detection process in FIG. 32 is terminated temporarily. In Step S180, the compensation target line address Addr is initialized, and the characteristics detection process in FIG. 32 is terminated by assuming that the characteristics detection process for the drive transistors of all the pixel circuits 50 in the display 500 has been completed.

### 1.8.6 Compensation Process

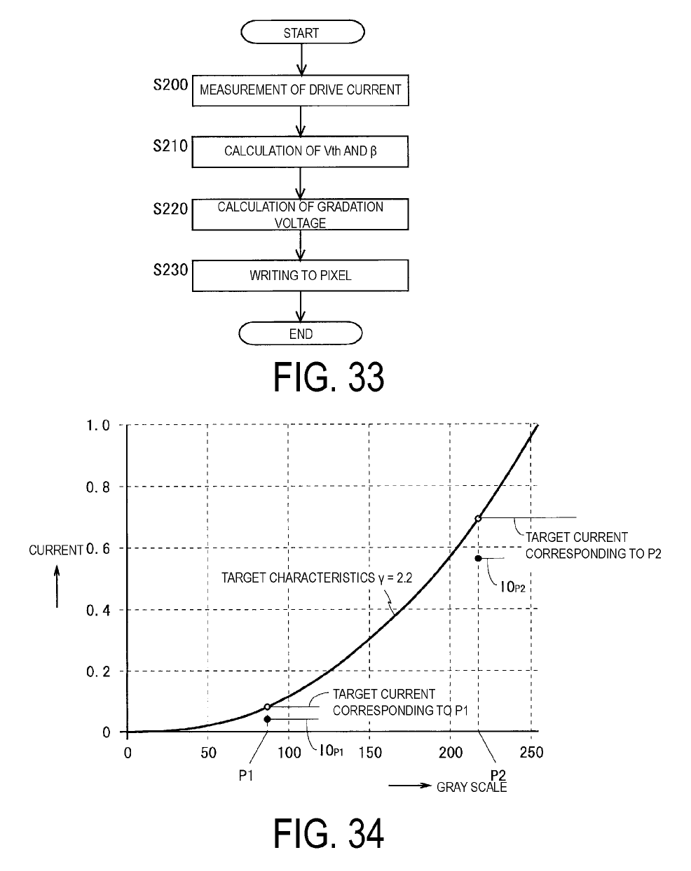

Next, with reference to FIG. 33, a description will be given of a series of operations performed in the present embodiment to compensate variations in characteristics of the drive transistors T2 of the pixel circuits 50 (referred to as a “compensation process” below). FIG. 33 is a flowchart for describing a procedure for the compensation process in a case of focusing on one pixel (pixel at i-th row, j-th column).

First, measurement of a drive current is performed in the characteristics detection process period as described above (Step S200). The measurement of a drive current is performed on the basis of the two kinds of gray scales (the first gray scale P1 and the second gray scale P2: P2>P1). The measurement of a drive current based on these two kinds of gray scales may be configured such that measurement of a drive current based on the first gray scale P1 is performed in the first frame period of two consecutive frame periods while measurement of a drive current is performed based on the second gray scale P2 in the second frame period. However, the present invention is not limited to this. The timing to start the actions in the current measurement mode and the duration of the actions are determined by the above-described mode control signal Cm. Hence, in the present embodiment, two frame periods in which a drive currents based on the two kinds of gray scales are measured in each of the pixel circuits 50 in one compensation target row may be consecutive, but there may be a frame period in the normal display mode between these two frame periods.

In the present embodiment, measurement of a drive current based on the first gray scale P1 is performed in the first frame period of the above-described two frame periods for measuring a drive current for one compensation target row, and measurement of a drive current based on the second gray scale P2 is performed in the second frame period. More specifically, measurement of a drive current obtained by writing a first measurement gray scale voltage Vmp1 as pixel data into the pixel circuit 50 calculated according to Equation (1) below is performed in the first frame, and measurement of a drive current obtained by writing a second measurement gray scale voltage Vmp2 as pixel data into the pixel circuit 50 calculated according to Equation (2) below is performed in the second frame.

Vmp1=Vcw*Vn(P1)*B(i,j)+Vth(i,j) (1)

Vmp2=Vcw*Vn(P2)*B(i,j)+Vth(i,j) (2)

Here, Vcw is the difference between the gray scale voltage corresponding to the minimum gray scale and the gray scale voltage corresponding to the maximum gray scale (i.e., the range of gray scale voltage). Vn(P1) is a value obtained by normalizing the first gray scale P1 to a value in the range from 0 to 1, and the Vn(P2) is a value obtained by normalizing the second gray scale P2 to a value in the range from 0 to 1. B(i, j) is a normalization coefficient for the pixel at i-th row, j-th column calculated according to Equation (3) below. Vth(i, j) is an offset value for the pixel at i-th row, j-th column (this offset value corresponds to a threshold voltage of the drive transistor).

B=√(β0/β) (3)

Here, β0 is the average value of the gain values of all the pixels, and β is a gain value for the pixel at i-th row, j-th column.

After the measurement of a drive current based on the two kinds of gray scales, the offset value Vth and the gain value β are calculated on the basis of the measurement values (Step S210). The operation in this Step S210 is performed by the correction arithmetic circuit 122 in the correction data calculator/storage 120 (refer to FIG. 10). For the calculation of the offset value Vth and the gain value β, Equation (4) below representing the relationship between the drain-source current (drive current) Ids and the gate-source voltage Vgs of the transistor, is used.

Ids=β*(Vgs−Yth)² (4)

Specifically, the offset value Vth expressed by Equation (5) below and the gain value β expressed by Equation (6) below are obtained according to the simultaneous equations of the equation obtained by substituting the measurement result based on the first gray scale P1 into Equation (4) above and the equation obtained by substituting the measurement result based on the second gray scale P2 into Equation (4).

Vth={Vgsp2√(IOp1)−Vgsp1√(IOp2)}/{√(IOp1)−√(IOp2)} (5)

β={√(IOp1)−√(IOp2)}²/(Vgsp1−Vgsp2)² (6)

Here, IOp1 denotes a drive current as a measurement result based on the first gray scale P1, and IOp2 denotes a drive current as a measurement result based on the second gray scale P2. Moreover, Vgsp1 denotes a gate-source voltage based on the first gray scale P1, and Vgsp2 denotes a gate-source voltage based on the second gray scale P2. As described above, in the present embodiment, the source terminal of the drive transistor T2 in the pixel circuit 50 for which a drive current is measured is maintained at the low level supply voltage ELVSS (refer to FIG. 30 and FIG. 31). A description will be given below by assuming this low level supply voltage ELVSS as “0”. In this case, Vgsp1 is given by Equation (7) below, and Vgsp2 is given by Equation (8) below.

Vgsp1=Vmp1 (7)

Vgsp2=Vmp2 (8)

By using the offset value Vth and the gain value β calculated as described above, the correction data held in the nonvolatile memory 123 in the correction data calculator/storage 120 (refer to FIG. 10) is updated. Note that to perform the operation in Step S210 at a high speed, the data of the measurement values obtained in Step S200 are temporarily stored in a memory, such as a static random access memory (SRAM) and a dynamic random access memory (DRAM), with which high speed access is possible.

Next, to write the pixel data in the pixel circuit 50 of i-th row, j-th column, the gray scale voltage Vp is calculated according to Equation (9) below by using the offset value Vth and the gain value β (Step S220). This operation in Step S220 is performed by the gray scale correction unit 130 (refer to FIG. 1).

Vp=Vcw*Vn(P)*√(β0/β)+Vth+Vf (9)

Here, Vn(P) is a value obtained by normalizing the display gray scale at the pixel of i-th row, j-th column to a value in the range from 0 to 1. Vf denotes a forward voltage of the organic EL element OLED and is assumed to be a known fixed value in the present embodiment. Note that it is assumed that the drain-source voltages of the light emission control transistors T3 to T5 can be ignored.

Thereafter, the gray scale voltage Vp calculated in Step S220 is written into the pixel circuit 50 of i-th row, j-th column as pixel data (Step S230). By performing the above-described compensation process on each of all the pixels, variations in characteristics of the drive transistors can be compensated.

FIG. 34 is a diagram illustrating gray scale-current characteristics. In FIG. 34, characteristics when y=2.2 are illustrated as target characteristics. In a case where deterioration occurs in drive transistors, the drive current IOp1 obtained when writing of pixel data based on the first gray scale P1 is performed does not match a target current corresponding to the first gray scale P1, and the drive current IOp2 obtained when writing of the pixel data based on the second gray scale P2 is performed does not match a target current corresponding to the second gray scale P2. However, in the present embodiment, the offset value Vth and the gain value β are calculated for each pixel circuit 50 in the above-described method on the basis of the above drive currents IOp1 and IOp2. Each of the gray scale voltages indicated by display data signals DA based on the RGB video data signal Din from the external unit is corrected by using the offset value Vth and the gain value β calculated for each of the pixel circuits 50 into which the gray scale voltage is to be written, and the gray scale voltage after the correction is written into the pixel circuit 50 as pixel data. In this way, a drive current approximately equal to the target current passes through each of the pixel circuits 50 in relation to a certain gray scale voltage indicated by the display data signal DA as a gray scale voltage to be written into the pixel circuit 50. As a result, occurrence of variations in luminance in the display screen is suppressed, which enables high picture quality display.

In the above example, in the second frame period of the above-described two frame periods for measuring drive currents for one compensation target, new correction data (offset value and gain value) is calculated on the basis of a result of current measurement based on the first gray scale P1 obtained in the first frame period and a result of current measurement based on the second gray scale P2 obtained in the second frame period. However, in a case where a frame period in the normal display mode exists between the two frame periods in the current measurement mode, new correction data (offset value and gain value) is calculated also in the first frame period, on the basis of a result of current measurement based on the first gray scale P1 obtained in the first frame period and a result of current measurement based on the second gray scale P2 performed for the compensation target row before the first frame period. In this case, in the frame period in the normal display mode between the first frame period and the second frame period, the digital video signal DV is generated by correcting gray scale data indicated by the display data signal DA based on the new correction data in the gray scale correction unit 130 (refer to FIG. 1), and the pixel data is written into each of the pixel circuits 50 on the basis of the digital video signal DV to display a color image. Note that, in the frame period in the normal display mode in a state where correction data has not been calculated yet, the gray scale correction unit 130 outputs, as the digital video signal DV, the gray scale data indicated by the display data signal DA without correction (refer to FIG. 1), and the pixel data is written into each of the pixel circuits 50 on the basis of the digital video signal DV to display a color image.

### 1.9 Effects

In the known organic EL display device, the R pixel circuit 50r, the G pixel circuit 50g, and the B pixel circuit 50b are used to form one pixel in a color image to be displayed, as illustrated in FIG. 3. In contrast to this, in the present embodiment, only one pixel circuit 50 is used to form the one pixel, as illustrated in FIG. 4. Hence, according to the present embodiment, the area of the display necessary to display a color image at certain resolution (number of pixels) can be significantly reduced in comparison with the area in a known case using the same resolution.

As illustrated in FIG. 3 and FIG. 4, according to the present embodiment, the R pixel circuit 50r, the G pixel circuit 50g, and the B pixel circuit 50b for forming one pixel in the known case are implemented by one pixel circuit 50, and hence the number of data lines necessary to display a color image at certain resolution is reduced to one third of that in the known case for the same resolution. In view of this, according to the present embodiment, the number of data-side unit circuits 211 provided for each of the data lines in the data-side driving circuit is accordingly reduced to one third of that of the known case. As illustrated in FIG. 3 and FIG. 4, in the organic EL display device using the external compensation method, one data-side unit circuit 211 also includes the current measurement unit circuit 211m as well as the data voltage output unit circuit 211d. Hence, the present embodiment assuming the external compensation method exerts significant effects also in the reduction of the contents of circuits in the data-side driving circuit.

As described above, according to the present embodiment, it is possible to reduce not only the contents of the circuits in the display 500, in which the pixel circuits for forming an image to be displayed are arranged in a matrix but also the contents of circuits in the data-side driving circuit, which makes it possible to display a high-resolution color image while minimizing an increase in cost. A detailed description will be given below of such effects of the present embodiment from a quantitative viewpoint.

### 1.9.1 Effects Related to Pixel Circuits

As illustrated in FIG. 3, in the known organic EL display device, each of the pixels of a color image to be displayed is constituted of an R sub pixel, a G sub pixel, and a B sub pixel, and the pixel circuit for forming each of the sub pixels is implemented by using three transistors T1, T2, and Tm. Hence, three pixel circuits for forming three sub pixels, which are the R sub pixel, the G sub pixel, and the B sub pixel are needed to form one pixel, and thus 3*3=9 transistors are needed to implement the three pixel circuits.

In contrast to this, as illustrated in FIG. 4, in the present embodiment, each of the pixels of a color image to be displayed is formed by one pixel circuit 50 including the organic EL elements OLED(R), OLED(G), and OLED(B) respectively emitting red light, green light, and blue light. Accordingly, 3+3=6 transistors including three transistors T1, T2, and Tm in the pixel circuit illustrated in FIG. 3 and three light emitting transistors T3, T4, and T5 corresponding to the three respective organic EL elements OLED(R), OLED(G), and OLED(B) are needed to implement the pixel circuit to form one pixel.

In both the known organic EL display device and the present embodiment, the transistors included in each pixel circuit are thin film transistors (TFTs). Assume that the length of one TFT (length in the channel length direction) is x and the width of one TFT (length in the channel width direction) is y. Then, an occupation area Sp of the necessary TFTs to form one pixel in the known organic EL display device is equal to the area for forming nine TFTs, which is

Sp=9x*1y=9xy,

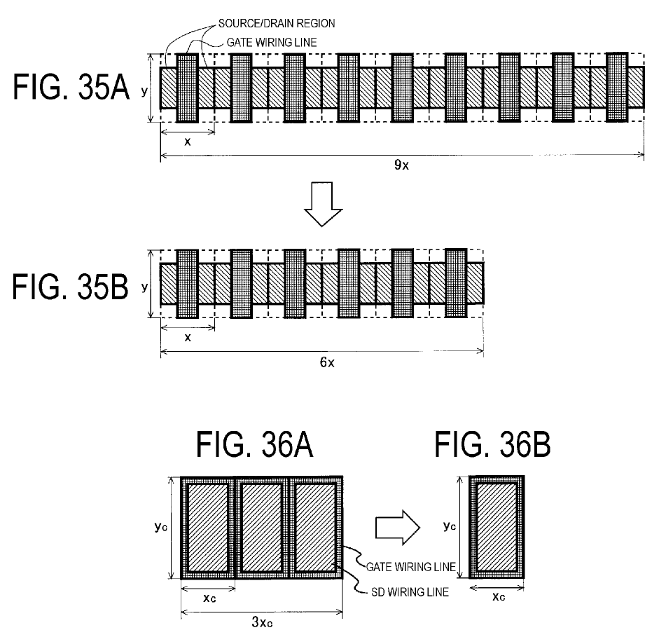

as illustrated in FIG. 35A. In contrast to this, an occupation area Sq of the necessary TFTs to form one pixel in the present embodiment is equal to the area for forming six TFTs, which is

Sq=6x*1y=6xy,

as illustrated in FIG. 35B. Note that in FIGS. 35A and 35B, the hatched portion with oblique lines corresponds to a source region or a drain region of the TFT, and the hatched portion with a grid pattern corresponds to gate wiring line of the TFT.

According to the above, a ratio Rt [%] of the occupation area Sq of the TFTs in the present embodiment to the occupation area Sp of the TFTs in the known organic EL display device is

Rt=Sq/Sp*100=(6xy)/(9xy)*100≈67%.

Hence, according to the present embodiment, the occupation area of the TFTs for implementing the pixel circuits in the display is reduced by approximately 33%.

Moreover, assume that the capacitor Cst as a data holding capacity in the pixel circuit is formed in a rectangular shape with gate wiring line and source or drain wiring line (referred to as “SD wiring line” below) and that the length of a short side of the capacitor Cst included in one pixel circuit is denoted by x_{c} while the length of a long side of the capacitor Cst is denoted by y_{c}. On this assumption, the occupation area Scp of the data holding capacity necessary to form one pixel in the known organic EL display device is the area for forming the three capacitors Cst as the data holding capacity in the three pixel circuits and is, as illustrated in FIG. 36A,

Scp=3x_{c}*y_{c}.

In contrast to this, the occupation area Scq of the data holding capacity necessary to form one pixel in the present embodiment is the area for forming the capacitor Cst as the data holding capacity in one pixel circuit and is, as illustrated in FIG. 36B,

Scq=x_{c}*y_{c}.

Note that in FIGS. 36A and 36B, the hatched portion with oblique lines corresponds to SD wiring line, and the hatched portion with a grid pattern corresponds to gate wiring line.

According to the above, a ratio Rc [%] of the occupation area Scq of the data holding capacity in the present embodiment to the occupation area Scp of the data holding capacity in the known organic EL display device is

Rc=Scq/Scp*100=(x_{c}y_{c})/(3x_{c}y_{c})*100≈33%.

Hence, according to the present embodiment, the occupation area of the data holding capacity for implementing the pixel circuits in the display is reduced by approximately 67%.

The pixel circuit is formed of the TFTs and the data holding capacity except for the organic EL elements, and thus the occupation area of the pixel circuit for forming one pixel of an image to be displayed can be significantly reduced according to the present embodiment in combination of the above-described effects of the reduction of the occupation area of the TFTs and the above-described effects of the reduction of the occupancy area of the data holding capacity. Hence, the present embodiment is remarkably advantageous in achieving high resolution of a display image compared to the known configuration. Note that, although only the areas for forming the TFTs and data holding capacity are focused above, areas of the wiring line for connecting the TFTs and the contact portions are also reduced in the present embodiment compared to the known configuration. Hence, in actual, more significant reduction effects than those described above can be obtained with respect to the area of the circuits necessary for forming each one pixel according to the present embodiment.

### 1.9.2 Effects Related to Data-Side Driving Circuit

As illustrated in FIG. 3, in the known organic EL display device, the R data line SLrj, the G data line SLgj, and the B data line SLbj are connected respectively to the R pixel circuit 50r, the G pixel circuit 50g, and the B pixel circuit 50b for respectively forming the R sub pixel, the G sub pixel, and the B sub pixel forming each of the pixels of an image to be displayed, and the data-side unit circuit 211 is connected to each of the three data lines SLrj, SLgj, and SLbj in the data-side driving circuit 200. In contrast to this, in the present embodiment, as illustrated in FIG. 4, each of the pixels of the image to be displayed is formed by one pixel circuit 50, and the data-side unit circuit 211 is connected to the data line SLj connected to this pixel circuit 50 in the data-side driving circuit 200. Accordingly, in a case where a color image is to be displayed in a full high-definition (FHD) method with the number of pixels of 1920*1080 for example, 1080*3 data lines are needed for the known organic EL display device while only 1080 data lines are sufficient in the present embodiment. Hence, according to the present embodiment, in a case of displaying a color image at certain resolution, the number of data lines is one third of that of the known organic EL display device for the same resolution, and the number of the data-side unit circuits in the data-side driving circuit 200 is also one third of that of the known organic EL display device accordingly. As a result of this, the contents of the circuits in the data-side driving circuit 200 is reduced significantly (to approximately ⅓), and consequently, the size and cost of an integrated circuit (IC) for implementing the data-side driving circuit 200 can be significantly reduced. Consequently, the cost of the entire display device can be significantly reduced in combination with the above-described reduction in area of the pixel circuits. In particular, in a case where the external compensation method is adopted as in the present embodiment, each of the data-side unit circuits 211 includes the current measurement unit circuit 211m for measuring a drive current in a target pixel circuit via the data line SLj in addition to the data voltage output unit circuit 211d for outputting the drive data signal Dj as illustrated in FIG. 4, and hence the reduction effects in size and cost are greater than those in a case of not adopting the external compensation method.

Note that in the present embodiment, the light emission control line driving circuit 350 is needed (refer to FIG. 4 and FIG. 18), but the increase in the contents of circuits due to this is not large in consideration of the above-described reduction of the contents of circuits in the display 500 and the above-described reduction of contents of the circuits in the data-side driving circuit 200. Hence, even in consideration of the light emission control line driving circuit 350, sufficient effects can be obtained by the reductions in size and cost according to the present embodiment, which makes it possible to display a high-resolution color image while significantly suppressing an increase in cost.

### 2. Second Embodiment

Next, a description will be given of an active-matrix organic EL display device according to a second embodiment of the present invention.

As has been described, in the above-described first embodiment, the mode control signal Cm indicates, for each frame period, whether to act in the normal display mode or act in the current measurement mode. The organic EL display device according to the above-described first embodiment acts as illustrated in FIG. 25 in the frame period for which the mode control signal Cm indicates the normal display mode while acting as illustrated in FIG. 29 and FIG. 32 in the frame period for which the mode control signal Cm indicates the current measurement mode. In the above-described first embodiment, the mode control signal Cm can specify any frame period to perform current measurement and correction data calculation.

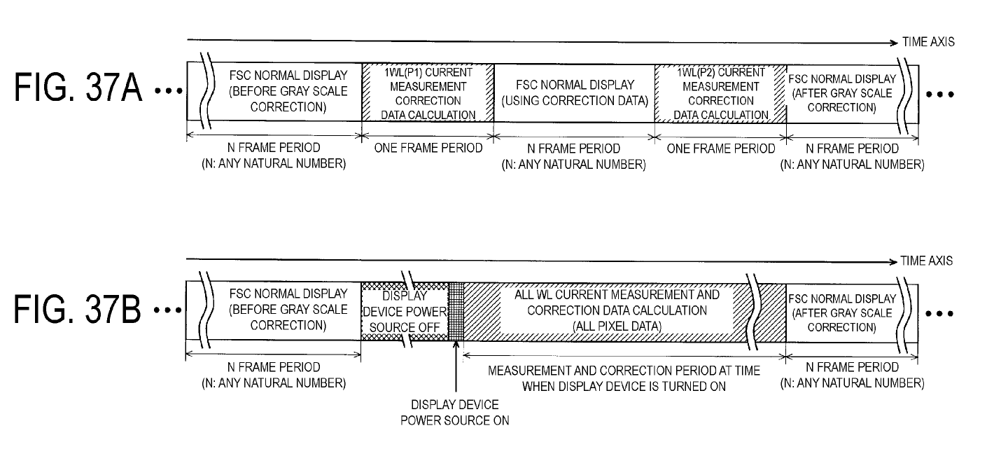

In this configuration, for example, an action of displaying a color image in a field sequential method and an action of measuring a drive current of each of the pixel circuits 50 in one compensation target row for one frame period and calculating correction data (offset value and gain value) on the basis of a result of the measurement, can be performed as illustrated in the timing chart in FIG. 37A. In the action example illustrated in FIG. 37A, after display of a color image in the field sequential method is performed in a period of a certain number of frames (N frame period) (referred to as “FSC normal display” below) is performed as actions of the normal display mode, a drive current in each of the pixel circuits 50 in one row (compensation target row) is measured on the basis of the first gray scale P1 in one frame period as actions of the current measurement mode. Moreover, in the frame period in this current measurement mode, new correction data (offset value and gain value) is calculated on the basis of a result of current measurement based on the first gray scale P1 obtained in this frame period and a result of current measurement based on the second gray scale P2 performed for the compensation target row before this frame period. Hence, in the frame period in this current measurement mode, an action of measuring a drive current for one compensation target row on the basis of the first gray scale P1 to calculate new correction data (referred to as “1WL(P1) current measurement and correction data calculation” below) is performed. Thereafter, as actions in the normal display mode, FSC normal display in which pixel data is written into each pixel circuit 50 on the basis of the gray scale data obtained as a result of correction using new correction data obtained in the frame period in the current measurement mode to display a color image, is performed in the certain frame period (N frame period).

After this, as an action in the current measurement mode, a drive current is measured in each of the pixel circuits 50 in the above-described compensation target row on the basis of the second gray scale P2 in one frame period. Moreover, in the frame period in this current measurement mode, new correction data (offset value and gain value) is calculated on the basis of a result of current measurement based on the second gray scale P2 obtained in this frame period and a result of current measurement based on the first gray scale P1 obtained in the frame period in the current measurement mode immediately before this frame period, to update correction data. Hence, in the frame period in this current measurement mode, actions of measuring a drive current for one compensation target row on the basis of the second gray scale P2 to update correction data (referred to as “1WL(P2) current measurement and correction data calculation” below) are performed. Thereafter, as actions in the normal display mode, FSC normal display in which pixel data is written into each pixel circuit 50 on the basis of gray scale data obtained as a result of correction using correction data obtained as a result of the update in the frame period in the current measurement mode to display a color image, are performed in the certain frame period (N frame period).

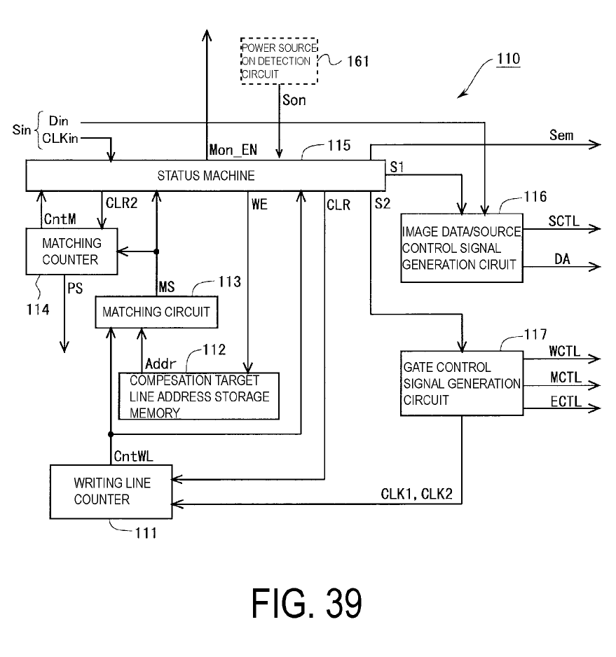

In contrast to this, in the second embodiment of the present invention, a period to perform current measurement and data correction calculation, i.e., a period to act in the current measurement mode, is determined in advance without inputting or generating the mode control signal Cm. For example, as will be described below, in a case where a period to act in the current measurement mode is determined on the basis of the time point at which the display device is turned on, a power source ON detection circuit 161 configured to detect that the display device is turned on is provided in or outside the drive controller 110 in the display device, and a power source ON signal Son output from the power source ON detection circuit 161 is input to the status machine 115 in the drive controller 110 as a signal indicating that the display device is turned on, as illustrated in FIG. 39. A description of the present embodiment will be continued below on the assumption of this configuration. Other configurations of the present embodiment are similar to those of the first embodiment. Hence, the same parts are denoted by the same reference signs below, and detailed descriptions thereof are omitted.

The organic EL display device according to the present embodiment includes a configuration in which, when the display device is turned on, current measurement based on the first gray scale P1 and current measurement based on the second gray scale P2 are performed for each of all the pixel circuits 50 in the display 500 in the period immediately after the turning-on of the display device, on the basis of the above-described power source ON signal Son and new correction data is calculated on the basis of results of the measurements (such current measurement and correction data calculation are referred to as “all WL current measurement and correction data calculation” below), and acts as illustrated in FIG. 37B. In this action example, after FSC normal display is performed in the period of the certain number of frames (N frame period), the display device is turned off. Thereafter, when the display device is turned on, the all WL current measurement and correction data calculation are performed in the period immediately after the turning-on of the display device, and after that, FSC normal display in which pixel data is written into each of the pixel circuits 50 on the basis of gray scale data obtained as a result of correction using new correction data thus calculated to display a color image, is performed in the period of a certain number of frames (N frame period).

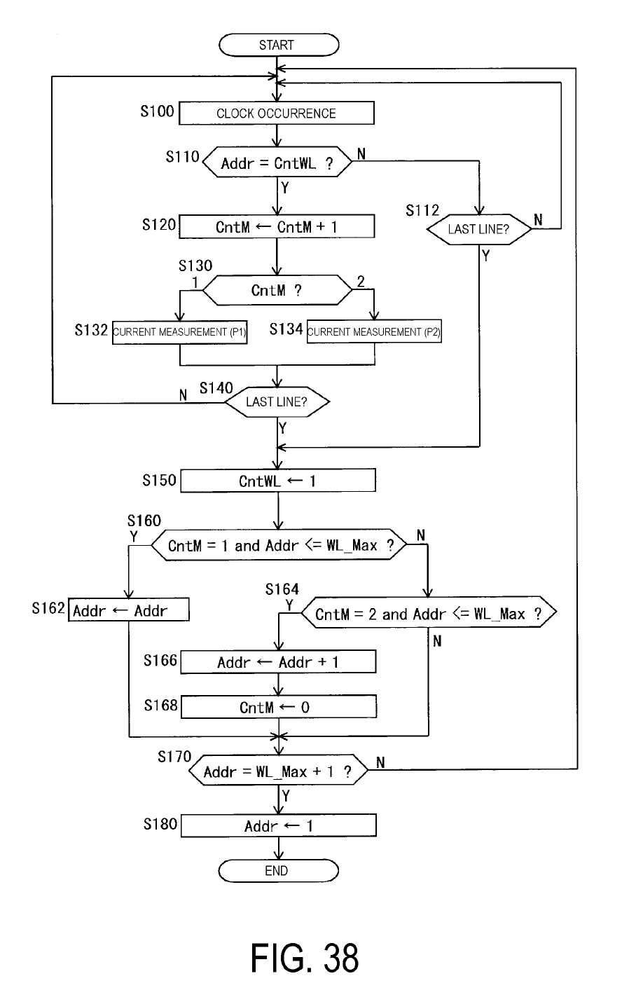

The above-described all WL current measurement and correction data calculation in the present embodiment are specifically implemented by a characteristics detection process in the flowchart illustrated in FIG. 38. In the flowchart in FIG. 32 illustrating the characteristics detection process in the first embodiment, when determination is made on whether the condition that “the value of the compensation target line address Addr is equal to a value obtained by adding 1 to the value WL_Max indicating the last row” is satisfied and the condition is not satisfied in Step S170, it is assumed that measurement of a drive current in each of the pixel circuits 50 in one compensation target row has ended although the characteristics detection process for the drive transistor of each of all the pixel circuits 50 in the display 500 is not completed, and the characteristics detection process in FIG. 32 is terminated temporarily. In contrast to this, in the flowchart in FIG. 38 illustrating the characteristics detection process in the present embodiment, the characteristics detection process is configured such that, when it is determined that the above-described condition is not satisfied in Step S170, the process returns to the first step S100 in the flowchart, which is different from the flowchart in FIG. 32. However, the other operations in the flowchart in FIG. 38 illustrating the characteristics detection process in the present embodiment are similar to those in the flowchart in FIG. 32. Hence, the same steps are denoted by the same reference numerals, and descriptions thereof are omitted.

As described above, in the present embodiment, the timings at and the order in which the actions in the normal display mode (FSC normal display) and the actions in the current measurement mode (current measurement and correction data calculation) are performed are different from those in the above-described first embodiment. However, the configurations of the pixel circuits 50 and the light emission control line driving circuit 350 having characteristics different from the known organic EL display device (FIG. 3) using the external compensation method are similar to those in the first embodiment (refer to FIG. 18). Hence, the present embodiment achieves effects similar to those of the first embodiment. Note that in the present embodiment, the timing at which the actions in the current measurement mode are started is determined in advance (FIG. 37B), and thus the configuration associated with the mode control signal Cm is not needed, which can simplify the configuration to some extent in comparison with that in the first embodiment.

### 3. Third Embodiment

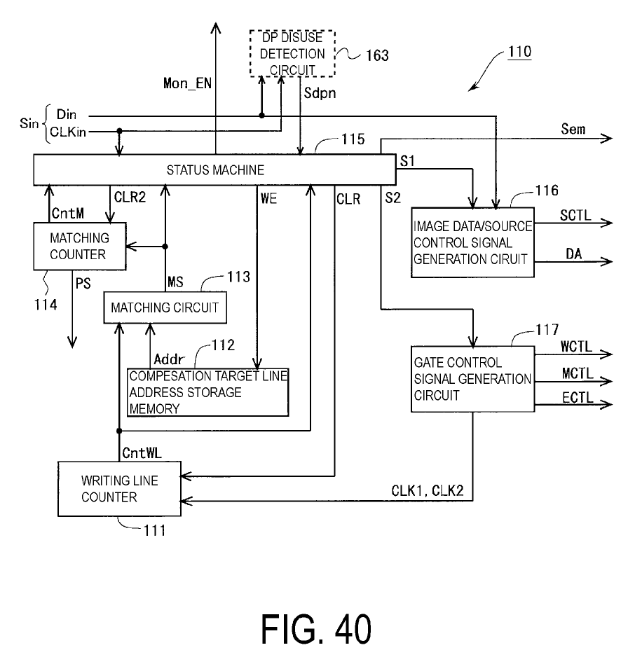

Next, a description will be given of an active matrix organic EL display device according to a third embodiment of the present invention. In the present embodiment, the display device includes a configuration of acting in the current measurement mode in a period where the display device is turned on but is not used (referred to as a “DP disuse period” below). With this configuration, as illustrated in FIG. 40, a DP disuse detection circuit 163 is provided in or outside the drive controller 110 in the display control circuit 100, the DP disuse detection circuit 163 being configured to detect a DP disuse period on the basis of the RGB video data signal Din included in the input signal Sin from an external unit and timing information such as the external clock signal CLKin. A DP disuse signal Sdpn indicating whether the display device is used is output from the DP disuse detection circuit 163, and the DP disuse signal Sdpn is input to the status machine 115 in the drive controller 110. Other configurations of the present embodiment are similar to those of the first embodiment. Hence, the same parts are denoted by the same reference signs below, and detailed descriptions thereof are omitted.

The organic EL display device according to the present embodiment acts in the current measurement mode in the period of a certain number of frames (N frame period) in the DP disuse period on the basis of the DP disuse signal Sdpn and acts in the normal display mode in the periods other than the DP disuse period. Note that in the DP disuse period, the compensation target row is sequentially changed, similarly to the first embodiment, while current measurement based on the first gray scale P1 and current measurement based on the second gray sale P2 are performed for each compensation target row in two frame periods and correction data is updated (refer to Step S166 in FIG. 32).

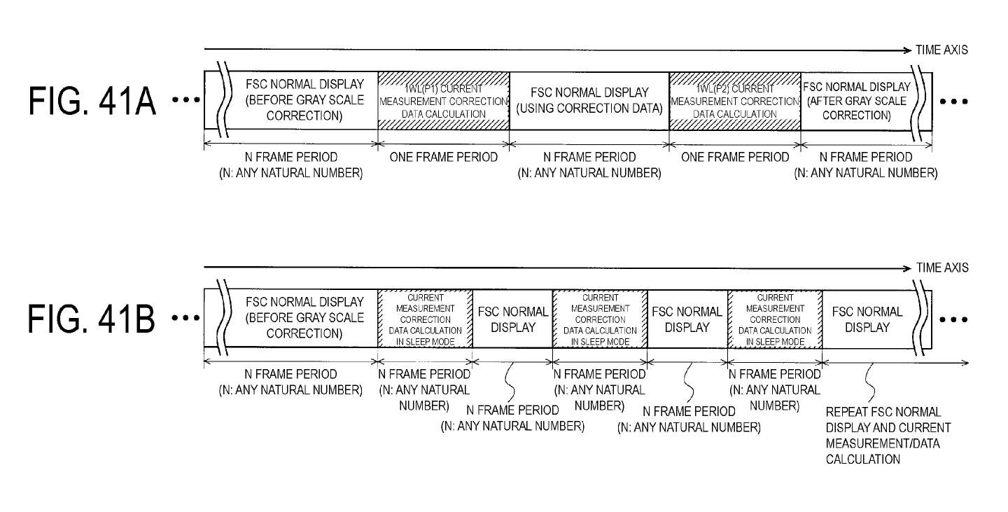

For example, in a case where the DP disuse detection circuit 163 illustrated in FIG. 40 is configured to detect a sleep mode period, the organic EL display device according to the present embodiment acts as illustrated in FIG. 41B. Note that FIG. 41A is a timing chart for comparison and illustrates actions in the first embodiment. Note that, the sleep mode period here is a period in which the normal display action is not performed in a period where a user is not using the display device (although the display device is turned on).

In the action example illustrated in FIG. 41B, when the sleep mode period is detected by the DP disuse detection circuit 163 after the FSC normal display is performed in the period of the certain number of frames (N frame period), the actions in the current measurement mode (current measurement and correction data calculation) are performed only in the period of the certain number of frames (N frame period) in the sleep mode period, and after that, FSC normal display in which pixel data is written into each pixel circuit 50 on the basis of gray scale data obtained as a result of correction using correction data calculated through the actions in the current measurement mode to display a color image, is performed in the period of the certain number of frames (N frame period). Thereafter, similar actions are repeated every time a sleep mode period is detected. The compensation target row is sequentially updated in the actions in the current measurement mode in the sleep mode periods (refer to Step S166 in FIG. 32). Note that also in the present embodiment, similar to the first embodiment, a drive current is measured in each of the pixel circuits in one compensation target row in one frame period in the current measurement mode.

As described above, the present embodiment is different from the first embodiment in that the timings at and periods in which the actions in the current measurement mode (current measurement and correction data calculation) are performed are based on detection of the DP disuse period (sleep mode period). However, the configurations of the pixel circuits 50 and the light emission control line driving circuit 350 having characteristics different from the known organic EL display device (FIG. 3) using the external compensation method are similar to those in the first embodiment (refer to FIG. 18). With the configuration stated above, the present embodiment can achieve effects similar to those of the first embodiment.

### 4. Modified Example

The present invention is not limited to the embodiments described above, and various modifications may be made without departing from the scope of the present invention. A description follows regarding modified examples of the above-described embodiments.

### 4.1 First Modified Example

In the above-described embodiments, the light emission control lines EM1(i), EM2(i), and EM3(i), the number of which (three) is equal to the number of the organic EL elements OLED(R), OLED(G), and OLED(B) included in one pixel circuits 50, are provided for each pixel circuit row, and the light emission control line driving circuit 350 includes the first to third light emission control line deactivation circuits 350d1 to 350d3 corresponding to the three respective light emission control lines EM1(i), EM2(i), and EM3(i), as illustrated in FIG. 18. To the respective first to third light emission control line deactivation circuits 350d1 to 350d3, the first to third deactivation start pulse signals ESPd1 to ESPd3 which include pulses changing to a high level at the same timing as that of the n-th writing control signal Gw(n) in a corresponding one of the first to third subframe periods (refer to FIG. 25) are input.

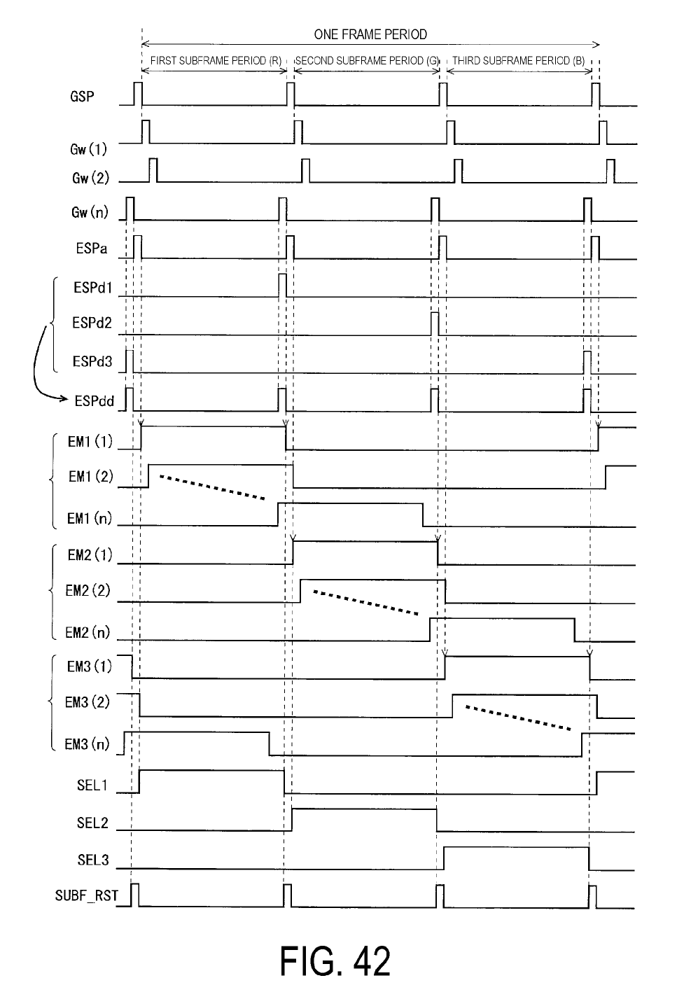

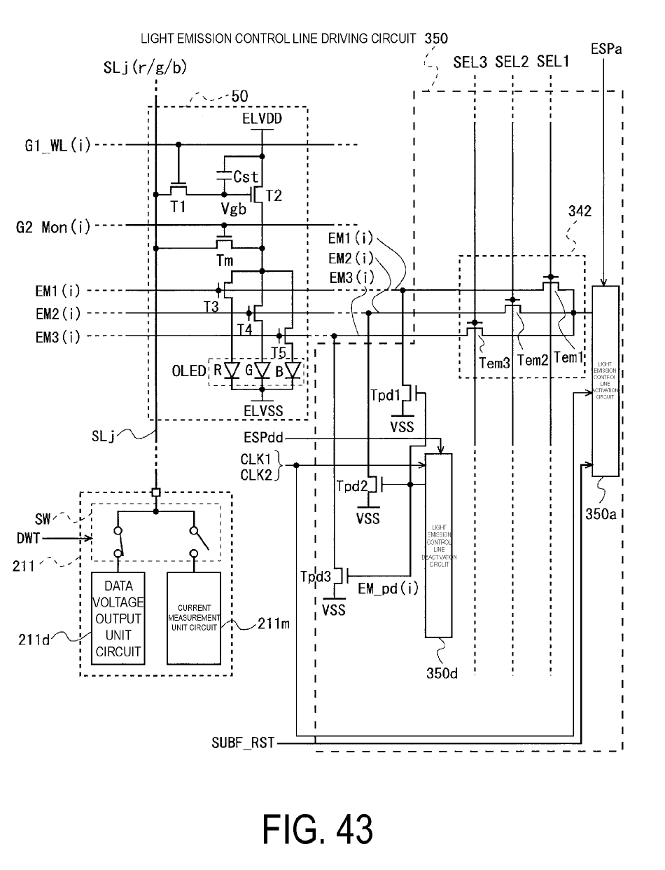

However, by using a pulse signal corresponding to the logical sum of the first to third deactivation start pulse signals ESPd1 to ESPd3, i.e., an integrated deactivation start pulse signal ESPdd including pulses changing to a high level at the same timings as the pulses of the n-th writing control signal Gw(n) in the respective subframe periods as illustrated in FIG. 42, the first to third light emission control line deactivation circuits 350d1 to 350d3 can be replaced with one light emission control line deactivation circuit. FIG. 43 illustrates a configuration of the light emission control line driving circuit 350 according to such a modified example. In the light emission control line driving circuit 350 illustrated in FIG. 43, the first to third light emission control line deactivation circuits 350d1 to 350d3 in the light emission control line driving circuit 350 illustrated in FIG. 18 are replaced with one light emission control line deactivation circuit 350d, and the gate terminals of the first to third pull-down transistors Tpd1, Tpd2, and Tpd3 connected to the respective first to third light emission control lines EM1(i), EM2(i), and EM3(i) in each pixel circuit row are connected to each other to be connected to the output terminal of the one light emission control line deactivation circuit 350d.

As described above, the integrated deactivation start pulse signal ESPdd changes to a high level at the same timings as the pulses of the n-th (last) writing control signal Gw(n) in the respective subframe periods, and thus the first deactivation signal EM_pd(1) among the n deactivation signals EM_pd(1) to EM_pd(n) output from the light emission control line deactivation circuit 350d, i.e., the deactivation signal EM_pd(1) supplied to the gate terminals of the pull-down transistors Tpd1 to Tpd3 in the first row, changes to a high level and keeps a high level only for one horizontal interval immediately after the pulse of the n-th writing control signal Gw(n), and thereafter second and subsequent deactivation signals EM_pd(2) to EM_pd(n) sequentially change to a high level and keep a high level for one horizontal interval. In contrast, as illustrated in FIG. 25 and FIG. 42, the start (first) writing control signal Gw(1) in the k-the subframe period changes from a low level to a high level at the time point where one horizontal interval has elapsed from the drop of the last (n-th) writing control signal Gw(n) in the subframe period immediately before the k-th subframe, and according to this, the voltage of the k-th light emission control line Emk(1) in the first row changes from a low level to a high level, and thereafter, the k-th light emission control lines EMk(i) (i=2 to n) in the second and subsequent rows sequentially change from a low level to a high level at one horizontal interval (k=1, 2, 3). In this way, the deactivation signal EM_pd(i) supplied to the gate terminals of the pull-down transistors Tpd1 to Tpd3 in each row changes from a high level to a low level at the time point when the writing control signal Gw(i) in the row in the k-th subframe period changes from a low level to a high level (time point when the voltage of the k-th light emission control line EMk(i) in the row changes from a low level to a high level) and changes from a low level to a high level at the time point that is one horizontal interval before the time point when the writing control signal Gw(i) in the row changes from a low level to a high level in the subframe period immediately after the k-th subframe period (k=1, 2, 3; i=1 to n).

With the above configuration, even when the light emission control line driving circuit 350 including the configuration illustrated in FIG. 18 is replaced with the light emission control line driving circuit 350 including the configuration illustrated in FIG. 43, the period in which each of the light emission control lines EMk(i) in each row is in an active state does not change (period in which a voltage of each of the light emission control lines EMk(i) is in a high level). In contrast, in the light emission control line driving circuit 350 including the configuration illustrated in FIG. 43, the first to third light emission control line deactivation circuits 350d1 to 350d3 in the light emission control line driving circuit 350 including the configuration illustrated in FIG. 18 are replaced with one light emission control line deactivation circuit 350d. Hence, according to the present modified example, similar functions as those in the above-described embodiments can be maintained while the contents of circuits can be further reduced.

### 4.2 Second Modified Example

Each of the above-described embodiments includes the data-side driving circuit 200 having a function of measuring a current output to each of the data lines SL1 to SLm from each of the pixel circuits 50 on the basis of the drive of the monitor control lines G2_Mon(1) to G2_Mon(n) (refer to FIG. 1, FIG. 4, FIG. 5, and the like), and includes a configuration of detecting the characteristics of the drive transistor T2 (offset value and gain value as correction data) by measuring a drive current in each of the pixel circuits 50. However, the present invention is not limited to this and may include a configuration of detecting the characteristics of the drive transistor T2 (offset value and gain value as correction data) by measuring a voltage in each pixel circuit 50. A description will be given below of a modified example in which measurement of a voltage is performed instead of measurement of a current in the first embodiment described above. Note that the present modified example includes a similar configuration to that of the above-described first embodiment (refer to FIG. 1, FIG. 2, FIG. 6, and the like) except the configuration of the data-side driving circuit 200. Hence, in the following description, the same or corresponding parts of the configuration of the present modified example as or to the configuration of the first embodiment are denoted by the same reference signs, and detailed descriptions thereof are omitted.

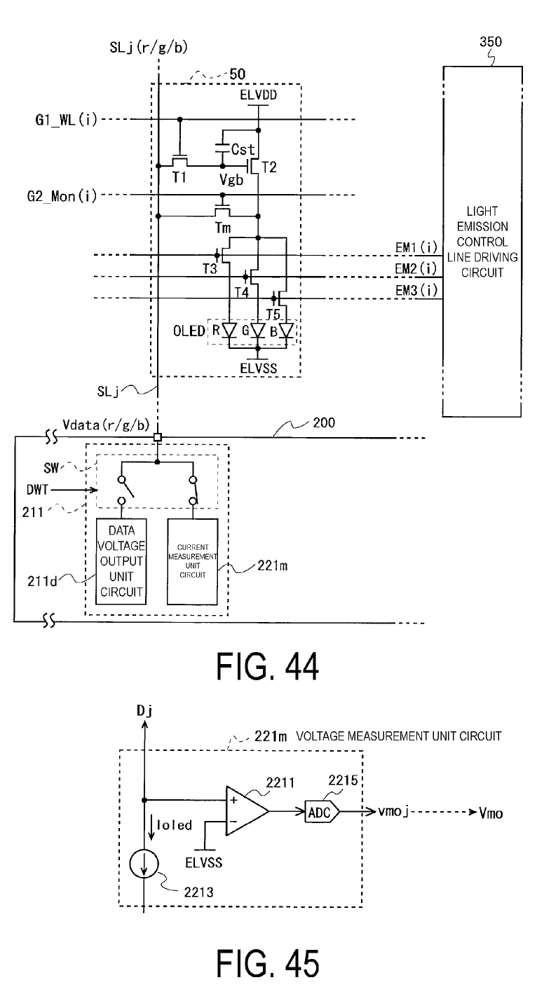

FIG. 44 is a circuit diagram illustrating configurations of the pixel circuit 50 and the data-side unit circuit 211 in the display device according to the present modified example. As illustrated in FIG. 44, in the display device according to the present modified example, the current measurement unit circuit 211m included in the data-side unit circuit 211 provided for each one data line SLj is replaced with a voltage measurement unit circuit 221m in the configuration illustrated in FIG. 4 of the display device according to the first embodiment. With this configuration, the data-side driving circuit 200 in the present modified example functions as a data line driving circuit and a voltage measurement circuit. In this configuration, the current measurement mode in the first embodiment is replaced with a voltage measurement mode. In other words, the present modified example includes a normal display mode and a voltage measurement mode as action modes. Note that the actions in the normal display mode in the present modified example are similar to the actions in the normal display mode in the first embodiment, and hence a description thereof is omitted.

In the present modified example, as illustrated in FIG. 44, a switching switch SW is provided, the switching switch SW being configured to switch between a state where each data line SLj is connected to the data voltage output unit circuit 211d and a state where each data line SLj is connected to the voltage measurement unit circuit 221m, on the basis of the input/output control signal DWT (included in the source control signal SCTL) from the display control circuit 100.

FIG. 45 is a circuit diagram illustrating a configuration example of the voltage measurement unit circuit 221m in the present modified example. This voltage measurement unit circuit 221m includes an amplifier 2211, a constant-current power supply 2213, and an AD converter 2215. A noninverting input terminal of the amplifier 2211 is connected to the constant-current power supply 2213 and is also connected to the data line SLj, and the inverting input terminal of the amplifier 2211 is connected to the low level power supply line ELVSS. The output terminal of the amplifier 2211 is connected to the output terminal of the voltage measurement unit circuit 221m via the AD converter 2215. With such a configuration, in the voltage measurement mode, the voltage between the low level power supply line ELVSS and the data line SLj is amplified by the amplifier 2211 in a state where a constant current Ioled flows into the voltage measurement unit circuit 221m from the compensation target pixel circuit 50 via the data line SLj by the constant-current power supply 2213. The output voltage from the amplifier 2211 is converted into a digital value by the AD converter 2215 and is then output as the monitor voltage vmoj. Note that, in the voltage measurement mode, the light emission control transistors T3 to T5 in each pixel circuit 50 are in an OFF state as in the current measurement mode in the first embodiment, and hence no current flows into any of the organic EL elements OLED in any pixel circuit 50.

The monitor voltage vmoj output from each data-side unit circuit 211 is transmitted to the correction data calculator/storage 120 in the display control circuit 100 as the voltage measurement result Vmo obtained in the voltage measurement circuit in the data-side driving circuit 200 (refer to FIG. 1). As in the above-described first embodiment, this correction data calculator/storage 120 holds correction data (offset value and gain value), calculates new correction data (offset value and gain value) at the time when two voltage measurement results corresponding to the two kinds of gray scales (first gray scale P1 and second gray scale P2: P2>P1) are obtained for each target pixel circuit 50, and updates the held correction data by the calculated data. The process for updating correction data and the compensation process for compensating variations in characteristics of the drive transistors are substantially similar to those of the first embodiment, and hence descriptions thereof are omitted.

The present modified example described above is different from the first embodiment in that a voltage is measured to obtain the characteristics of the drive transistors in each of the pixel circuits 50. However, the configurations of the pixel circuits 50 and the light emission control line driving circuit 350 having characteristics different from the known organic EL display device (FIG. 3) using the external compensation method are similar to those in the first embodiment (refer to FIG. 18). Hence, the present modified example achieves similar effects to those of the first embodiment. Note that modification as in the present modified example is possible to be made in the second and third embodiments, and each of such modified examples achieves similar effects to those of the corresponding one of the above-described second and third embodiments.

### 4.3 Third Modified Example

Each of the above-described embodiments is configured to detect the characteristics (offset value and gain value as correction data) of the drive transistor T2 by measuring a current passing through the drive transistor T2 in each pixel circuit 50 in the current measurement mode. However, instead of or together with this, each of the above-described embodiments may be configured to detect the characteristics of the organic EL elements OLED(R), OLED(G), and OLED(B) in the pixel circuit 50. In this case, in the characteristics detection process period for detecting the characteristics of the organic EL element OLED, the writing control line driving circuit 300 drives the writing control line G1_WL(i), the monitor control line driving circuit 400 drives the monitor control line G2_Mon(i), and the light emission control line driving circuit 350 drives the light emission control lines EM1(i), EM2(i), and EM3(i) (i=1 to n), under the control by the display control circuit 100, whereby each of the pixel circuits 50 and the data-side driving circuit 200 acts as described below (refer to FIG. 29 to FIG. 31).

First, a measurement data voltage with which the drive transistor T2 in each of the pixel circuits 50 in the compensation target row is in an OFF state, is supplied to the data holding capacity Cst of the pixel circuit 50 and held. Next, in the current measurement period in the above-described characteristics detection process period, the monitor control line G2_Mon(It) corresponding to the compensation target row is turned into an active state (refer to FIG. 29), and thereby the monitor control transistor Tm of the pixel circuit 50 in the compensation target row is turned into an ON state, to supply the measurement voltage Vm to each of the pixel circuits 50 in the compensation target row from each of the current measurement unit circuits 211m in the data-side driving circuit 200 via the data line SLj (j=1 to m). Here, the input transistor T1 and the drive transistor T2 are in an OFF state in each of the pixel circuits 50 in the compensation target row, any one of the light emission control transistors T3, T4, and T5 is in an ON state (the light emission control transistor in the ON state will be referred to as a “conducting light emission control transistor Ton” below). With this configuration, the measurement voltage Vm is supplied to the anode of the organic EL element OLED(S) connected to the conducting light emission control transistor Ton among the organic EL elements OLED(R), OLED(G), and OLED(B) (S is any of R, G, and B). Now, assume that the light emission control transistor T3 is the conducting light emission control transistor Ton. A current passes through the organic EL element OLED(R) in each of the pixel circuits 50 in the compensation target row from each of the current measurement unit circuits 211m via the data line SLj, and the current is measured by the current measurement unit circuit 211m. The current passing through the organic EL element OLED(R) in each of the pixel circuits 50 in the compensation target row is thus measured, and the current passing through each of the other organic EL elements OLED(G) and OLED(B) can be measured by switching the conducting light emission control transistor Ton, which is in an ON state, among the light emission control transistors T3, T4, and T5.

As described above, the current passing through each of the organic EL elements OLED(R), OLED(G), and OLED(B) in each of the pixel circuits in the compensation target row is measured, the characteristics of the organic EL elements OLED(R), OLED(G), and OLED(B) are detected from results of the measurement, and results of the detection are held as correction data as in the configuration that characteristics of the drive transistor T2 are detected on the basis of result of measurement of the current passing through the drive transistor T2. The correction data is used to correct each of gray scale voltages indicated by the display data signal DA for image display, as correction data (offset value and gain value) obtained on the basis of the result of measurement of the current passing through the drive transistor T2 (refer to FIG. 33). In this case, the forward voltage Vf in the right side of Equation (9) mentioned above is not a fixed value but is calculated by using the correction data obtained by detecting the characteristics of the organic EL elements (R), OLED(G), and OLED(B).

In the present modified example, the configuration is made to detect the characteristics (offset value and gain value as correction data) of each of the organic EL elements OLED(X) by measuring the current passing through each of the organic EL elements OLED(X) (X=R, G, B) in the pixel circuit 50. Instead of this, a prescribed current may be sequentially supplied to the organic EL elements OLED(X) in the pixel circuit 50 from the data-side driving circuit 200 via the data line SLj, and the voltage of the anode of the organic EL element OLED(X) through which the current passes may be measured via the data line SLj (refer to FIG. 44 and FIG. 45). Such voltage measurement can also detect the characteristics of the organic EL element OLED(X) in the pixel circuit 50, and each gray scale voltage indicated by the display data signal DA for image display can be corrected by using correction data based on a result of the characteristics detection, as in the case of current measurement.

### 4.4 Other Modified Examples

In the above-described embodiments, a color image is displayed in a sequential additive color mixture method for displaying an image of colors assigned in three respective subframe periods corresponding to three primary colors. The three primary colors used here are constituted by red, green, and blue, but three primary colors constituted by other colors may be used. Moreover, four or more subframe periods may be included in each frame period, and a configuration may be made as to display a color image in a sequential additive color mixture method for displaying an image of colors assigned in the four or more respective subframe periods.

Note that descriptions have been given of the above-described embodiments by taking an organic EL display device as an example. However, the present invention is applicable to any display device other than an organic EL display device as long as the display device is an active matrix display device including current-driven self-luminescent display elements.

### 5. Additional Remarks

The present application claims priority based on JP 2015-257664 with the title of “PIXEL CIRCUIT, AND DISPLAY DEVICE AND DRIVING METHOD THEREFORE” filed on Dec. 29, 2015, the content of which is incorporated in the present application by reference.

### REFERENCE SIGNS LIST

1 Organic EL display device
6 Organic EL panel
3, 4, 35asr, 35dsr Shift register
30, 35a, 35d, 40 Unit circuit (in shift register)
50 Pixel circuit
100 Display control circuit
110 Drive controller (drive control circuit)
116 Image data/source control signal generation circuit
117 Gate control signal generation circuit
120 Correction data calculator/storage
130 Gray scale correction unit
161 Power source ON detection circuit
163 DP disuse detection circuit
200 Data-side driving circuit
210 Data line driving circuit
211 Data-side unit circuit
211d Data voltage output unit circuit
211m Current measurement unit circuit
221m Voltage measurement unit circuit
220 Current measurement circuit
340 Demultiplexing circuit
342 Demultiplexer
300 Writing control line driving circuit
350 Light emission control line driving circuit
350a Light emission control line activation circuit
350d, 350d1 to 350d3 Light emission control line deactivation circuit
360 Light emission control signal input switching circuit (selection signal generation circuit)
400 Monitor control line driving circuit
500 Display
T1 Input transistor
T2 Drive transistor
Tm Monitor control transistor
T3 to T5 Light emission control transistor
Tem1 to Tem3 Activation control transistor
Tpd1 to Tpd3 Pull-down transistor
OLED Organic EL element
Cst Capacitor (data holding capacity)
SLj Data line (j=1 to m)
G1_WL, G1_WL(i) Writing control line (i=1 to n)
G2_Mon, G2_Mon(i) Monitor control line (i=1 to n)
EM1(i), EM2(i), EM3(i) Light emission control line (i=1 to n)
ESPa Activation start pulse signal
ESPd1 to ESPd3 Deactivation start pulse signal
ESPdd Integrated deactivation start pulse signal
CLK1 to CLK4 Clock signal
GGem(i) Light emission enable signal (i=1 to n)
EMk_pd(i), EM_pd(i) Deactivation signal (k=1 to 3; i=1 to n)
Sem Light emission switching indication signal
SEL1 to SEL3 Selection signal

1. A pixel circuit provided in a display device including a plurality of data lines and a plurality of writing control lines intersecting with the plurality of data lines, the pixel circuit corresponding to any one of the plurality of data lines and to any one of the plurality of writing control lines, the pixel circuit comprising:
a prescribed number of display elements configured to emit light of a prescribed number of primary colors by being driven by currents, the prescribed number being three or more;
a prescribed number of light emission control transistors configured to serve as switching elements connected to the prescribed number of display elements in series and controlling lighting/lighting-out of the prescribed number of display elements;
a data holding capacity configured to hold data voltages for controlling drive currents of the prescribed number of display elements;
an input transistor configured to serve as a switching element including a control terminal connected to a corresponding one of the plurality of writing control lines and controlling voltage supply from corresponding data line of the plurality of data lines to the data holding capacity;
a drive transistor configured to supply a drive current corresponding to the data voltage to a display element connected to each of the light emission control transistors that is in an ON state among the prescribed number of display elements; and
a monitor control transistor configured to serve as a switching element, one conduction terminal of the monitor control transistor being connected between the drive transistor and each of the light emission control transistors, and another conduction terminal of the monitor control transistor being connected to the corresponding data line.

2. A display device comprising:
a plurality of data lines;
a plurality of writing control lines intersecting with the plurality of data lines;
a plurality of pixel circuits according to claim 1 each corresponding to any one of the plurality of data lines and to any one of the plurality of writing control lines and disposed in a matrix along the plurality of data lines and the plurality of writing control lines;
a plurality of light emission control lines, a prescribed number of the plurality of light emission control lines being disposed for each of the plurality of writing control lines, the prescribed number being equal to the prescribed number of the light emission control transistors;
a plurality of monitor control lines corresponding to the plurality of writing control lines and disposed along the plurality of writing control lines, and each connected to a control terminal of the monitor control transistor in a corresponding one of the plurality of pixel circuits;
a data line driving circuit configured to apply a plurality of data signals to the plurality of data lines, the plurality of data signals representing a color image to be displayed;
a writing control line driving circuit configured to selectively drive the plurality of writing control lines;
a monitor control line driving circuit configured to drive the plurality of monitor control lines;
a light emission control line driving circuit configured to drive the plurality of light emission control lines and cause the prescribed number of light emission control transistors in each of the pixel circuits to sequentially turn into an ON state in each of frame periods;
a measurement circuit configured to measure a current or a voltage in each of the plurality of pixel circuits via the monitor control transistor in the pixel circuit and the data line corresponding to the pixel circuit; and
a drive control circuit configured to control the data line driving circuit, the writing control line driving circuit, the monitor control line driving circuit, and the light emission control line driving circuit.

3. The display device according to claim 2,
wherein in a case where the color image is displayed by the plurality of pixel circuits, the drive control circuit
divides each of the frame periods into a prescribed number of subframe periods corresponding to the prescribed number of primary colors,
controls the writing control line driving circuit and causes the plurality of writing control lines to sequentially turn into an active state in each of the subframe periods,
controls the data line driving circuit to apply, in each of the subframe periods, signals representing an image of a primary color corresponding to the subframe period among images of the prescribed number of primary colors constituting the color image, as the plurality of data signals, to the plurality of data lines,
controls the monitor control line driving circuit to maintain monitor control transistors in the plurality of pixel circuits in an OFF state, and
controls the light emission control line driving circuit to cause, in each of the subframe periods, only a light emission control transistor connected in series to the display element to emit a light in the primary color corresponding to the subframe period among the prescribed number of light emission control transistors in each of the plurality of pixel circuits, to change to an ON state while causing the prescribed number of light emission control transistors in each of the plurality of pixel circuits to sequentially turn into an ON state for prescribed time periods in each of the frame periods.

4. The display device according to claim 3, further comprising a selection signal generation circuit configured to generate a prescribed number of selection signals becoming active in the prescribed number of subframe periods in each of the frame periods,
wherein the light emission control line driving circuit includes
a plurality of demultiplexers corresponding to the plurality of writing control lines and each connected to the prescribed number of light emission control lines corresponding to corresponding one of the writing control lines,
a light emission control line activation circuit configured to output a plurality of light emission enable signals to the plurality of demultiplexers,
a plurality of pull-down transistors each functioning as a switching element provided for each of the plurality of light emission control lines and including a first conduction terminal and a second conduction terminal, the first conduction terminal being connected to corresponding light emission control line, the second conduction terminal being supplied with a prescribed voltage indicating an inactive state, and
a light emission control line deactivation circuit configured to control on/off of the plurality of pull-down transistors,
each of the plurality of demultiplexers includes a prescribed number of activation control transistors being a prescribed number of activation control transistors corresponding to the prescribed number of respective light emission control lines connected to the demultiplexer and each functioning as a switching element including a first conduction terminal and a second conduction terminal, the first conduction terminal being supplied with a light emission enable signal output from the light emission control line activation circuit to the demultiplexer, the second conduction terminal being connected to the corresponding one of the plurality of light emission control lines,
the selection signal generation circuit supplies the prescribed number of selection signals to respective control terminals of the prescribed number of activation control transistors in each of the plurality of demultiplexers, and
in a case where the color image is displayed by the plurality of pixel circuits, the drive control circuit
controls the light emission control line activation circuit and the selection signal generation circuit and causes the plurality of light emission control lines to sequentially turn into an active state to thereby cause the light emission control transistors connected to the display elements of one of light emission colors in the plurality of pixel circuits to sequentially turn into an ON state in each subframe period corresponding to the light emission color, and
controls the light emission control line deactivation circuit and causes the plurality of light emission control lines caused to sequentially turn into the active state by the light emission control line activation circuit, to sequentially turn into an inactive state to thereby cause the prescribed number of light emission control transistors in each of the pixel circuits to sequentially turn into an ON state in the respective prescribed periods.

5. The display device according to claim 2,
wherein, in a case of measuring a current or a voltage in each of the plurality of pixel circuits corresponding to any one writing control line of the plurality of writing control lines,
the drive control circuit controls the monitor control line driving circuit to cause only the monitor control transistor in each of the plurality of pixel circuits corresponding to the one writing control line to be in an ON state, and
the measurement circuit measures a current or a voltage of each of the plurality of pixel circuits corresponding to the one writing control line via the monitor control transistor in the pixel circuit and the data line corresponding to the pixel circuit.

6. The display device according to claim 5,
wherein, in a case of measuring a current or a voltage in each of the plurality of pixel circuits corresponding to any one writing control line of the plurality of writing control lines, the drive control circuit controls the light emission control line driving circuit to cause at least the prescribed number of light emission control transistors of each of the plurality of pixel circuits corresponding to the one writing control line to be an OFF state.

7. The display device according to claim 2,
wherein a transistor configuring each of the plurality of pixel circuits is a thin film transistor in which a channel layer is formed of an oxide semiconductor.

8. A driving method for a display device,
the display device including
a plurality of data lines,
a plurality of writing control lines intersecting with the plurality of data lines, and
a plurality of pixel circuits each corresponding to any one of the plurality of data lines and to any one of the plurality of writing control lines and disposed in a matrix along the plurality of data lines and the plurality of writing control lines,
a plurality of light emission control lines, a prescribed number of the plurality of light emission control lines being disposed for each of the plurality of writing control lines, the prescribed number being equal to the prescribed number of the light emission control transistors, and
a plurality of monitor control lines corresponding to the plurality of writing control lines and disposed along the plurality of writing control lines,
each of the plurality of pixel circuits including
a prescribed number of display elements configured to emit respective light of a prescribed number of primary colors by being driven by currents, the prescribed number being three or more,
a prescribed number of light emission control transistors configured to serve as switching elements connected to the prescribed number of display elements in series and controlling lighting/lighting-out of the prescribed number of display elements,
a data holding capacity configured to hold data voltages for controlling drive currents of the prescribed number of display elements,
an input transistor configured to serve as a switching element including a control terminal connected to the corresponding one of the plurality of writing control lines and controlling voltage supply from corresponding data line of the plurality of data lines to the data holding capacity,
a drive transistor configured to supply a drive current corresponding to the data voltage to a display element connected to each of the light emission control transistors that is in an ON state among the prescribed number of display elements, and
a monitor control transistor configured to serve as a switching element including a control terminal connected to the monitor control line disposed along the corresponding writing control line, one conduction terminal connected between the drive transistor and each of the light emission control transistors, and another conduction terminal connected to the corresponding data line to be able to transmit a current or a voltage in the pixel circuit to the corresponding data line, the driving method comprising:
a data line drive step of applying a plurality of data signals representing a color image to be displayed to the plurality of data lines;
a writing control line drive step of selectively driving the plurality of writing control lines;
a monitor control line drive step of driving the plurality of monitor control lines; and
a light emission control line drive step of driving the plurality of light emission control lines to cause the prescribed number of display elements in each of the plurality of pixel circuits to sequentially turn into a lit state in each of the frame periods.

9. The driving method according to claim 8,
wherein in a case where the color image is displayed by the plurality of pixel circuits,
each of the frame periods is divided into a prescribed number of subframe periods corresponding to the prescribed number of primary colors,
in the writing control line drive step, the plurality of writing control lines are sequentially turned into an active state in each of the subframe periods,
in the data line drive step, signals representing an image of a primary color corresponding to the subframe period among images of the prescribed number of primary colors constituting the color image are applied as the plurality of data signals to the plurality of data lines in each of the subframe periods,
in the monitor control line drive step, the plurality of monitor control lines are driven, and the monitor control transistor in each of the plurality of pixel circuits is maintained in an OFF state, and
in the light emission control line drive step, in each of the subframe periods, only a light emission control transistor connected in series to the display element to emit a light in the primary color corresponding to the subframe period among the prescribed number of light emission control transistors in each of the plurality of pixel circuits, is changed to an ON state, and the prescribed number of light emission control transistors in each of the plurality of pixel circuits are sequentially turned into an ON state for prescribed time periods in each of the frame periods.

10. The driving method according to claim 8, further comprising a measurement step of measuring a current or a voltage in each of the plurality of pixel circuits,
wherein, in a case of measuring a current or a voltage in each of the plurality of pixel circuits corresponding to any one writing control line of the plurality of writing control lines,
in the monitor control line drive step, the plurality of writing control lines are driven, and only the monitor control transistor in each of the plurality of pixel circuits corresponding to the one writing control line is caused to be in an ON state, and
in the measurement step, a current or a voltage in each of the plurality of pixel circuits corresponding to the one writing control line is measured via the monitor control transistor in the pixel circuit and the data line corresponding to the pixel circuit.

11. The display device according to claim 3,
wherein in a current measurement mode, the drive control circuit controls the writing control line driving circuit and causes to write a pixel data into each of the plurality of pixel circuits by sequentially turning the plurality of writing control lines into an active state in each of frame periods without dividing each of the frame periods into a plurality of the subframe periods,
and a current or a voltage in each of the plurality of pixel circuits corresponding to the one writing control line is measured via the monitor control transistor in the pixel circuit and the data line corresponding to the pixel circuit.
